(19) United States
(12) Patent Application Publication
(10) Pub. No.: US 2023/0056225 A1
(43) Pub. Date: Feb. 23, 2023

(54) PHOTOSENSITIVE COMPOSITION, CURED PRODUCT, AND METHOD FOR PRODUCING CURED PRODUCT

(71) Applicant: TOKYO OHKA KOGYO CO., LTD., Kawasaki-shi (JP)

(72) Inventors: Hiroki CHISAKA, Kawasaki-shi (JP); Koichi MISUMI, Kawasaki-shi (JP)

(21) Appl. No.: 17/756,436

(22) PCT Filed: Nov. 17, 2020
(86) PCT No.: PCT/JP2020/042815

§ 371 Date: May 25, 2022

(30) Foreign Application Priority Data
Nov. 28, 2019 (JP) 2019-215873

(51) Int. Cl. G03F 7/075

(52) U.S. Cl. CPC G03F 7/0757

(57) ABSTRACT

A photosensitive composition capable of forming a cured product with high transparency, a cured product of the photosensitive composition, and a method for producing the cured product using the photosensitive composition. In a photosensitive composition including a base component having photopolymerizability and a photopolymerization initiator, a silicone resin is used as the base component, and a phosphine oxide compound and an oxime ester compound as a photopolymerization initiator are used in combination at a specific ratio.

### TECHNICAL FIELD

The present invention relates to a photosensitive composition, a cured product of the photosensitive composition, and a method for producing a cured product using the above photosensitive composition.

### BACKGROUND ART

A photosensitive composition including a photopolymerizable compound having an unsaturated double bond, and a photopolymerization initiator, and capable of forming a transparent cured product has been used as a material for forming a coating material such as a hard coating, a transparent material constituting a display panel such as a liquid crystal display panel and an organic EL display panel, and a protection film or an insulating film in a touch panel.

There have been proposed as these photosensitive compositions, for example, a photosensitive composition including a photopolymerizable monomer, a transparent resin that is a mixture of resins having specific structures, a photopolymerization initiator, and a solvent, and used for forming a protective film or an insulating film in touch-panel (see Patent Document 1).
Patent Document 1: Japanese Unexamined Patent Application, Publication No. 2013-064973

### DISCLOSURE OF THE INVENTION

### Problems to be Solved by the Invention

However, for the photosensitive composition that includes an oxime ester compound as the photopolymerization initiator and gives the transparent cured product, there is often room for improvement in the transparency of the cured product formed.

The present invention has been made in light of the problems mentioned above, and an object thereof is to provide a photosensitive composition capable of forming a cured product with high transparency, a cured product of the photosensitive composition, a method for producing the cured product using the photosensitive composition mentioned above.

### Means for Solving the Problems

The present inventors have found that the above-mentioned problems can be solved by using a silicone resin as a base component (A), and using a phosphine oxide compound (B1) and an oxime ester compound in combination at a specific ratio in a photosensitive composition including the base component (A) having photopolymerizability and the photopolymerization initiator (B).

A first aspect of the present invention relates to a photosensitive composition including a base component (A) and a photopolymerization initiator (B),

in which the base component (A) consists of a resin (A1), or a combination of the resin (A1) and a photopolymerizable monomer (A2),
the resin (A1) includes a silicone resin,
when the base component does not include the photopolymerizable monomer (A2), the resin (A1) includes a photopolymerizable resin (A1-1) having an ethylenically unsaturated double bond,
the photopolymerization initiator (B) includes a phosphine oxide compound (B1) and an oxime ester compound (B2) in combination.

A second aspect of the present invention relates to a cured product of the photosensitive composition according to the first aspect.

A third aspect of the present invention relates to a method for producing a cured product including:

shaping the photosensitive composition according to the shape of the cured material to be formed, and,
exposing the shaped photosensitive composition.

### Effects of the Invention

The present invention can provide a photosensitive composition capable of forming a cured product with high transparency, a cured product of the photosensitive composition, a method for producing the cured product using the photosensitive composition mentioned above.

### PREFERRED MODE FOR CARRYING OUT THE INVENTION

### <<Photosensitive Composition>>

A photosensitive composition includes a base component (A), and a photopolymerization initiator. The base component (A) consists of a resin (A1), or a combination of the resin (A1) and a photopolymerizable monomer (A2). The resin (A1) includes a silicone resin. When the base component (A) does not include the photopolymerizable monomer (A2), the resin (A1) has an ethylenically unsaturated double bond. The photopolymerization initiator includes a phosphine oxide compound (B1) and an oxime ester compound (B2) in combination.

The photosensitive composition with the above constituents cures well by exposure and provides the cured product with high transparency.

Hereinafter, essential or optional components that can be included in the photosensitive composition are described.

### <Base Component (A)>

The photosensitive composition includes a base component (A) that gives shapability to the photosensitive composition. The base component (A) consists of a resin (A1), or a combination of the resin (A1) and a photopolymerizable monomer (A2). The resin (A1) includes a silicone resin. When the base component (A) does not include the photopolymerizable monomer (A2), the resin (A1) has an ethylenically unsaturated double bond.

### [Resin (A1)]

The photosensitive resin composition essentially includes a resin (A1) as the base component (A).

The resin (A1) essentially includes a silicone resin. The silicone resin is not particularly limited as long as the silicone resin has a molecular chain consisting of a siloxane bond, and is recognized by those skilled in the art as silicone resin.

A molecular chain of the silicon resin is may be straight or branched. The silicone resin may be a so-called silsesquioxane resin. A structure of the silsesquioxane resin is not particularly limited, and may be any structures which have conventionally been known, such as a cage-like structure, an incomplete cage-like structure, a ladder-like structure, and a random-like structure.

The resin (A1) may include other resin than the silicone resin as long as the objective of the present invention is not impaired. A content of the silicone resin in the resin (A1) is preferably 50% by mass or more, more preferably 80% by mass or more, further preferably 90% by mass or more, even more preferably 95% by mass or more, and particularly preferably 100% by mass relative to a mass of the resin (A1).

Other resin than the silicone resin that can be used as the resin (A1) is not particularly limited as long as a resin material is transparent, and gives shapability to the photosensitive composition. Specific examples of the resin material include a polyacetal resin, a polyamide resin, a polycarbonate resin, a polyester resin (a polybutylene terephthalate, a polyethylene terephthalate, a polyarylate and the like), an FR-AS resin, an FR-ABS resin, an AS resin, an ABS resin, a polyphenylene oxide resin, a polyphenylene sulfide resin, a polysulfone resin, a polyethersulfone resin, a polyetheretherketone resin, a fluorine-based resin, a polyimide resin, a polyamide imide resin, a polyamide bismaleimide resin, a polyetherimide resin, a polybenzoxazole resin, a polybenzothiazole resin, a polybenzimidazole resin, a BT resin, a polymethylpentene, a ultra high molecular weight polyethylene, an FR-polypropylene, a (meth)acrylic resin (a polymethylmethacrylate and the like), a polystyrene, and the like. These resin materials can be used in combination of two or more types thereof.

The above-described resin material is preferably dissolved in the photosensitive composition. The above-described resin material may be a suspension liquid such as a latex as long as the objects of the present invention are not inhibited.

The resin (A1) preferably includes a photopolymerizable resin (A1-1) having an ethylenically unsaturated double bond, since the cured product with good mechanical property can be easily formed. The photopolymerizable resin (A1-1) may be the silicone resin or other resin, and is preferably the silicone resin. The resin (A1) preferably includes an alkali-soluble resin (A1-2), since patterning by photolithography method is easy when the cured product is formed by using the photosensitive composition. The alkali-soluble resin (A1-2) may be the silicone resin or other resin. It should be noted that there is a case that the resin material as the resin (A1) corresponds both the photopolymerizable resin (A1-1) and the alkali-soluble resin.

Here in the present specification, the alkali-soluble resin (A1-2) is a resin having a functional group that gives alkali-solubility (for example, a phenolic hydroxy group, a carboxy group, or a sulfonic acid group).

Examples of the silsesquioxane resin as the resin (A1) includes a silsesquioxane resin having a carboxylic group-containing group. Such silsesquioxane resin acts as the alkali-soluble resin in the photosensitive composition.

The silsesquioxane resin having the carboxylic group-containing group is preferably a resin having a constituent unit represented by the following formula (ala).

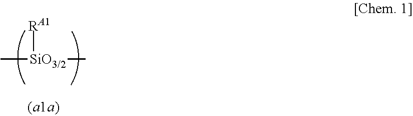

In the formula (ala), RA is a group represented by the following formula (a1a-I):

—X^{A}—B^{A}—Y^{A}—COOH (a1a-I),

X^{A} is a single bond, an alkylene group having 1 or more and 6 or less carbon atoms, an arylene group having 6 or more and 12 or less carbon atoms, or a group represented by —R^{A6}—NH—R^{A7}—,
R^{A6} and R^{A7} are each independently an alkylene group having 1 or more and 3 or less carbon atoms,
Y^{A} is a divalent cyclic organic group, or an aliphatic hydrocarbon group having 1 or more and 20 or less carbon atoms,
B^{A} is —NH—CO—, —CO—NH—, —NH—CO—O—, —O—CO—NH—, or —NH—CO—NH, and X^{A} and Y^{A} are each independently substituted with one or more group selected from the group consisting of a (meth)acryloyloxy group, a vinyl group, and an epoxy-group containing organic group.

For example, the silsesquioxane resin may include a constituent unit represented by the following formula (a1a-1) or (a1a-2), in addition to the constituent unit represented by the formula (a1a). In the constituent unit represented by the following formula (a1a-1) or (a1a-2), when R^{A0} is an organic group, the organic group may include one or more selected from an aromatic group, an amide bond, and a urethane bond.

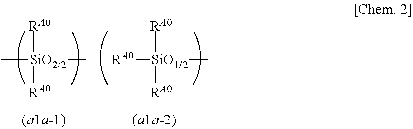

In the formula (a1a-1) and (a1a-2), R^{A0}s are each independently a hydrogen atom, or a monovalent organic group.

In the formula (a1a-1) and (a1a-2), when R^{A0} is the organic group, a number of carbon atoms thereof is not particularly limited, and, for example, preferably 1 or more and 50 or less, more preferably 1 or more and 30 or less, and particularly preferably 1 or more and 20 or less. Structure of the organic group can be linear, branched, cyclic, or a combination of these structures. The organic group may have one or more unsaturated bonds. The organic group may have a hetero atom. Examples of the hetero atom includes a halogen atom, an oxygen atom, a sulfur atom, a nitrogen atom, or a phosphorus atom.

Suitable examples of the organic group include an alkyl group, an alkoxy group, a cycloalkyl group, a cycloalkoxy group, a saturated aliphatic acyl group, a saturated aliphatic acyloxy group, an alkoxycarbonyl group, an optionally substituted phenyl group, an optionally substituted phenoxy group, an optionally substituted benzoyl group, an optionally substituted phenoxycarbonyl group, an optionally substituted benzoyloxy group, an optionally substituted phenylalkyl group, an optionally substituted naphthyl group, an optionally substituted naphthoxy group, an optionally substituted naphthoyl group, an optionally substituted naphthoxycarbonyl group, an optionally substituted naphthoyloxy group, an optionally substituted naphthylalkyl group, an optionally substituted heterocyclyl group, an amino group substituted with one or two organic groups, and the like.

Examples of the substituent that these groups may have include an alkyl group having 1 or more and 20 or less carbon atoms, an alkoxy group having 1 or more and 20 or less carbon atoms, a cycloalkyl group having 3 or more and 10 or less carbon atoms, a cycloalkoxy group having 3 or more and 10 or less carbon atoms, a saturated aliphatic acyl group having 2 or more and 20 or less carbon atoms, an alkoxycarbonyl group having 2 or more and 20 or less carbon atoms, a saturated aliphatic acyloxy group having 2 or more and 20 or less carbon atoms, a phenyl group, a phenoxy group, a phenylthio group, a benzoyl group, a phenoxycarbonyl group, a benzoyloxy group, a phenylalkyl group having 7 or more and 20 or less, a naphthyl group, a naphthoxy group, a naphthoyl group, a naphthoxycarbonyl group, a naphthoyloxy group, a naphthylalkyl group having 11 or more and 20 or less carbon atoms, a heterocyclyl group, a heterocyclylcarbonyl group, an amino group, an amino group substituted with one or two organic groups having 1 or more and 20 or less carbon atoms, a nitro group, a hydroxy group, a halogen atom, a cyano group, a carboxy group, and the like.

In the formula (ala), R^{A1} is a group represented by the following formula (a1a-I):

—X^{A}—B^{A}—Y^{A}—COOH (a1a-I).

In the formula (a1a-I), X^{A} is a single bond, an alkylene group having 1 or more and 6 or less carbon atoms, an arylene group having 6 or more and 12 or less carbon atoms, or a group represented by —R^{A6}—NH—R^{A7}—. R^{A6} and R^{A7} are each independently an alkylene group having 1 or more and 3 or less carbon atoms. Y^{A} is a divalent cyclic organic group, or a chain aliphatic hydrocarbon group having 1 or more and 20 or less carbon atoms. B^{A} is —NH—CO—, —CO—NH—, —NH—CO—O—, —O—CO—NH—, or —NH—CO—NH—. X^{A} and Y^{A} are each independently substituted with one or more group selected from the group consisting of a (meth) acryloyloxy group, a vinyl group, and an epoxy group-containing organic group.

Specific examples of the alkylene group having 1 or more and 6 or less carbon atoms as X^{A} include a methylene group, an ethane-1,2-diyl group, an ethane-1,1-diyl group, a propane-1,3-diyl group, a propane-1,2-diyl group, a butane-1,4-diyl group, a pentane-1,5-diyl group, a hexane-1,6-diyl group, and the like.

A number of carbon atoms of the arylene group as X^{A} is 6 or more and 12 or less, and preferably 6 or more and 10 or less. Suitable specific examples of the arylene group include, a o-phenylene group, a m-phenylene group, a p-phenylene group, a naphthalene-1,4-diyl group, a naphthalene-1,5-diyl group, a naphthalene-2,6-diyl group, a biphenyl-4,4′-diyl group.

Specific examples of —R^{A6}—NH—R^{A7}— includes —CH₂—NH—CH₂—, —(CH₂)₂—NH—(CH₂)₂—, —(CH₂)₃—NH—(CH₂)—, —CH₂—NH—(CH₂)₂—, —(CH₂)₂—NH—CH₂—, —(CH₂)₂—NH—(CH₂)—, —(CH₂)₃—NH—(CH₂)₂—, —CH₂—NH—(CH₂)—, —(CH₂)₃—NH—CH₂—, and the like.

The divalent cyclic organic group as Y^{A} may be a group in which two hydrogen atoms are removed from an aromatic ring, or a group in which two hydrogen atoms are removed from an aliphatic ring. When Y^{A} is the divalent group including an aromatic ring, the divalent cyclic organic group is preferably a group in which two hydrogen atoms are removed from an aromatic ring having 6 or more and 10 or less carbon atoms and optionally substituted with a substituent having 1 or 2 carbon atoms. Suitable examples of the aromatic ring having 6 or more and 10 or less carbon atoms include a benzene ring, a naphthalene ring, a methylbenzene ring, a dimethylbenzene ring, and the like. When Y^{A} is the divalent group including an aliphatic ring, the divalent cyclic organic group is preferably a group in which two hydrogen atoms are removed from an aliphatic ring having 5 or more and 16 or less carbon atoms. Suitable examples of the aliphatic ring having 5 or more and 16 or less carbon atoms include a cyclopentane ring, a cyclohexane ring, a cycloheptane ring, a cyclooctane ring, a cyclononane ring, a cyclodecane ring, a dicyclopentadiene ring, a norbornane ring, a norbornene ring, a cubane ring, a basketane ring, and the like.

When Y^{A} is a chain aliphatic hydrocarbon group, the chain aliphatic hydrocarbon group may be linear or branched, and may be a saturated hydrocarbon group, or an unsaturated hydrocarbon group. Suitable examples of the chain aliphatic hydrocarbon group having 1 or more and 20 or less carbon atoms include alkylene groups, alkylene groups having a double bond, or alkylene groups having a branched chain having 1 or more and 9 or less carbon atoms such as a methylene group, an ethane-1,2-diyl group, an ethane-1,1-diyl group, a propane-1,3-diyl group, a propane-1,2-diyl group, a propane-1,3-diyl group, a propane-1,2-diyl group, a vinylene group, a (2-octenyl)ethylene group, and a (2,4,6-trimethyl-2-nonenyl)ethylene.

In the formula (a1a-I), X^{A} and Y^{A} are each independently optionally substituted with one or more group selected from the group consisting of a (meth)acryloyloxy group, a vinyl group, and an epoxy group-containing organic group. When at least one of X^{A} and Y^{A} are substituted with the (meth)acryloyloxy group, or the vinyl group, the silsesquioxane resin corresponds to the photopolymerizable resin (A-1). In addition, the silsesquioxane resin is preferably a silicon resin in which at least one of X^{A} and Y^{A} are substituted with one or more groups selected form the group consisting of the (meth)acryloyl group, the vinyl group, and the epoxy group-containing organic group.

The silsesquioxane resin may include other constituent unit than the constituent unit represented by the formula (a1a). Other constituent unit is not particularly limited, and a constituent unit represented by the following formular (a2b) is preferred as other constituent unit.

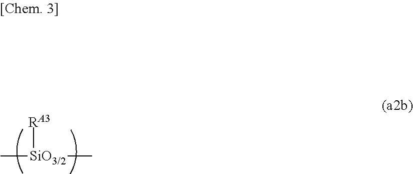

In the formula (a2b), R^{A3} represents an alkyl group having 1 or more and 12 or less carbon atoms, an aryl group having 6 or more and 12 or less carbon atom, or an aralkyl group having 7 or more and 12 or less carbon atoms.

When R^{A3} is the alkyl group, for example, a methyl group, an ethyl group, and an n-propyl group are preferred. When R^{A3} is the aryl group or the aralkyl group, for example, a phenyl group, a benzyl group, a tolyl group, a xylyl group, and a naphthyl group are preferred.

In the silsesquioxane resin, at least one of X^{A} and Y^{A} are preferably substituted with one or more groups selected form the group consisting of the (meth)acryloyl group, the vinyl group, and the epoxy group-containing group, and a ratio of the constituent unit represented by the formula (ala) is preferably 10% by mol or more and 100% by mol or less, and more preferably 30% by mol or more and 70% by mol or less.

The silsesquioxane resin is also preferably a silsesquioxane resin having a constituent unit represented by the following formula (a2a) with the constituent unit represented by the formula (ala).

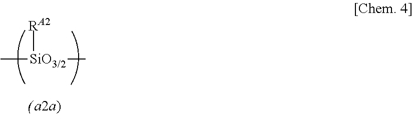

In the formula (a2a), R^{A}2 is a group represented by the following formula (a1a-II):

—Z^{A}-A^{A} (a1a-II),

Z^{A} is a single bond, an alkylene group having 1 or more and 6 or less carbon atoms, or an arylene group having 6 or more and 12 or less carbon atoms, and
A^{A} is a (meth)acryloyloxy group, a vinyl group, or an epoxy group-containing organic group.

In the formular (a1a-II), when Z^{A} is the alkylene group having 1 or more and 6 or less carbon atoms, specific examples include a methylene group, an ethane-1,2-diyl group, an ethane-1,1-diyl group, a propane-1,3-diyl group, a propane-1,2-diyl group, a butane-1,4-diyl group, a pentane-1,5-diyl group, a hexane-1,6-diyl group, and the like.

A number of carbon atoms of the arylene group as Z^{A} is 6 or more and 12 or less, and preferably 6 or more and 10 or less. Suitable specific examples of the arylene group include a o-phenylene group, a m-phenylene group, a p-phenylene group, a naphthalene-1,4-diyl group, a naphthalene-1,5-diyl group, a naphthalene-2,6-diyl group, a biphenyl-4,4′-diyl, and the like.

In the formula (a1a-II), A^{A} is a (meth)acryloyloxy group, a vinyl group, or an epoxy group-containing organic group. The epoxy group-containing organic group is not particularly limited, and, for example, an oxiranyl group, a glycidyl group, and a glycidyloxy group are exemplified.

When the silsesquioxane resin includes the constituent unit represented by the formula (a2a) and having a polymerizable group, in the constituent unit represented by the formula (ala) included in the silsesquioxane resin, X^{A} and Y^{A} do not necessarily have to be substituted with one or more groups selected from the group consisting of a (meth)acryloyloxy group, a vinyl group, and an epoxy group-containing organic group. Since a compound that give the constituent unit represented by the formula (ala) is easily synthesized or obtained, in the formula (ala), it is preferable that X^{A} and Y^{A} are not substituted with such polymerizable group.

For example, specific example of the group represented by the formula (a1a-I) in the constituent unit represented by the formula (ala) include a group in which a combination of X^{A}, B^{A}, and Y^{A} is shown in the following Table 1. Y^{A} in the Table 1 has two bonds, and Y^{A} bonds to a carboxy group via one of two bonds, and bond to B^{A} via the other bond. B^{A} in the Table 1 bonds to X^{A} and Y^{A} in the same manner.

TABLE 1

| | X^{A} | B^{A} | Y^{A} |
|---|---|---|---|
| 1 | —(CH₂)₃— | —NH—CO— | 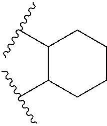 [SMILES: *C1CCCCC1*] |
| 2 | —(CH₂)₃— | —NH—CO— | 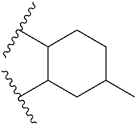 [SMILES: *C1CCC(C)CC1*] |
| 3 | —(CH₂)₃— | —NH—CO— | 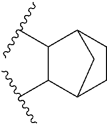 [SMILES: *C1C2CCC(C2)C1*] |
| 4 | —(CH₂)₃— | —NH—CO— | 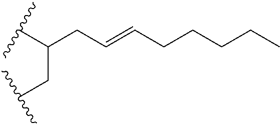 [SMILES: *CC(*)C/C=C/CCCCC] |
| 5 | —(CH₂)₃— | —NH—CO— | 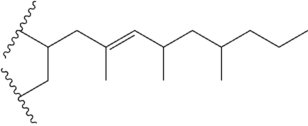 [SMILES: *CC(*)C/C(C)=C/C(C)CC(C)CCC] |
| 6 | —(CH₂)₃— | —NH—CO— | 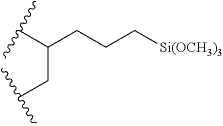 |
| 7 | —(CH₂)₃—NH—(CH₂)₂— | —NH—CO— | 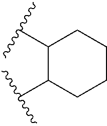 [SMILES: *C1CCCCC1*] |
| 8 | —(CH₂)₃—NH—(CH₂)₂— | —NH—CO— | 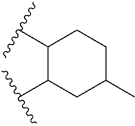 [SMILES: *C1CCC(C)CC1*] |
| 9 | —(CH₂)₃—NH—(CH₂)₂— | —NH—CO— | 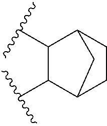 [SMILES: *C1C2CCC(C2)C1*] |
| 10 | —(CH₂)₃—NH—(CH₂)₂— | —NH—CO— | 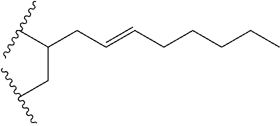 [SMILES: *CC(*)C/C=C/CCCCC] |
| 11 | —(CH₂)₃—NH—(CH₂)₂— | —NH—CO— | 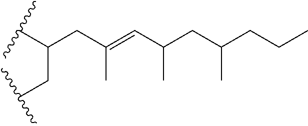 [SMILES: *CC(*)C/C(C)=C/C(C)CC(C)CCC] |
| 12 | —(CH₂)₃—NH—(CH₂)₂— | —NH—CO— | 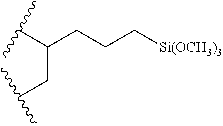 |

Specific examples of a group represented by the formula (a2a-II) in the constituent unit represented by the formula (a2a) included in the silsesquioxane resin include a group in which a combination of Z^{A} and A^{A} is shown in the following Table 2.

TABLE 2

| | Z^{A} | A^{A} |
|---|---|---|
| 1 | —(CH₂)₃— | Methacryloyloxy group |
| 2 | —(CH₂)₃— | Acryloyloxy group |
| 3 | —(CH₂)₃— | Glycidyloxy group |
| 4 | Single bond | Vinyl group |
| 5 | —CH₂— | Vinyl group |
| 6 | —(CH₂)₃— | Vinyl group |
| 7 | —(C₆H₅)— | Vinyl group |

The silsesquioxane resin may include other constituent unit than the constituent unit represented by the formula (ala) and the constituent unit represented by the formula (a2a). Other constituent unit is not particularly limited, and preferably the constituent unit represented by the aforementioned formula (a2b).

A ratio of the constituent unit represented by the formula (a2a) in the silsesquioxane resin is not particularly limited, and preferably 5% by mol or more and 90% by mol or less, more preferably 10% by mol or more and 70% by mol or less, and further preferably 20% by mol or more and 60% by mol or less.

In addition, a ratio of the constituent unit represented by the formula (ala) in the silsesquioxane resin is not particularly limited, and 5% by mol or more and 90% by mol or less, preferably 10% by mol or more and 0% by mol or less, and preferably 20% by mol and 60% by mol or less.

A weight average molecular weight Mw of the above-described silsesquioxane resin is usually 1000 or more and 100000 or less, preferably 1000 or more and 50000 or less, and more preferably 1500 or more and 20000 or less.

Hereinafter, other resin than the silicone resin that can be used as the alkali-soluble resin (A1-2) is described.

Examples of the alkali-soluble resin (A1-2) includes a resin having a cardo structure (a-1) (hereinafter also referred to as “cardo resin (a-1))”). When the resin having a cardo structure (a-1) is used as the alkali-soluble resin (A1-2), the photosensitive composition with good resolution can be easily obtained, and the cured product that are less likely to flow excessively by heating can be easily formed using photosensitive compositions. Therefore, the cured product with desired shape can be easily formed.

[Resin Having a Cardo Structure (a-1)]

A resin having a cardo structure in the structure thereof, and having a specific alkali-solubility can be used as the resin having a cardo structure. The cardo structure is a structure in which the second cyclic structure and the third cyclic structure bond to one carbon atom constituting the first ring structure. The second cyclic structure and the third cyclic structure may be the same or different. Typical examples of the cardo structure include a structure in which two aromatic rings (for example, benzene ring) are bonded to the carbon atom at the 9-position of a fluorene ring.

The cardo resin (a-1) is not particularly limited, and conventionally known resins can be used. Among the conventionally known resins, a resin represented by the following formula (a-1) is preferred. The cardo resin (a-1) represented by the following formula (a-1) has a (meth)acryloyl group, and therefore also corresponds to the photopolymerizable resin (A1-1).

It should be noted that, in the present claims and the specification, “(meth)acrylate” means both acrylate and methacrylate. In the present claims and the specification, “(meth)acrylic” means both acrylic and methacrylic. In the present claims and the specification, “(meth)acryloyl” means both acryloyl and methacryloyl.

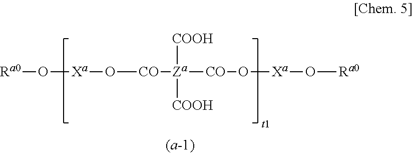

In the formula (a-1), X^{a} represents a group represented by the following formula (a-2).

t1 represents an integer of 0 or more and 20 or less.

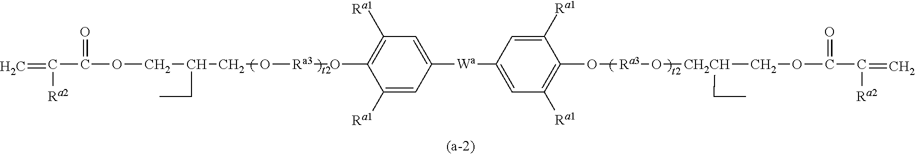

In the formula (a-2), R^{a1}s each independently represent a hydrogen atom, a hydrocarbon group having 1 or more and 6 or less carbon atoms, or a halogen atom, R^{a2}s each independently represent a hydrogen atom or methyl group, R^{a3}s each independently represent a linear or branched alkylene group, t2 represents 0 or 1, and W^{a} represents a group represented by the following formula (a-3).

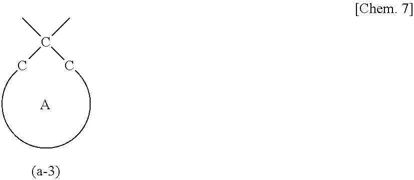

In the formula (a-2), R^{a3} is preferably an alkylene group having 1 or more and 20 or less carbon atoms, more preferably an alkylene group having 1 or more and 10 or less carbon atoms, particularly preferably an alkylene group having 1 or more and 6 or less carbon atoms, and the most preferably an ethane-1,2-diyl group, a propane-1,2-diyl group, and a propane-1,3-diyl group.

The ring A in the formula (a-3) represents an optionally substituted alicyclic ring which may be fused with an aromatic ring. The alicyclic ring may be an aliphatic hydrocarbon ring or an aliphatic heterocycle. Examples of the alicyclic ring include monocycloalkanes, bicycloalkanes, tricycloalkanes, tetracycloalkanes, and the like. Specific examples include monocycloalkanes such as cyclopentane, cyclohexane, cycloheptane and cyclooctane, and adamantane, norbornane, isobornane, tricyclodecane and tetracyclododecane. The aromatic ring which may be fused with the alicyclic ring may be an aromatic hydrocarbon ring or an aromatic heterocycle, and preferably an aromatic hydrocarbon ring. Specifically, a benzene ring and a naphthalene ring are preferred.

Suitable examples of the divalent group represented by the formula (a-3) include following groups.

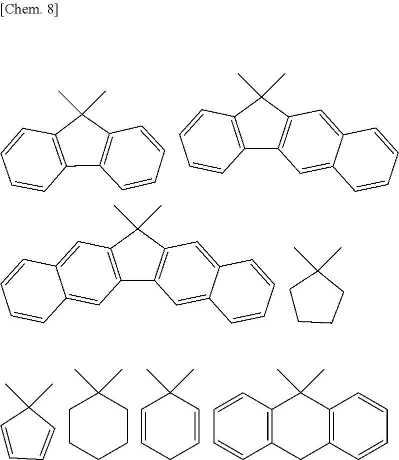

The divalent group X^{a} in the formula (a-1) is introduced in the cardo resin (a-1) by reacting a tetracarboxylic acid anhydride providing a residual group Z^{a} with a diol compound represented by the following formula (a-2a).

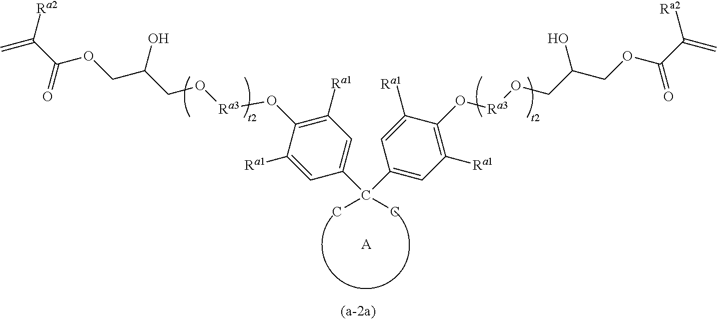

In the formula (a-2a), R^{a1}, R^{a2}, R^{a3}, and t2 are the same as those described for the formula (a-2). In the formula (a-2a), Ring A is the same as that described for the formula (a-3).

A diol compound represented by the formula (a-2a) can be produced, for example, by the following method. First, the hydrogen atom in a phenolic hydroxyl group possessed by the diol compound represented by the following formula (a-2b) is optionally substituted with a group represented by —R^{a3}—OH in accordance with a conventional method, followed by glycidylization with epichlorohydrin to obtain an epoxy compound represented by the following formula (a-2c). Then, the epoxy compound represented by the following formula (a-2c) is reacted with acrylic acid or methacrylic acid to obtain a diol compound represented by the formula (a-2a). In the formula (a-2b) and the formula (a-2c), R^{a1}, R^{a3}, and t2 are as described for the formula (a-2). The ring A in the formula (a-2b) and the formula (a-2c) is as described for the formula (a-3). The method for producing a diol compound represented by the formula (a-2a) is not limited to the method mentioned above.

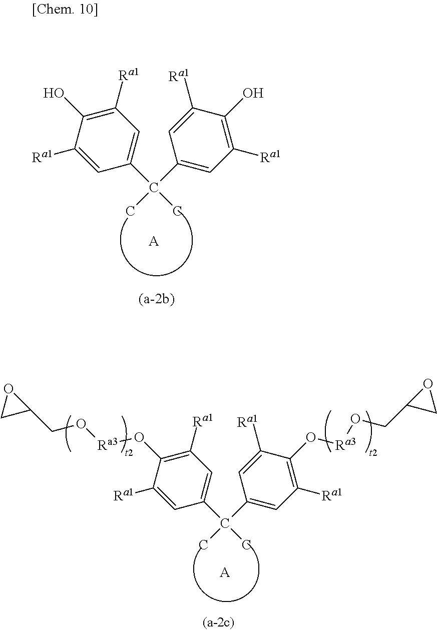

Suitable examples of the diol compound represented by the formula (a-2b) include the following diol compounds.

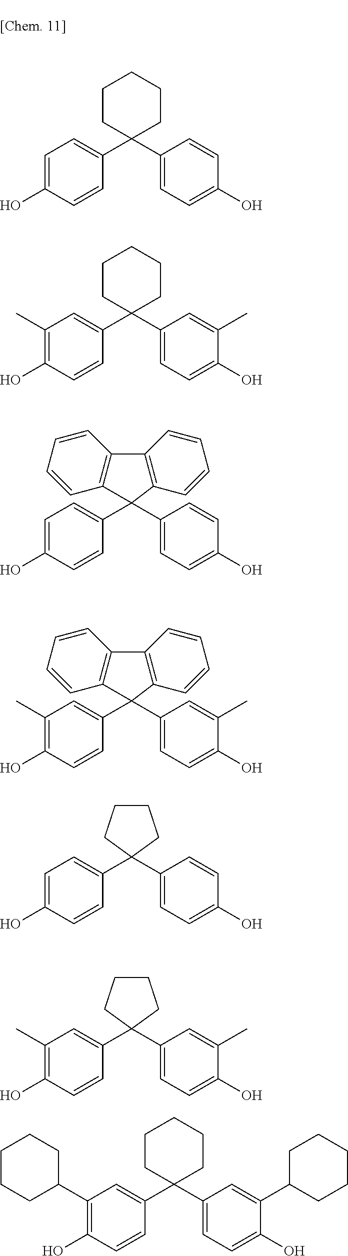

In the formula (a-1), R^{a0} is a hydrogen atom or a group represented by —CO—Y^{a}—COOH. Herein, Y^{a} represents a residue obtainable by removing an acid anhydride group (—CO—O—CO—) from dicarboxylic acid anhydride. Examples of the dicarboxylic anhydride include maleic anhydride, succinic anhydride, itaconic anhydride, phthalic anhydride, tetrahydrophthalic anhydride, hexahydrophthalic anhydride, methylendomethylenetetrahydrophthalic anhydride, chlorendic anhydride, methyltetrahydrophthalic anhydride, anhydrous glutaric acid, and the like.

Furthermore, in the formula (a-1), Z^{a} is a residue obtainable by removing 2 acid anhydride groups from tetracarboxylic acid dianhydride. Examples of the tetracarboxylic acid dianhydride include tetracarboxylic acid dianhydride represented by the following formula (a-4), pyromellitic dianhydride, benzophenonetetracarboxylic dianhydride, biphenyltetracarboxylic dianhydride, biphenylethertetracarboxylic dianhydride, and the like. Among these, pyromellitic dianhydride or biphenyltetracarboxylic dianhydride is preferred in view of broad margin for a development process. In the formula (a-1), t1 represents an integer of 0 or more and 20 or less.

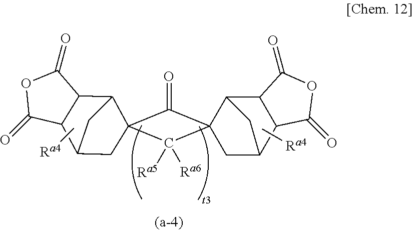

In the formula (a-4), R^{a4}, R^{a5}, and R^{a6} each independently represent one selected from the group consisting of a hydrogen atom, an alkyl group having 1 or more and 10 or less, and a fluorine atom, and t3 represents an integer of 0 or more and 12 or less.

An alkyl group which may be selected as R^{a4} in the formula (a-4) is an alkyl group having 1 or more and 10 or less carbon atoms. When the number of carbon atoms of the alkyl group is in this range, heat resistance of the obtained carboxylic acid ester is especially improved. When R^{a4} is alkyl group, the number of carbon atoms thereof is preferably 1 or more and 6 or less, more preferably 1 or more and 5 or less, further preferably 1 or more and 4 or less, and particularly preferably 1 or more and 3 or less, since a cardo resin having excellent heat resistance is easily obtained. When R^{a4} is alkyl group, the alkyl group may be any one of straight chain and branched chain alkyl groups.

As R^{a4} in the formula (a-4), a hydrogen atom or an alkyl group having 1 or more and 10 or less carbon atoms are preferred. R^{a4} in the formula (a-4) is preferably a hydrogen atom, a methyl group, an ethyl group, an n-propyl group or an isopropyl group, and more preferably a hydrogen atom or a methyl group. Plural R^{a4}s in the formula (a-4) are preferably the same group, since a tetracarboxylic acid dianhydride with high purity can easily be prepared.

In the formula (a-4), t3 represent an integer of 0 or more and 12 or less. When value of t3 is 12 or less, purification of the tetracarboxylic acid dianhydride is easy. Upper limit of t3 is preferably 5, and more preferably 3, since purification of the tetracarboxylic acid dianhydride is easy. Lower limit of t3 is preferably 1, and more preferably 2 in view of the chemical stability of the tetracarboxylic acid dianhydride. In the formula (a-4), t3 is preferably 2 or 3.

An alkyl group having 1 or more and 10 or less carbon atoms which may be selected as R^{as} and R^{a6} in the formula (a-4) is same as the alkyl group having 1 or more and 10 or less carbon atoms which may be selected as R^{a4}. R^{as} and R^{a6} are preferably a hydrogen atom or an alkyl group having 1 or more and 10 or less (preferably 1 or more and 6 or less, more preferably 1 or more and 5 or less, further preferably 1 or more and 4 or less, and particularly preferably 1 or more and 3 or less), and more preferably a hydrogen atom or a methyl group, since purification of tetracarboxylic acid dianhydride is easy.

Examples of the tetracarboxylic dianhydride represented by the formula (a-4) include norbornane-2-spiro-α-cyclopentanone-α′-spiro-2″-norbornane-5,5″,6,6″-tetracarboxylic dianhydride (another name “norbornane-2-spiro-2′-cyclopentanone-5′-spiro-2”-norbornane-5,5″,6,6″-tetracarboxylic dianhydride″), methylnorbornane-2-spiro-α-cyclopentanone-α′-spiro-2″-(methylnorbornane)-5,5″,6,6″-tetracarboxylic dianhydride, norbornane-2-spiro-α-cyclohexanone-α′-spiro-2″-norbornane-5,5″,6,6″-tetracarboxylic dianhydride (another name “norbornane-2-spiro-2′-cyclohexanone-6′-spiro-2”-norbornane-5,5″,6,6″-tetracarboxylic dianhydride″), methylnorbornane-2-spiro-α-cyclohexanone-α′-spiro-2″-(methylnorbornane)-5,5″,6,6″-tetracarboxylic dianhydride, norbornane-2-spiro-α-cyclopropanone-α′-spiro-2″-norbornane-5,5″,6,6″-tetracarboxylic dianhydride, norbornane-2-spiro-α-cyclobutanone-α′-spiro-2″-norbornane-5,5″,6,6″-tetracarboxylic dianhydride, norbornane-2-spiro-α-cycloheptanone-α′-spiro-2″-norbornane-5,5″,6,6″-tetracarboxylic dianhydride, norbornane-2-spiro-α-cyclooctanone-α′-spiro-2″-norbornane-5,5″,6,6″-tetracarboxylic dianhydride, norbornane-2-spiro-α-cyclononanone-α′-spiro-2″-norbornane-5,5″,6,6″-tetracarboxylic dianhydride, norbornane-2-spiro-α-cyclodecanone-α′-spiro-2″-norbornane-5,5″,6,6″-tetracarboxylic dianhydride, norbornane-2-spiro-α-cycloundecanone-α′-spiro-2″-norbornane-5,5″,6,6″-tetracarboxylic dianhydride, norbornane-2-spiro-α-cyclododecanone-α′-spiro-2″-norbornane-5,5″,6,6″-tetracarboxylic dianhydride, norbornane-2-spiro-α-cyclotridecanone-α′-spiro-2″-norbornane-5,5″,6,6″-tetracarboxylic dianhydride, norbornane-2-spiro-α-cyclotetradecanone-α′-spiro-2″-norbornane-5,5″,6,6″-tetracarboxylic dianhydride, norbornane-2-spiro-α-cyclopentadecanone-α′-spiro-2″-norbornane-5,5″,6,6″-tetracarboxylic dianhydride, norbornane-2-spiro-α-(methylcyclopentanone)-α′-spiro-2″-norbornane-5,5″,6,6″-tetracarboxylic dianhydride, norbornane-2-spiro-α-(methylcyclohexanone)-α′-spiro-2″-norbornane-5,5″,6,6″-tetracarboxylic dianhydride, and the like.

A weight average molecular weight of the cardo resin (a-1) is preferably 1,000 or more and 40,000 or less, more preferably 1,500 or more and 30,000 or less, and further preferably 2,000 or more and 10,000 or less. When the weight average molecular weight is in above-mentioned range, sufficient heat resistance and mechanical strength of film can be obtained while excellent developing property is obtained.

[Novolak Resin (a-2)]

The alkali-soluble resin (A1-2) preferably includes a novolak resin (a-2) in view of suppressing excessively flowing of the cured product by heating. It is possible to use, as the novolak resin (a-2), various novolak resins which have been conventionally blended in the photosensitive composition. The novolak resin (a-2) is preferably obtained by subjecting an aromatic compound having a phenolic hydroxy group (hereinafter simply referred to as “phenols”) and aldehydes to cause addition condensation in the presence of an acid catalyst.

### (Phenols)

Examples of phenols used to prepare the novolak resin (a-2) include phenol; cresols such as o-cresol, m-cresol, and p-cresol; xylenols such as 2,3-xylenol, 2,4-xylenol, 2,5-xylenol, 2,6-xylenol, 3,4-xylenol, and 3,5-xylenol; ethylphenols such as o-ethylphenol, m-ethylphenol, and p-ethylphenol; alkylphenols such as 2-isopropylphenol, 3-isopropylphenol, 4-isopropylphenol, o-butylphenol, m-butylphenol, p-butylphenol, and p-tert-butylphenol; trialkylphenols such as 2,3,5-trimethylphenol and 3,4,5-trimethylphenol; polyhydric phenols such as resorcinol, catechol, hydroquinone, hydroquinone monomethyl ether, pyrogallol, and phloroglucinol; alkylpolyhydric phenols (any alkyl group has 1 or more and 4 or less carbon atoms) such as alkylresorcin, alkylcatechol, and alkylhydroquinone; α-naphthol; β-naphthol; hydroxydiphenyl; and bisphenol A. These phenols can be used alone or in combination of two or more types thereof.

Among these phenols, m-cresol and p-cresol are preferable, and it is more preferable to use m-cresol and p-cresol in combination. In this case, it is possible to adjust various properties such as heat resistance of the cured product formed by using the photosensitive composition by adjusting a blending ratio of the two. The blending ratio of m-cresol to p-cresol is not particularly limited and is preferably 3/7 or more and 8/2 or less in terms of a molar ratio of m-cresol/p-cresol. It is possible to easily obtain a photosensitive composition capable of forming a cured product excellent in heat resistance by using m-cresol and p-cresol at a ratio in the above range.

A novolak resin produced by using m-cresol in combination with 2,3,5-trimethylphenol is also preferable. When using such a novolak resin, it is possible to particularly easily obtain a photosensitive composition capable of forming a cured product having high heat resistance that causes less flow by heating at post-bake. The blending ratio of m-cresol to 2,3,5-trimethylphenol is not particularly limited and is preferably 70/30 or more and 95/5 or less in terms of a molar ratio of m-cresol/2,3,5-trimethylphenol.

### (Aldehydes)

As aldehydes used to prepare the novolak resin (a-2), a formaldehyde, a paraformaldehyde, a furfural, a benzaldehyde, a nitrobenzaldehyde, and an acetaldehyde are exemplified. These aldehydes can be used alone or in combination of two or more types thereof.

### (Acid Catalyst)

Examples of the acid catalyst used to prepare the novolak resin (a-2) include inorganic acids such as hydrochloric acid, sulfuric acid, nitric acid, phosphoric acid, and phosphorous acid; organic acids such as formic acid, oxalic acid, acetic acid, diethylsulfuric acid, and paratoluenesulfonic acid; and metal salts such as zinc acetate. These acid catalysts can be used alone or in combination of two or more types thereof.

### (Molecular Weight)

Regarding a polystyrene-equivalent weight average molecular weight (Mw; hereinafter also simply referred to as “weight average molecular weight”) of the novolak resin (a-2), from a viewpoint of the heat resistance of a cured product formed by using the photosensitive composition, the lower limit is preferably 2,000, more preferably 5,000, particularly preferably 10,000, still more preferably 15,000, and most preferably 20,000, and the upper limit is preferably 50,000, more preferably 45,000, still more preferably 40,000, and most preferably 35,000.

As a novolak resin (a-2), at least two resins with different weight average molecular weights in terms of the mass-average molecular weight of polystyrene can be used in combination. When resins with different weight average molecular weights are used in combination, good balance between the developability of the photosensitive composition and the heat resistance of the cured product can be achieved.

[Modified Epoxy Resin (a-3)]

The alkali-soluble resin (A1-2) may include, a polybasic anhydride (a-3c) adduct (a-3) of a reaction product of an epoxy compound (a-3a) and an unsaturated group-containing carboxylic acid (a-3b), since the cured product that are not easily deformed by heating and has high water resistance can be easily formed. Such adduct is also referred to as “modified epoxy resin (a-3)”. It should be noted that, in the present claims and the specification, a compound which corresponds to the above definition and does not correspond to aforementioned the resin having a cardo structure (a-1) is referred to as a modified epoxy resin (a-3). The modified epoxy resin (a-3) also corresponds to photopolymerizable resin (A1-1) in that it has an unsaturated group derived from the unsaturated group-containing carboxylic acid (a-3b).

The epoxy compound (a-3a), the unsaturated group-containing carboxylic acid (a-3b), and the polybasic anhydride (a-3c) will be described below.

<Epoxy Compound (a-3a)>

The epoxy compound (a-3a) is not particularly limited as long as it is a compound having an epoxy group, and may be either an aromatic epoxy compound having an aromatic group or an aliphatic epoxy compound having no aromatic group, and is preferably an aromatic epoxy compound having an aromatic group. The epoxy compound (a-3a) may be either a monofunctional epoxy compound or a difunctional or higher polyfunctional epoxy compound, and is preferably a polyfunctional epoxy compound.

Specific examples of the epoxy compound (a-3a) include difunctional epoxy resins such as a bisphenol A type epoxy resin, a bisphenol F type epoxy resin, a bisphenol S type epoxy resin, a bisphenol AD type epoxy resin, a naphthalene type epoxy resin, and a biphenyl type epoxy resin; glycidyl ester type epoxy resins such as a dimer acid glycidyl ester and a triglycidyl ester; glycidyl amine type epoxy resins such as tetraglycidyl aminodiphenylmethane, triglycidyl-p-aminophenol, tetraglycidyl metaxylylenediamine, and tetraglycidyl bisaminomethylcyclohexane; heterocyclic epoxy resins such as triglycidyl isocyanurate; trifunctional type epoxy resins such as phloroglucinol triglycidyl ether, trihydroxybiphenyl triglycidyl ether, trihydroxyphenylmethane triglycidyl ether, glycerin triglycidyl ether, 2-[4-(2,3-epoxypropoxy)phenyl]-2-[4-[1,1-bis[4-(2,3-epoxypropoxy)phenyl]ethyl]phenyl]propane, and 1,3-bis[4-[1-[4-(2,3-epoxypropoxy)phenyl]-1-[4-[1-[4-(2,3-epoxypropoxy)phenyl]-1-methylethyl]phenyl]ethyl]phenoxy]-2-propanol; and tetrafunctional type epoxy resins such as tetrahydroxyphenylethane tetraglycidyl ether, tetraglycidyl benzophenone, bisresorcinol tetraglycidyl ether, and tetraglycidoxybiphenyl.

The epoxy compound (a-3a) is preferably an epoxy compound having a biphenyl skeleton. It is preferred that the epoxy compound having a biphenyl skeleton has at least one biphenyl skeleton represented by the following formula (a-3a-1) in a main chain. The epoxy compound having a biphenyl skeleton is preferably a polyfunctional epoxy compound having two or more epoxy groups. It is easy to obtain a photosensitive composition capable of forming a cured product excellent in balance between the sensitivity and the developability, and excellent in the adhesion to a substrate by using the epoxy compound having a biphenyl skeleton.

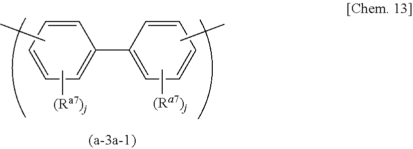

In the formula (a-3a-1), R^{a7} each independently is a hydrogen atom, an alkyl group having 1 or more and 12 or less carbon atoms, a halogen atom, or an optionally substituted phenyl group, and j is an integer of 1 or more and 4 or less.

When R^{a7} is an alkyl group having 1 or more and 12 or less carbon atoms, specific examples of the alkyl group include a methyl group, an ethyl group, an n-propyl group, an isopropyl group, an n-butyl group, an isobutyl group, a sec-butyl group, a tert-butyl group, an n-pentyl group, an isopentyl group, a sec-pentyl group, a tert-pentyl group, an n-hexyl group, an n-heptyl group, an n-octyl group, an isooctyl group, a sec-octyl group, a tert-octyl group, an n-nonyl group, an isononyl group, an n-decyl group, an isodecyl group, an n-undecyl group, and an n-dodecyl group.

When R^{a7} is a halogen atom, specific examples of the halogen atom include a fluorine atom, a chlorine atom, a bromine atom, and an iodine atom.

When R^{a7} is an optionally substituted phenyl group, there is no particular limitation on the number of substituents on the phenyl group. The number of substituents on the phenyl group is 0 or more and 5 or less, and preferably 0 or 1. Examples of the substituent include an alkyl group having 1 or more and 4 or less carbon atoms, an alkoxy group having 1 or more and 4 or less carbon atoms, an aliphatic acyl group having 2 or more and 4 or less carbon atoms, a halogen atom, a cyano group, and a nitro group.

The epoxy compound (a-3a) having a biphenyl skeleton represented by the formula (a-3a-1) is not particularly limited and includes, for example, an epoxy compound represented by the following formula (a-3a-2).

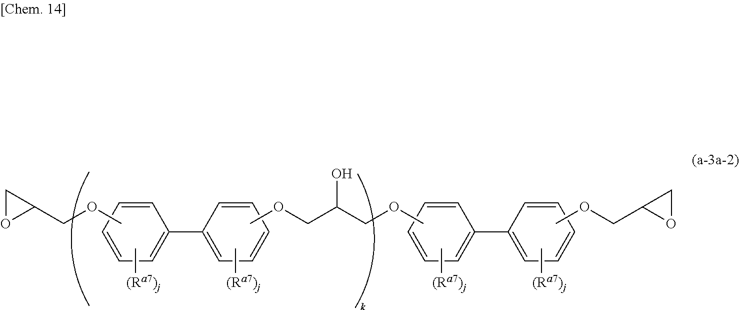

In the formula (a-3a-2), R^{a7} and j are the same as those in the formula (a-3a-1), and k is an average repetition number of a constituent unit in parentheses and is 0 or more and 10 or less.

Among the epoxy compounds represented by the formula (a-3a-2), a compound represented by the following formula (a-3a-3) is preferable since it is particularly easy to obtain a photosensitive composition excellent in balance between the sensitivity and the developability.

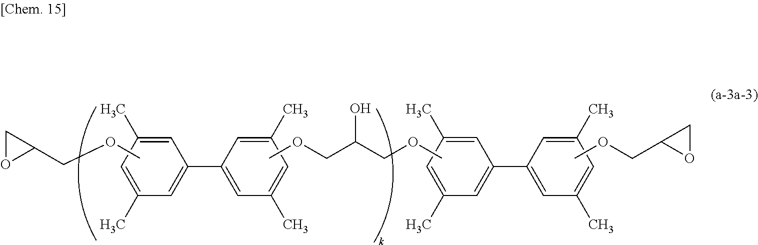

In the formula (a-3a-3), k is the same as that in the formula (a-3a-2).

(Unsaturated Group-Containing Carboxylic Acid (a-3b))

In preparation of a modified epoxy compound (a-3), an epoxy compound (a-3a) is reacted with an unsaturated group-containing carboxylic acid (a-3b). The unsaturated group-containing carboxylic acid (a-3b) is preferably monocarboxylic acid having a reactive unsaturated double bond such as an acryl group or a methacrylic group in a molecule. Examples of such unsaturated group-containing carboxylic acid include acrylic acid, methacrylic acid, β-styrylacrylic acid, β-furfurylacrylic acid, α-cyanocinnamic acid, cinnamic acid, and the like. The unsaturated group-containing carboxylic acid (a-3b) may be used alone or may be used in combination of two or more types thereof.

It is possible to react an epoxy compound (a-3a) with an unsaturated group-containing carboxylic acid (a-3b) by a known method. Preferred reaction methods include, for example, a method in which an epoxy compound (a-3a) is reacted with an unsaturated group-containing carboxylic acid (a-3b) in an organic solvent at a reaction temperature of 50° C. or higher and 150° C. or lower for several hours to several tens of hours using, as a catalyst, tertiary amines such as triethylamine and benzylethylamine, quaternary ammonium salts such as dodecyltrimethylammonium chloride, tetramethylammonium chloride, tetraethylammonium chloride, and benzyltriethylammonium chloride, pyridine, or triphenylphosphine.

Usually, a ratio of the amounts of the two in the reaction of the epoxy compound (a-3a) with the unsaturated group-containing carboxylic acid (a-3b) is preferably 1:0.5 to 1:2, more preferably 1:0.8 to 1:1.25, and particularly preferably 1:0.9 to 1:1.1 in terms of a ratio of an epoxy equivalent of an epoxy compound (a-3a) and a carboxylic acid equivalent of an unsaturated group-containing carboxylic acid (a-3b). When a ratio of the amount of the epoxy compound (a-3a) used to the amount of the unsaturated group-containing carboxylic acid (a-3b) used is 1:0.5 to 1:2 in terms of the equivalent ratio, crosslinking efficiency tends to be improved, which is preferrable.

(Polybasic Anhydride (a-3c))

The polybasic anhydride (a-3c) is an anhydride of carboxylic acid having two or more carboxyl groups. Examples of the polybasic anhydride (a-3c) include, but are not limited to, maleic anhydride, succinic anhydride, itaconic anhydride, phthalic anhydride, tetrahydrophthalic anhydride, hexahydrophthalic anhydride, methylhexahydrophthalic anhydride, methyltetrahydrophthalic anhydride, trimellitic anhydride, pyromellitic anhydride, benzophenonetetracarboxylic dianhydride, 3-methylhexahydrophthalic anhydride, 4-methylhexahydrophthalic anhydride, 3-ethylhexahydrophthalic anhydride, 4-ethylhexahydrophthalic anhydride, tetrahydrophthalic anhydride, 3-methyltetrahydrophthalic anhydride, 4-methyltetrahydrophthalic anhydride, 3-ethyltetrahydrophthalic anhydride, 4-ethyltetrahydrophthalic anhydride, a compound represented by the following formula (a-3c-1), and a compound represented by the following formula (a-3c-2). These polybasic anhydrides (a-3c) may be used alone or may be used in combination of two or more types thereof.

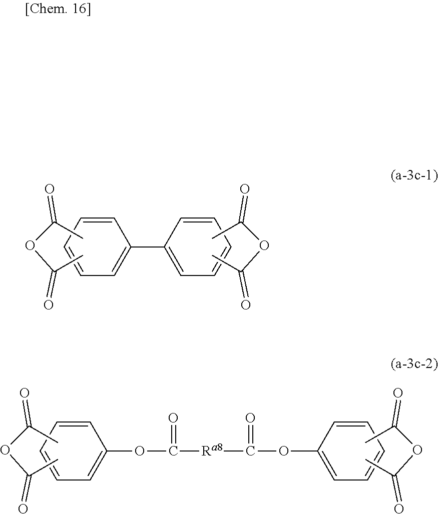

In the formula (a-3c-2), R^{a8} represents an optionally substituted alkylene group having 1 or more and 10 or less carbon atoms.

The polybasic anhydride (a-3c) is preferably a compound having two or more benzene rings since it is easy to obtain a photosensitive composition excellent in balance between the sensitivity and the developability. It is more preferred that the polybasic anhydride (a-3c) contains at least one of the compounds represented by the formula (a-3c-1) and the compound represented by the formula (a-3c-2).

It is possible to appropriately select the method in which the epoxy compound (a-3a) is reacted with the unsaturated group-containing carboxylic acid (a-3b), followed by a reaction with the polybasic anhydride (a-3c) from known methods. A ratio of the amounts of these compounds used is usually 1:1 to 1:0.1, and preferably 1:0.8 to 1:0.2, in terms of an equivalent ratio of a molar number of OH groups in the components after reacting the epoxy compound (a-3a) with the unsaturated group-containing carboxylic acid (a-3b) to an equivalent ratio of an acid anhydride group of the polybasic anhydride (a-3c). When the ratio is within the above range, it is easy to obtain photosensitive composition with satisfactory developability.

An acid value of the modified epoxy resin (a-3) is preferably 10 mgKOH/g or more and 150 mgKOH/g or less, and more preferably 70 mgKOH/g or more and 110 mgKOH/g or less, in terms of a resin solid component. When the acid value of the resin is set at 10 mgKOH/g or more, sufficient solubility in a developing solution is obtained. When the acid value of the resin is set at 150 mgKOH/g or less, sufficient curability can be obtained, thus obtaining satisfactory surface properties.

A weight average molecular weight of the modified epoxy resin (a-3) is preferably 1,000 or more and 40,000 or less, and more preferably 2,000 or more and 30,000 or less. When the weight average molecular weight is 1,000 or more, it is easy to form a cured film excellent in heat resistance and strength. When the weight average molecular weight is 40,000 or less, it is easy to obtain a photosensitive composition which exhibits sufficient solubility in the developing solution.

[Acrylic Resin (a-4)]

An acrylic resin (a-4) us also preferred as a component constituting the alkali-soluble resin (A1-2). As the acrylic resin (a-4), a resin containing a constituent unit derived from a (meth)acrylic acid and/or a constituent unit derived from other monomers such as a (meth)acrylic acid ester can be used. The (meth)acrylic acid is an acrylic acid or a methacrylic acid. The (meth)acrylic acid ester is represented by the following formula (a-4-1), and is not particularly limited as long as the object of the present invention is not inhibited.

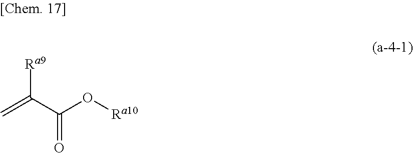

In the formula (a-4-1), R^{a9} represents a hydrogen atom or a methyl group, and R^{a10} is a monovalent organic group. This organic group may have a bond or a substituent, other than a hydrocarbon group such as a heteroatom, in the organic group. This organic group may be a straight-chain group, a branched-chain, or a cyclic group.

A substituent in an organic group as R^{a10} is not particularly limited, and examples of the substituent include a halogen atom, a hydroxy group, a mercapto group, a sulfide group, a cyano group, an isocyano group, a cyanato group, an isocyanato group, a thiocyanato group, an isothiocyanato group, a silyl group, a silanol group, an alkoxy group, an alkoxycarbonyl group, a carbamoyl group, a thiocarbamoyl group, a nitro group, a nitroso group, a carboxy group, a carboxylate group, an acyl group, an acyloxy group, a sulfino group, a sulfo group, a sulfonato group, a phosphino group, a phosphinyl group, a phosphono group, a phosphonato group, a hydroxyimino group, an alkylether group, an alkylthioether group, an arylether group, an arylthioether group, an amino group (—NH₂, —NHR, and —NRR′: wherein R and R′ each independently represent a hydrocarbon group), and the like. A hydrogen atom included in the above-mentioned substituent may be substituted with a hydrocarbon group. Furthermore, the hydrocarbon group included in the above-mentioned substituent may be a straight-chain group, a branched-chain group, or a cyclic group.

The organic group as R^{a10} may have reactive functional groups such as an acryloyloxy group, a methacryloyloxy group, an epoxy group, and an oxetanyl group. Acyl groups having an unsaturated double bond, such as an acryloyloxy group and a methacryloyloxy group can be produced, for example, by reacting at least one part of epoxy groups in an acrylic resin (a-4) including a constituent unit having epoxy groups with an unsaturated carboxylic acid such as acrylic acid or methacrylic acid. After reaction of at least one part of the epoxy groups and the unsaturated carboxylic acid, a group formed by the reaction may be reacted with a polybasic anhydride.

Specific examples of the polybasic anhydride include maleic anhydride, succinic anhydride, itaconic anhydride, phthalic anhydride, tetrahydrophthalic anhydride, hexahydrophthalic anhydride, methylhexahydrophthalic anhydride, methyltetrahydrophthalic anhydride, trimellitic anhydride, pyromellitic anhydride, benzophenonetetracarboxylic dianhydride, 3-methylhexahydrophthalic anhydride, 4-methylhexahydrophthalic anhydride, 3-ethylhexahydrophthalic anhydride, 4-ethylhexahydrophthalic anhydride, and the like.

Specifically, a formation of a constituent unit shown in the following reaction scheme by reacting a constituent unit derived from glycidyl methacrylate and acrylic acid is exemplified. A constituent unit that gives alkali-solubility to a resin is formed by a reaction of such a constituent unit having a hydroxyl group with the polybasic acid anhydride such as tetrahydrophthalic acid anhydride.

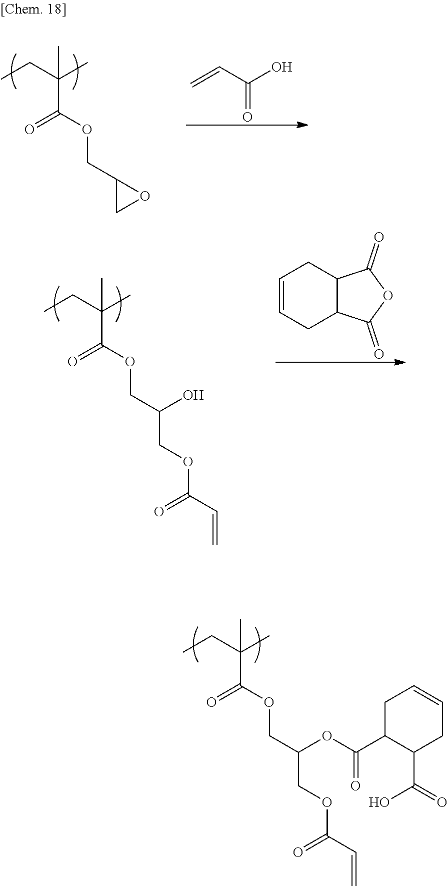

When the acrylic resin (a-4) includes a constituent unit derived from a compound represented by the formula (a-4-1) and having an organic group including an unsaturated double bond as R^{a10}, the acrylic resin also corresponds to the photopolymerizable resin (A1-1).

R^{a10} is preferably an alkyl group, an aryl group, an aralkyl group, or a heterocyclic group. These groups may be substituted with a halogen atom, a hydroxy group, an alkyl group, or a heterocyclic group. When these groups include an alkylene moiety, the alkylene moiety is interrupted by an ether bond, thioether bond, or ester bond.

When the alkyl group is a straight-chain or branched-chain group, the number of carbon atoms thereof is preferably 1 or more and 20 or less, more preferably 1 or more and 15 or less, and particularly preferably 1 or more and 10 or less. Suitable examples of the alkyl group include a methyl group, an ethyl group, an n-propyl group, an isopropyl group, an n-butyl group, an isobutyl group, a sec-butyl group, a tert-butyl group, an n-pentyl group, an isopentyl group, a sec-pentyl group, a tert-pentyl group, an n-hexyl group, an n-heptyl group, an n-octyl group, an isooctyl group, a sec-octyl group, a tert-octyl group, an n-nonyl group, an isononyl group, an n-decyl group, an isodecyl group, and the like.

When the alkyl group is an alicyclic group or a group including an alicyclic group, examples of the alicyclic group included in the alkyl group include a monocyclic alicyclic group such as cyclopentyl group and cyclohexyl group, and a polycyclic alicyclic group such as adamantyl group, norbornyl group, isobornyl group, tricyclononyl group, and tetracyclododecyl group.

When a compound represented by the formula (a-4-1) has a chain group having an epoxy group as R^{a10}, specific examples of the compound represented by the formula (a-4-1) include (meth)acrylic acid epoxyalkyl esters such as glycidyl (meth)acrylate, 2-methyl glycidyl (meth)acrylate, 3,4-epoxybutyl (meth)acrylate, and 6,7-epoxyheptyl (meth)acrylate.

The compound represented by the formula (a-4-1) may be an alicyclic epoxy group-containing (meth)acrylic acid ester. An alicyclic group constituting the alicyclic epoxy group may be either monocyclic or polycyclic. Examples of the monocyclic alicyclic group include a cyclopentyl group, a cyclohexyl group, and the like. Examples of the polycyclic alicyclic group include a norbornyl group, an isobornyl group, a tricyclononyl group, a tricyclodecyl group, a tetracyclododecyl group, and the like.

When the compound represented by the formula (a-4-1) is an alicyclic epoxy group-containing (meth)acrylic acid ester, specific examples thereof include compounds represented by the following formulas (a-4-1a) to (a-4-1o). Among these compounds, compounds represented by the following formulas (a-4-1a) to (a-4-1e) are preferable, and compounds represented by the following formulas (a-4-1a) to (a-4-1c) are more preferable, so as to obtain appropriate developability.

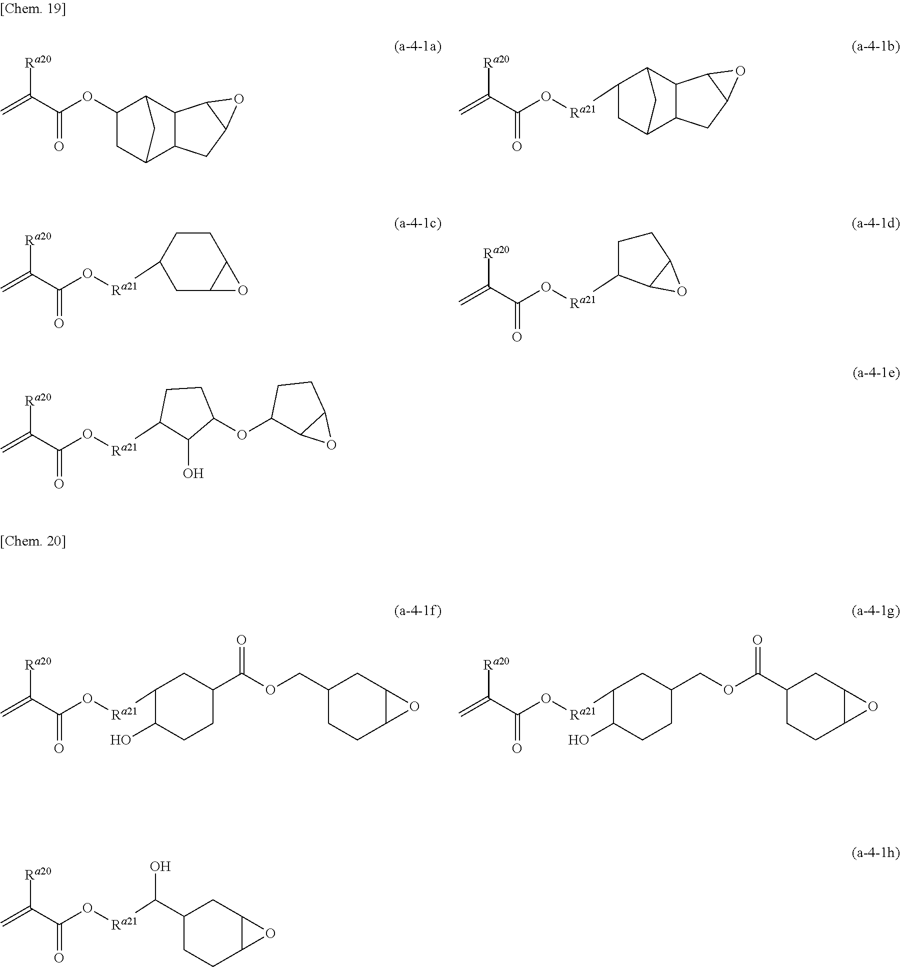

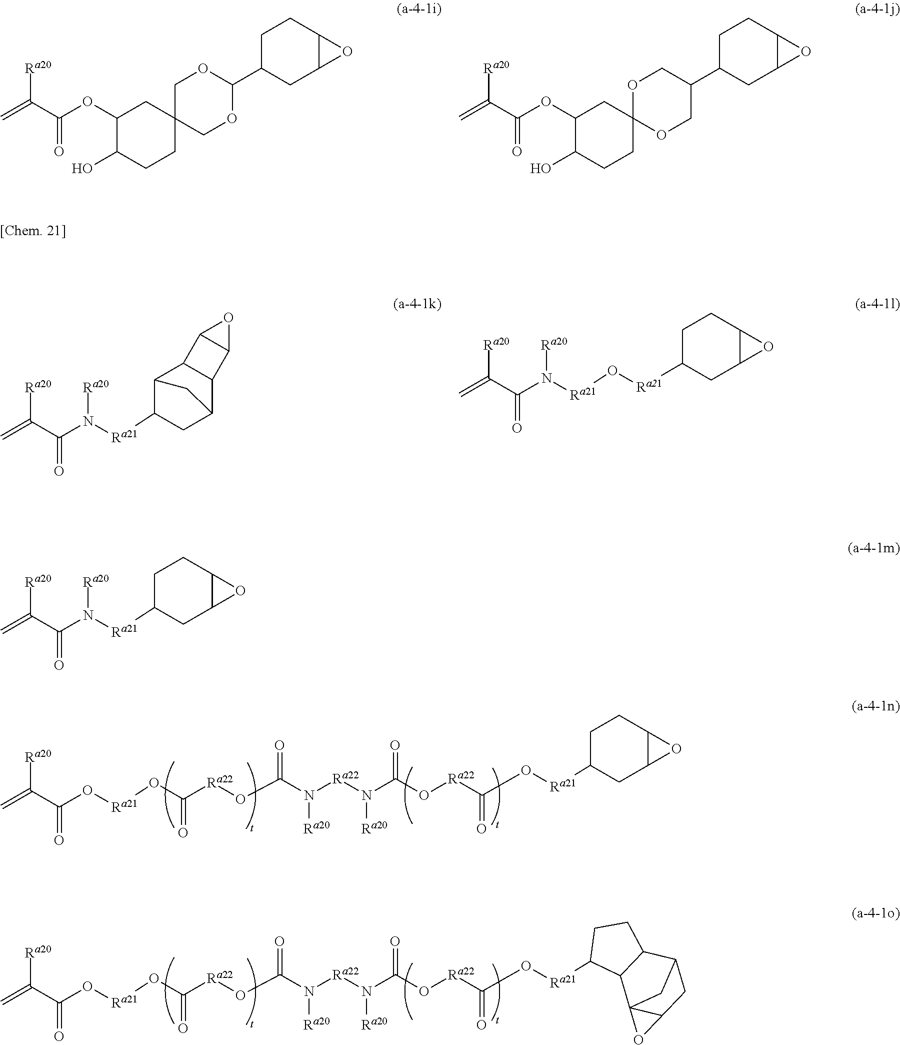

In the above formulas, R^{a20} represents a hydrogen atom or a methyl group, R^{a21} represents a divalent aliphatic saturated hydrocarbon group having 1 or more and 6 or less carbon atoms, R^{a22} represents a divalent hydrocarbon group having 1 or more and 10 or less carbon atoms, and t represents an integer of 0 or more and 10 or less. R^{a21} is preferably, a straight-chain or branched-chain alkylene group, for example, a methylene group, an ethylene group, a propylene group, a tetramethylene group, an ethylethylene group, a pentamethylene group, or a hexamethylene group. R^{a22} is preferably, for example, a methylene group, an ethylene group, a propylene group, a tetramethylene group, an ethylethylene group, a pentamethylene group, a hexamethylene group, a phenylene group, a cyclohexylene group, or —CH₂-Ph-CH₂— (Ph represents a phenylene group).

Furthermore, the acrylic resin (a-4) may be that in which a monomer other than (meth)acrylic acid is polymerized. Examples of such monomer include (meth)acrylamides, unsaturated carboxylic acids, allyl compounds, vinyl ethers, vinyl esters, styrenes, and the like. These monomers can be used alone or in combination of two or more types thereof.

Examples of (meth)acrylamides include (meth)acrylamide, N-alkyl(meth)acrylamide, N-aryl(meth)acrylamide, N,N-dialkyl(meth)acrylamide, N,N-diaryl(meth)acrylamide, N-methyl-N-phenyl(meth)acrylamide, N-hydroxyethyl-N-methyl(meth)acrylamide, and the like.

Examples of unsaturated carboxylic acids include mono carboxylic acids such as crotonic acid; dicarboxylic acids such as maleic acid, fumaric acid, citraconic acid, mesaconic acid, and itaconic acid; anhydrides of these dicarboxylic acids and the like.

Examples of the allyl compounds include allyl esters such as allyl acetate, allyl caproate, allyl caprylate, allyl laurate, allyl palmitate, allyl stearate, allyl benzoate, allyl acetoacetate, and allyl lactate; allyloxyethanol; and the like.

Examples of vinyl ethers include alkyl vinyl ethers such as hexyl vinyl ether, octyl vinyl ether, decyl vinyl ether, ethylhexyl vinyl ether, methoxyethyl vinyl ether, ethoxyethyl vinyl ether, chloroethyl vinyl ether, 1-methyl-2,2-dimethylpropyl vinyl ether, 2-ethylbutyl vinyl ether, hydroxyethyl vinyl ether, diethylene glycol vinyl ether, dimethylaminoethyl vinyl ether, diethylaminoethyl vinyl ether, butylaminoethyl vinyl ether, benzyl vinyl ether, and tetrahydrofurfuryl vinyl ether; vinylaryl ethers such as vinyl phenyl ether, vinyl tolyl ether, vinyl chlorophenyl ether, vinyl-2,4-dichlorophenyl ether, vinyl naphthyl ether, and vinyl anthranyl ether; and the like.

Examples of vinyl esters include vinyl butyrate, vinyl isobutyrate, vinyl trimethyl acetate, vinyl diethyl acetate, vinyl valerate, vinyl caproate, vinyl chloroacetate, vinyl dichloroacetate, vinyl methoxyacetate, vinyl butoxyacetate, vinyl phenylacetate, vinyl acetoacetate, vinyl lactate, vinyl-B-phenyl butyrate, vinyl benzoate, vinyl salicylate, vinyl chlorobenzoate, vinyl tetrachlorobenzoate, vinyl naphthoate, and the like.

Examples of styrenes include styrene; alkylstyrenes such as methylstyrene, dimethylstyrene, trimethylstyrene, ethylstyrene, diethylstyrene, isopropylstyrene, butylstyrene, hexylstyrene, cyclohexylstyrene, decylstyrene, benzylstyrene, chloromethylstyrene, trifluoromethylstyrene, ethoxymethylstyrene, and acetoxymethylstyrene; alkoxystyrenes such as methoxystyrene, 4-methoxy-3-methylstyrene, and dimethoxystyrene; halostyrenes such as chlorostyrene, dichlorostyrene, trichlorostyrene, tetrachlorostyrene, pentachlorostyrene, bromostyrene, dibromostyrene, iodostyrene, fluorostyrene, trifluorostyrene, 2-bromo-4-trifluoromethylstyrene, and 4-fluoro-3-trifluoromethylstyrene; and the like.

In the acrylic resin (a-4), the content of the constituent unit derived from (meth)acrylic acid and the content of the constituent unit derived from other monomers are not limited as long as the object of the present invention is not inhibited. In the acrylic resin (a-4), the content of the constituent unit derived from (meth)acrylic acid is preferably 5% by mass or more and 50% by mass or less, and more preferably 10% by mass or more and 30% by mass or less with respect to the mass of the acrylic resin (a-4).

When the acrylic resin (a-4) includes a constituent unit having an unsaturated double bond, the amount of the constituent unit having an unsaturated double bond in the acrylic resin (a-4) is preferably 1% by mass or more and 50% by mass or less, more preferably 1% by mass or more and 30% by mass or less, and particularly preferably 1% by mass or more and 20% by mass or less. When the acrylic resin (a-4) includes a constituent unit having an unsaturated double bond within the above range, it is possible to homogenize by incorporating an acrylic resin into a crosslinking reaction in a resist film, so that it is effective to improve the heat resistance and mechanical properties of the cured film.

The weight average molecular weight of the acrylic resin (a-4) is preferably 2,000 or more and 50,000 or less, and more preferably 3,000 or more and 30,000 or less. When the content is in the above-mentioned range, a balance of film-forming properties of the photosensitive composition and developing properties after exposure tends to be easily achieved.

In addition to the above, examples of the resin that corresponds to both the photopolymerizable resin (A1-1) and the alkali-soluble resin (A2-2) include a polyester (meth)acrylate obtained by reacting a (meth)acrylic acid with polyester prepolymer obtained by condensing a polyhydric alcohol and a monobasic acid or polybasic acid; a polyurethane (meth)acrylate obtained by reacting a (meth)acrylic acid with a reactant of a polyol and a compound having two isocyanate groups; an epoxy (meth)acrylate resin obtained by reacting a (meth)acrylic acid with an epoxy resin such as a bisphenol A type epoxy resin, a bisphenol S type epoxy resin, a phenol novolak type epoxy resin, a cresol novolak type epoxy resin, a resol type epoxy resin, a triphenolmethane type epoxy resin, a polycarboxylic acid polyglycidyl ester type epoxy resin, a polyol polyglycidyl ester type epoxy resin, an aliphatic epoxy resin, an alicyclic epoxy resin, an amine epoxy resin, dihydroxybenzene type epoxy resin; and the like.

The alkali-soluble resin (A1-2) and the resin that corresponds to both the photopolymerizable resin (A1-1) and the alkali-soluble resins (A1-2) are described above. Examples of a resin that does not correspond to the alkali-soluble resin (A1-2) and corresponds to the photopolymerizable resin (A1-1) include an unsaturated group-modified resin in which a group having an unsaturated double bond such as a (meth)acryloyl group, a vinyl, and an allyl group is introduced to a resin such as a polyacetal resin, a polyamide resin, a polycarbonate resin, a polyester resin (a polybutylene terephthalate, a polyethylene terephthalate, a polyarylate and the like), an FR-AS resin, an FR-ABS resin, an AS resin, an ABS resin, a polyphenylene oxide resin, a polyphenylene sulfide resin, a polysulfone resin, a polyethersulfone resin, a polyetheretherketone resin, a fluorine-based resin, a polyimide resin, a polyamide imide resin, a polyamide bismaleimide resin, a polyetherimide resin, a polybenzoxazole resin, a polybenzothiazole resin, a polybenzimidazole resin, a BT resin, a polymethylpentene, a ultra high molecular weight polyethylene, an FR-polypropylene, a (meth)acrylic resin (a polymethylmethacrylate and the like), and a polystyrene.

A method for unsaturated group-modification is not particularly limited. For example, a resin may be modified by copolymerization with a monomer having an unsaturated group. When a resin has a hydroxy group, an amino group, or the like, a group having an unsaturated double bond such as (meth)acryloyl group, vinyl group, and allyl group may be introduced to such functional groups.

### [Photopolymerizable Monomer (A2)]

The photosensitive composition may include a photopolymerizable monomer (A2) in combination with the aforementioned resin (A1). As the photopolymerizable monomer (A2), a compound conventionally added to a photosensitive composition can be used without any particular limitation.

Examples of the monofunctional photopolymerizable monomer include (meth)acrylamide, methylol (meth)acrylamide, methoxymethyl(meth)acrylamide, ethoxymethyl(meth)acrylamide, propoxymethyl(meth)acrylamide, butoxymethoxymethyl(meth)acrylamide, N-methylol (meth)acrylamide, N-hydroxymethyl(meth)acrylamide, (meth)acrylic acid, fumaric acid, maleic acid, maleic anhydride, itaconic acid, itaconic anhydride, citraconic acid, citraconic anhydride, crotonic acid, 2-acrylamide-2-methylpropanesulfonic acid, tert-butylacrylamide sulfonic acid, methyl (meth)acrylate, ethyl (meth)acrylate, butyl (meth)acrylate, 2-ethylhexyl (meth)acrylate, cyclohexyl (meth)acrylate, 2-hydroxyethyl (meth)acrylate, 2-hydroxypropyl (meth)acrylate, 2-hydroxybutyl (meth)acrylate, 2-phenoxy-2-hydroxypropyl (meth)acrylate, 2-(meth)acryloyloxy-2-hydroxypropyl phthalate, glycerol mono(meth)acrylate, tetrahydrofurfuryl (meth)acrylate, dimethylamino (meth)acrylate, glycidyl (meth)acrylate, 2,2,2-trifluoroethyl (meth)acrylate, 2,2,3,3-tetrafluoropropyl (meth)acrylate, and half (meth)acrylates of phthalic acid derivatives. These monofunctional p photopolymerizable monomers may be used individually, or two or more thereof may be used in combination.

Examples of the polyfunctional photopolymerizable monomer include polyfunctional monomers such as ethylene glycol di(meth)acrylate, diethylene glycol di(meth)acrylate, tetraethylene glycol di(meth)acrylate, propylene glycol di(meth)acrylate, polypropylene glycol di(meth)acrylate, butylene glycol di(meth)acrylate, neopentyl glycol di(meth)acrylate, 1,6-hexane glycol di(meth)acrylate, trimethylolpropane tri(meth)acrylate, glycerol di(meth)acrylate, pentaerythritol triacrylate, pentaerythritol tetraacrylate, dipentaerythritol pentaacrylate, dipentaerythritol hexaacrylate, pentaerythritol di(meth)acrylate, pentaerythritol tri(meth)acrylate, pentaerythritol tetra(meth)acrylate, dipentaerythritol penta(meth)acrylate, dipentaerythritol hexa(meth)acrylate, 2,2-bis(4-(meth)acryloxydiethoxyphenyl)propane, 2,2-bis(4-(meth)acryloxypolyethoxyphenyl)propane, 2-hydroxy-3-(meth)acryloyloxypropyl (meth)acrylate, ethylene glycol diglycidyl ether di(meth)acrylate, diethylene glycol diglycidyl ether di(meth)acrylate, phthalic acid diglycidyl ester di(meth)acrylate, glycerol triacrylate, glycerol polyglycidyl ether poly(meth)acrylate, urethane (meth)acrylate (in other words, a tolylene diisocyanate), reaction product of, trimethylhexamethylene diisocyanate, hexamethylene diisocyanate, and 2-hydroxyethyl (meth)acrylate, methylenebis(meth)acrylamide, (meth)acrylamide methylene ether, condensates of a polyhydric alcohol and N-methylol (meth)acrylamide, triacrylformal, and the like. These polyfunctional p photopolymerizable monomers may be used individually, or two or more thereof may be used in combination.

Furthermore, from the viewpoint of easiness in forming the cured product with high refractive index, a compound represented by the following formula (a-01) is also preferable as the photopolymerizable monomer (A2).

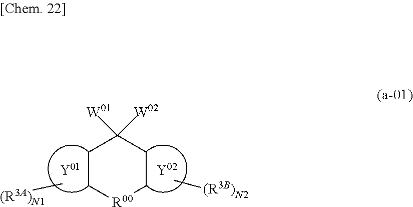

In the formula (a-01), W⁰¹ and W⁰² are each independently a group represented by the following formula (a-02).

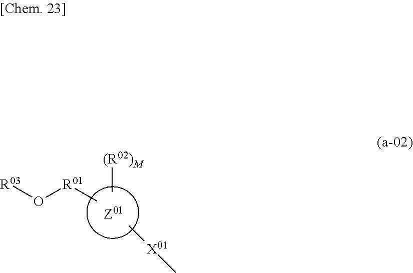

In the formula (a-02), a ring Z⁰¹ represents an aromatic hydrocarbon ring; X⁰¹ represents a single bond or a group represented by —S—; R⁰¹ represents a single bond, an alkylene group having 1 or more and 4 or less carbon atoms, or an alkyleneoxy group having 1 or more and 4 or less carbon atoms, and optionally substituted with a hydroxy group, when R⁰¹ is an alkyleneoxy group, an oxygen atom in the alkyleneoxy group is bonded to the ring Z⁰¹, and R⁰² is a monovalent hydrocarbon group, a hydroxyl group, a group represented by —OR^{4A}, a group represented by —SR^{4B}, an acyl group, an alkoxycarbonyl group, a halogen atom, a nitro group, a cyano group, a mercapto group, a carboxy group, an amino group, carbamoyl group, a group represented by —NHR^{4C}, a group represented by —N(R^{4D})₂, a sulfo group, or a monovalent hydrocarbon group, a group represented by —OR^{4A}, a group represented by —SR^{4B}, an acyl group, an alkoxycarbonyl group, a halogen atom, a nitro group, a cyano group, a mercapto group, a carboxyl group, an amino group, a carbamoyl group, a group represented by —NHR^{4C}, a group represented by —N(R^{4D})₂, a mesyloxy group, or a group substituted with a sulfo group; R^{4A} to R^{4D} each independently represent a monovalent hydrocarbon group; M represents an integer of 0 or more; R⁰³ is a hydrogen atom, a vinyl group, or a (meth)acryloyl group, and at least one of 2 R⁰³s is the vinyl group or the (meth)acryloyl group;

both W⁰¹ and W⁰² do not have a hydrogen atom as R⁰³;
a ring Y⁰¹ and a ring Y⁰², which may be the same or different, represent an aromatic hydrocarbon ring; R⁰⁰ represents a single bond, an optionally substituted methylene group, an ethylene group that is optionally substituted and may contain a hetero atom between two carbon atoms, a group represented by —O—, a group represented by —NH—, or a group represented by —S—; R^{3A} and R^{3B} each independently represent a cyano group, a halogen atom, or a monovalent hydrocarbon group; and N1 and N2 each independently represent an integer of 0 to 4.

In the formula (a-02), examples of the ring Z⁰¹ include benzene rings and fused polycyclic aromatic hydrocarbon rings [for example, fused di- to tetracyclic aromatic hydrocarbon rings such as fused dicyclic hydrocarbon rings (for example, C₈₋₂₀ fused dicyclic hydrocarbon rings, preferably C¹⁰-16 fused dicyclic hydrocarbon rings, such as naphthalene rings) and fused tricyclic aromatic hydrocarbon rings (for example, anthracene rings or phenanthrene rings)]. The ring Z⁰¹ is preferably a benzene ring or a naphthalene ring, more preferably a naphthalene ring. Because W⁰¹ and W⁰² in the formula (a-01) are each independently a group represented by the formula (a-02), W⁰¹ and W⁰² each include the ring Z⁰¹. The ring Z⁰¹ included in W⁰¹ and the ring Z⁰² included in W⁰² may be the same as or different from each other. For example, one of the rings may represent a benzene ring with the other ring representing a naphthalene ring or the like. Particularly preferably, both the rings represent a naphthalene ring.

Furthermore, the position of substitution of the ring Z⁰¹ bonded through X⁰¹ to a carbon atom to which both W⁰¹ and W⁰² are directly connected is not particularly limited. For example, when the ring Z⁰¹ represents a naphthalene ring, the group corresponding to the ring Z⁰¹ bonded to the carbon atom may be, for example, a 1-naphthyl group or a 2-naphthyl group.

In the formula (a-02), X⁰¹ independently represents a single bond or a group represented by —S—, and typically a single bond.

In the formula (a-02), suitable examples of the R⁰¹ include, a single bond; an alkylene group having 1 or more and 4 or less carbon atoms such as a methylene group, a trimethylene group, a propylene group, a butane-1,2-diyl group; an alkyleneoxy group having 1 or more and 4 or less carbon atoms optionally substituted with a hydroxy group such as —CH₂—O— (methyleneoxy group), —CH₂CH₂—O— (ethyleneoxy group), —CH₂CH₂CH₂—O— (propyleneoxy group), and —CH₂CH(OH)CH₂—O—. Note here that when R⁰¹ is an alkyleneoxy group, an oxygen atom in the alkyleneoxy group is bonded to the ring Z⁰¹. Furthermore, since W⁰¹ and W⁰² in the formula (a-01) are each independently a group represented by the following formula (b-02), W⁰¹ and W⁰² each include R⁰¹ as a divalent group. R⁰¹ included in W⁰¹ and R⁰¹ included in W⁰² may be the same as or different from each other.

In the formula (a02), examples of R⁰² include monovalent hydrocarbon groups such as alkyl groups (for example, C₁₋₁₂ alkyl groups, preferably C₁₋₈ alkyl groups, more preferably C₁₋₆ alkyl groups such as methyl, ethyl, propyl, isopropyl, and butyl groups), cycloalkyl groups (for example, C₅₋₁₀ cycloalkyl groups, preferably C₅₋₈ cycloalkyl groups, more preferably C₅₋₆ cycloalkyl groups such as cyclohexyl groups), aryl groups (for example, C₆₋₁₄ aryl groups, preferably C₆₋₁₀ aryl groups, more preferably C₆₋₈ aryl groups such as phenyl, tolyl, xylyl, and naphthyl groups), and aralkyl groups (for example, C₆₋₁₀ aryl-C₁₋₄ alkyl groups such as benzyl and phenethyl groups); hydroxyl groups; groups represented by —OR^{4A} [wherein, in the formula, R^{4A} represents a monovalent hydrocarbon group (for example, the above-exemplified monovalent hydrocarbon group)] such as alkoxy groups (for example, C₁₋₁₂ alkoxy groups, preferably C₁₋₈ alkoxy groups, more preferably C₁₋₆ alkoxy groups, such as methoxy, ethoxy, propoxy, and butoxy groups), cycloalkoxy groups (C₅₋₁₀ cycloalkoxy groups such as cyclohexyloxy groups), aryloxy groups (C₆₋₁₀ aryloxy groups such as phenoxy group), and aralkyloxy groups (for example, C₆₋₁₀ aryl-C₁₋₄ alkyloxy groups such as benzyloxy groups); groups represented by —SR^{4B} [wherein, in the formula, R^{4B} represents a monovalent hydrocarbon group (for example, the above-exemplified monovalent hydrocarbon group)] such as alkylthio groups (for example, C₁₋₁₂ alkylthio groups, preferably C₁₋₈ alkylthio groups, more preferably C₁₋₆ alkylthio groups such as methylthio, ethylthio, propylthio, and butylthio groups), cycloalkylthio groups (for example, C₅₋₁₀ cycloalkylthio groups such as cyclohexylthio groups), aryl thio groups (C₆₋₁₀ aryl thio groups such as phenylthio groups), and aralkylthio groups (for example, C₆₋₁₀ aryl-C₁₋₄ alkylthio groups such as benzylthio groups); acyl groups (C₁₋₆ acyl groups such as acetyl groups); alkoxycarbonyl groups (for example, C₁₋₄ alkoxycarbonyl groups such as methoxycarbonyl group); halogen atoms (a fluorine atom, a chlorine atom, a bromine atom, an iodine atom, and the like); nitro groups; cyano groups; mercapto groups; carboxyl groups; amino groups; carbamoyl groups; groups represented by —NHR^{4C} [wherein, in the formula, R^{4C} represents a monovalent hydrocarbon group (for example, the above-exemplified monovalent hydrocarbon group)] such as alkylamino groups (C₁₋₁₂ alkylamino groups, preferably C₁₋₈ alkylamino groups, more preferably C₁₋₆ alkylamino groups such as methylamino groups, ethylamino groups, propylamino groups, and butylamino groups), cycloalkylamino groups (for example, C₅₋₁₀ cycloalkylamino groups such as cyclohexylamino groups), arylamino groups (C₆₋₁₀ aryl amino groups such as phenylamino groups), and aralkyl amino groups (for example, C₆₋₁₀ aryl-C₁₋₄ alkylamino groups such as benzylamino groups); groups represented by —N(R^{4D})₂[wherein each R^{4D} independently represents a monovalent hydrocarbon group (for example, the above-exemplified monovalent hydrocarbon group)] such as dialkylamino groups (di(C₁₋₁₂ alkyl)amino groups, preferably di(C₁₋₈ alkyl)amino groups, more preferably di(C₁₋₆ alkyl)amino groups such as dimethylamino groups, diethylamino groups, dipropylamino groups, and dibutylamino groups), dicycloalkylamino groups (di(C₅₋₁₀ cycloalkyl)amino groups such as dicyclohexylamino groups), diaryl amino groups (di(C₆₋₁₀ aryl)amino groups such as diphenylamino groups), and diaralkyl amino groups (for example, di(C₆₋₁₀ aryl C₁₋₄ alkyl)amino groups such as dibenzylamino groups); (meth)acryloyloxy groups; sulfo groups; and the above monovalent hydrocarbon groups, groups represented by —OR^{4A}, groups represented by —SR^{4B}, acyl groups, alkoxycarbonyl groups, groups represented by —NHR^{4C}, or groups obtained by substituting at least a part of hydrogen atoms bonded to carbon atoms contained in groups represented by —N(R^{4D})₂ with the above monovalent hydrocarbon group, a hydroxyl group, a group represented by —OR^{4A}, a group represented by —SR^{4B}, an acyl group, an alkoxycarbonyl group, a halogen atom, a nitro group, a cyano group, a mercapto group, a carboxyl group, an amino group, a carbamoyl group, a group represented by —NHR^{4C}, a group represented by —N(R^{4D})₂, a (meth)acryloyloxy group, a mesyloxy group, or a sulfo group [for example, alkoxyaryl groups (for example, C₁₋₄ alkoxy C₆₋₁₀ aryl groups such as methoxyphenyl groups), alkoxycarbonylaryl groups (for example, C₁₋₄ alkoxycarbonyl C₆₋₁₀ aryl groups such as methoxycarbonylphenyl groups and ethoxycarbonylphenyl groups)].

Among them, typical examples of R⁰² include monovalent hydrocarbon groups, groups represented by —OR^{4A}, groups represented by —SR^{4B}, acyl groups, alkoxycarbonyl groups, halogen atoms, nitro group, cyano groups, groups represented by —NHR^{4C}, and groups represented by —N(R^{4D})₂.

Examples of preferred R⁰² include monovalent hydrocarbon groups [for example, alkyl groups (for example, C₁₋₆ alkyl groups), cycloalkyl groups (for example, C₅₋₈ cycloalkyl groups), aryl groups (for example, C₆₋₁₀ aryl groups), and aralkyl groups (for example, C₆₋₈ aryl-C₁₋₂ alkyl groups)], and alkoxy groups (for example, C₁₋₄ alkoxy groups). In particular, preferably, R⁰² represent a monovalent hydrocarbon group such as an alkyl group [for example, a C₁₋₄ alkyl group (particularly a methyl group)], an aryl group [for example, a C₆₋₁₀ aryl group (particularly a phenyl group)] (particularly an alkyl group).

Note here that when M is an integer of 2 or more, a plurality of R⁰²s may be different from or the same as each other. R⁰² included in W⁰¹ may be the same as or different from R⁰² included in W⁰².

In the formula (a-02), the number of R⁰²s, that is, M, may be selected according to the type of the ring Z⁰¹ and may be, for example, 0 or more and 4 or less, preferably 0 or more and 3 or less, more preferably or more and 2 or less. Note here that M in W⁰¹ may be the same as or different from M in W⁰².

In the formula (a-02), R⁰³ represents a hydrogen atom, a vinyl group, or a (meth)acryloyl group. At least one of R⁰³s are the vinyl group or the (meth)acryloyl group. Note here that both W⁰¹ and W⁰² do not have a hydrogen atom as R⁰³.

R⁰³ in W⁰¹ and R⁰³ in W⁰² may be the same as or different from each other as long as both are not a hydrogen atom. It is preferable that both of R⁰³ in W⁰¹ and R⁰³ in W⁰² are the (meth)acryloyl group.

R⁰³ is preferably a vinyl group or a (meth)acryloyl group since it is easy to synthesize and obtain the compound represented by the formula (a-01).

In the formula (a-01), examples of the rings Y⁰¹ and Y⁰² includes a benzene ring and a fused polycyclic aromatic hydrocarbon ring [for example, a fused di- to tetracyclic aromatic hydrocarbon ring, such as a fused dicyclic hydrocarbon ring (e.g., a C₈₋₂₀ fused dicyclic hydrocarbon ring such as a naphthalene ring, and preferably a C₁₀₋₁₆ fused dicyclic hydrocarbon ring), and a fused tricyclic aromatic hydrocarbon ring (e.g., an anthracene ring, a phenanthrene ring, etc.). The rings Y⁰¹ and Y⁰² are preferably a benzene ring or a naphthalene ring, and more preferably a benzene ring. The rings Y⁰¹ ring Y⁰² may be the same or different and, for example, one ring may be a benzene ring and the other ring may be a naphthalene ring.

In the formula (a-01), R⁰⁰ is a single bond, a methylene group which may have a substituent, an ethylene group which may have a substituent and including a heteroatom between two carbon atoms, a group represented by —O—, a group represented by —NH—, or a group represented by —S—, and typically a single bond. Examples of the substituents include a cyano group, a halogen atom (a fluorine atom, a chlorine atom, a bromine atom, and the like), a monovalent hydrocarbon group [for example, an alkyl group (C₁₋₆ alkyl groups such as a methyl group, an ethyl group, a propyl group, an isopropyl group, a butyl group, and a t-butyl group), an aryl group (C₆₋₁₀ aryl groups such as a phenyl group)], and the like. Examples of the hetero atom include an oxygen atom, a nitrogen atom, a sulfur atom, a silicon atom, and the like.

In the formula (a-01), as R^{3A} and R^{3B}, usually, a non-reactive substituent such as a cyano group, a halogen atom (such as a fluorine atom, a chlorine atom, and a bromine atom), a monovalent hydrocarbon group [such as an alkyl group, an aryl group (C₆₋₁₀ aryl groups such as a phenyl group)] is exemplified, a cyano group and an alkyl group are preferred, and an alkyl group is particularly preferred. As the alkyl group, C₁₋₆ alkyl groups such as a methyl group, an ethyl group, a propyl group, an isopropyl group, a butyl group (for example, C₁₋₄ alkyl groups, particularly a methyl group) are exemplified. When N1 is an integer of 2 or more, R^{3A}s may be different from each other or the same as. In addition, when N2 is an integer of 2 or more, R^{3B}s may be different from each other or the same as. Furthermore, R^{3A} and R^{3B} may be the same as or different from each other. There is no particular limitation on the bonding position (substitution position) of R^{3A} and R^{3B} on the rings Y⁰¹ and Y⁰². The substitution number N1 and N2 is preferably 0 or 1, and particularly 0. N1 and N2 may be the same or different with each other.

The compound represented by the formula (a-01) has high reactivity, while maintaining excellent optical properties and thermal properties. Particularly, when the rings Y⁰¹ and Y⁰² are benzene rings and R⁰⁰ is a single bond, the compound represented by the formula (a-01) has a fluorene skeleton and is more excellent in optical properties and thermal properties. Furthermore, the compound represented by the formula (a1) gives a cured product having high hardness.

Among compounds represented by the above formula (a-01), particularly suitable examples include the following compounds.

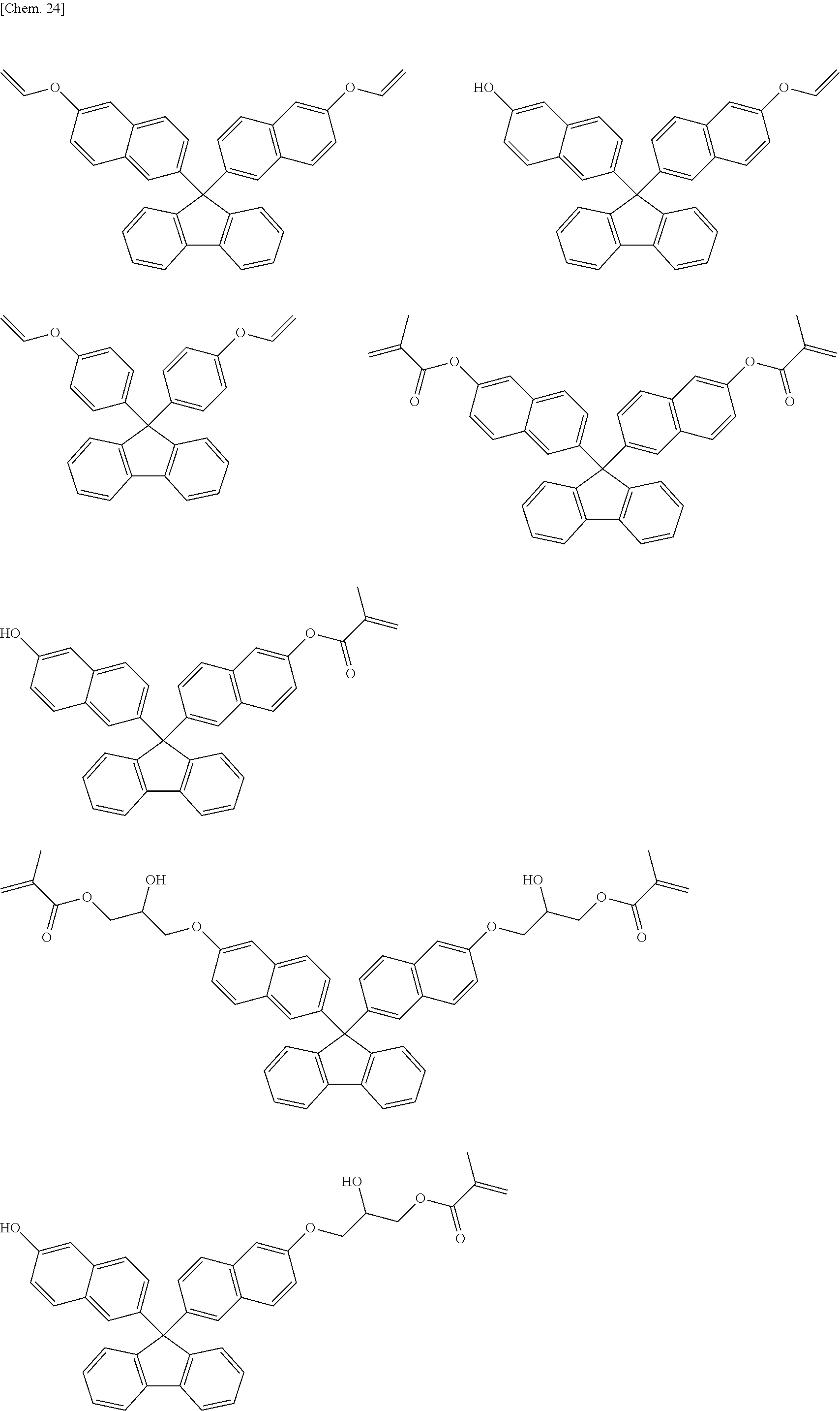

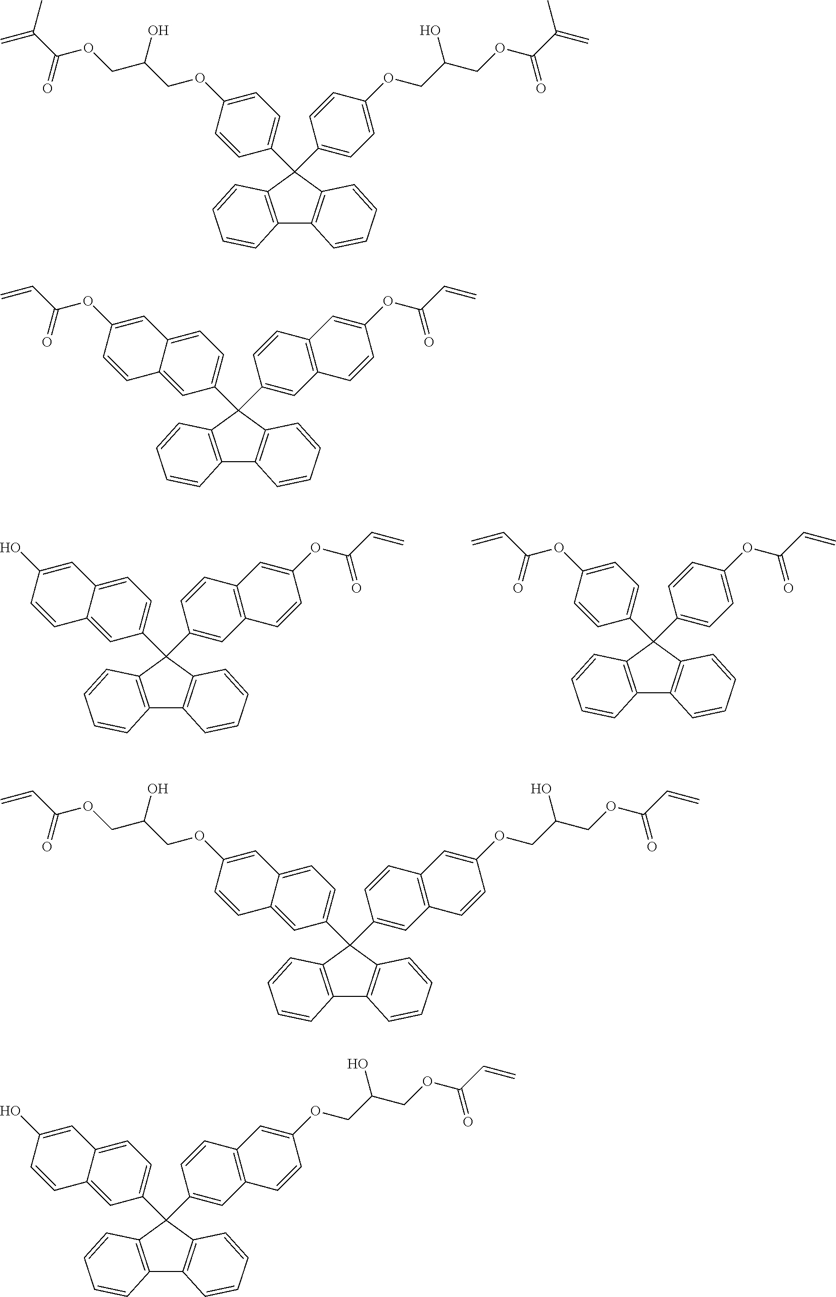

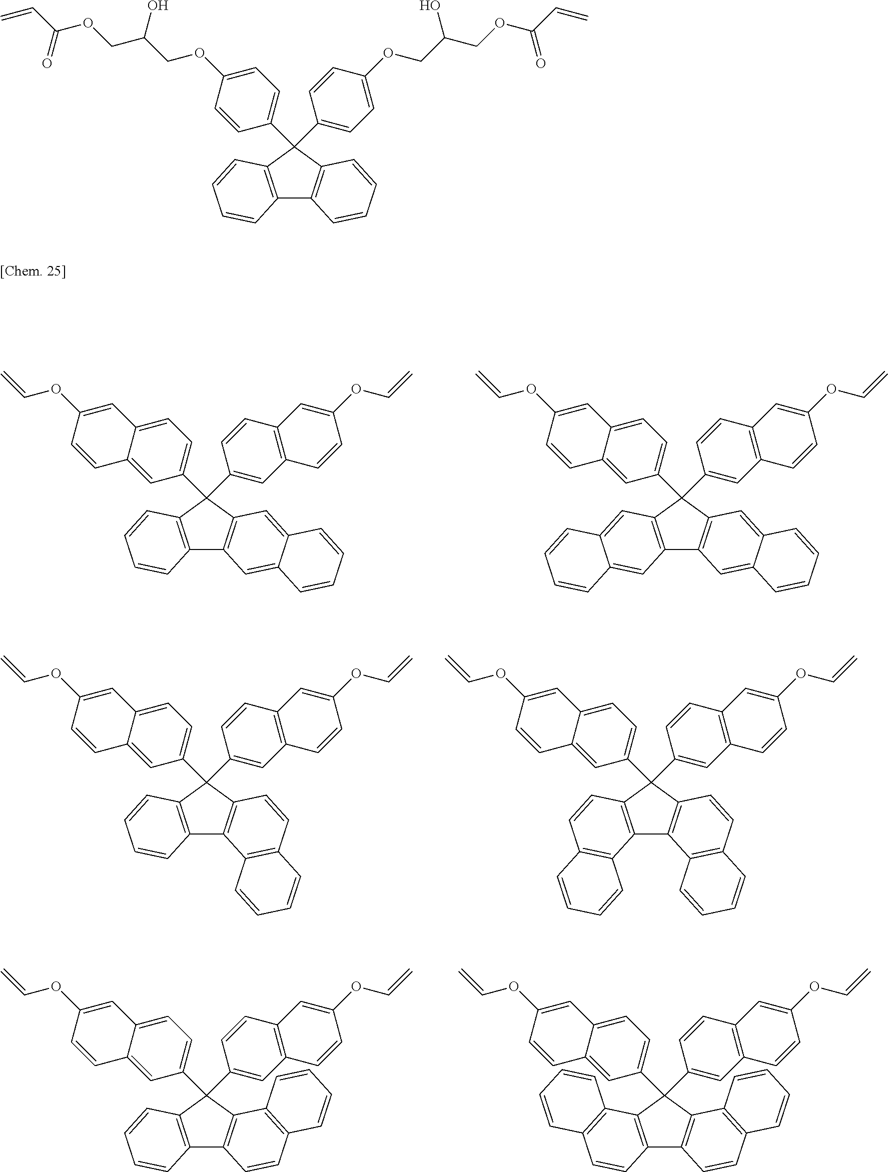

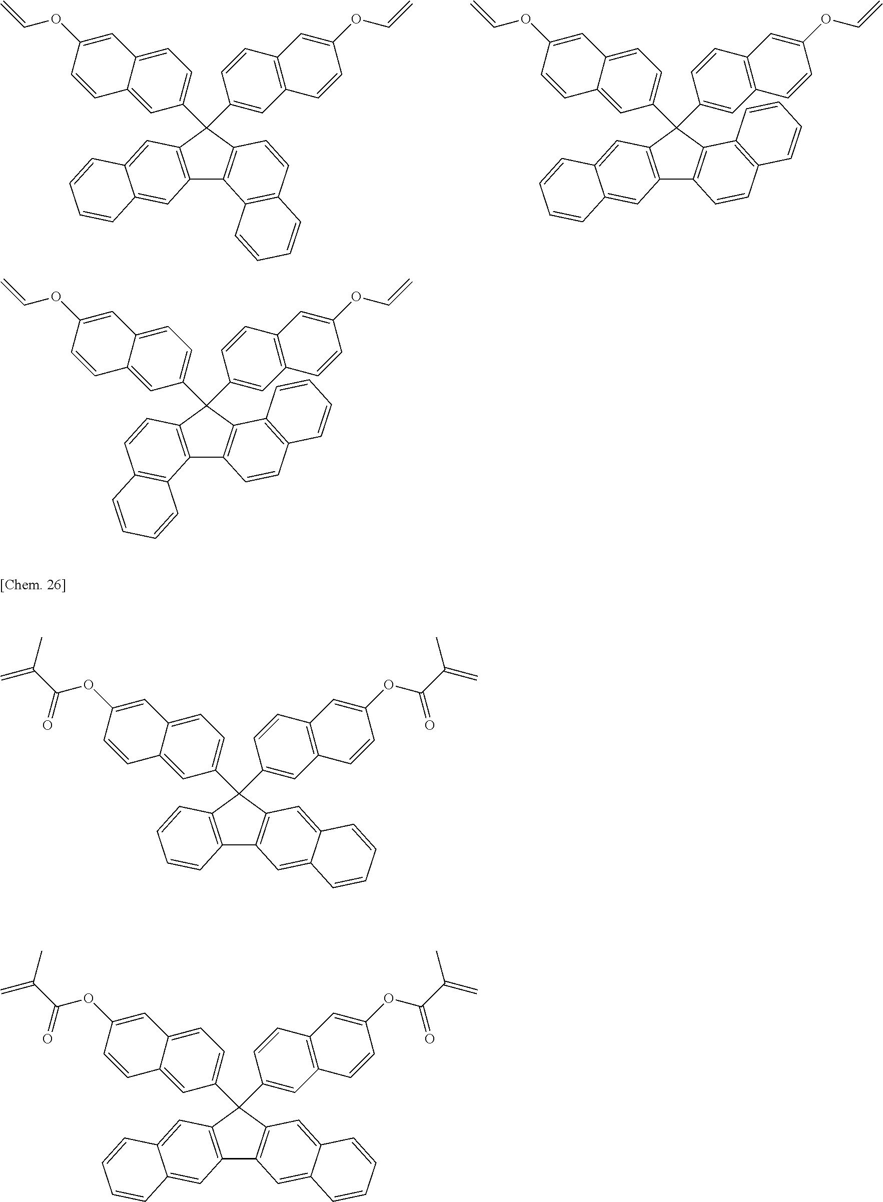 [SMILES: C=COc1ccc2cc(C3(c4ccc5cc(OC=C)ccc5c4)c4cc5ccccc5cc4-c4c3ccc3ccccc43)ccc2c1 ; C=COc1ccc2cc(C3(c4ccc5cc(OC=C)ccc5c4)c4cc5ccccc5cc4-c4ccc5ccccc5c43)ccc2c1 ; C=COc1ccc2cc(C3(c4ccc5cc(OC=C)ccc5c4)c4ccc5ccccc5c4-c4ccc5ccccc5c43)ccc2c1 ; C=C(C)C(=O)Oc1ccc2cc(C3(c4ccc5cc(OC(=O)C(=C)C)ccc5c4)c4ccccc4-c4cc5ccccc5cc43)ccc2c1 ; C=C(C)C(=O)Oc1ccc2cc(C3(c4ccc5cc(OC(=O)C(=C)C)ccc5c4)c4cc5ccccc5cc4-c4cc5ccccc5cc43)ccc2c1]

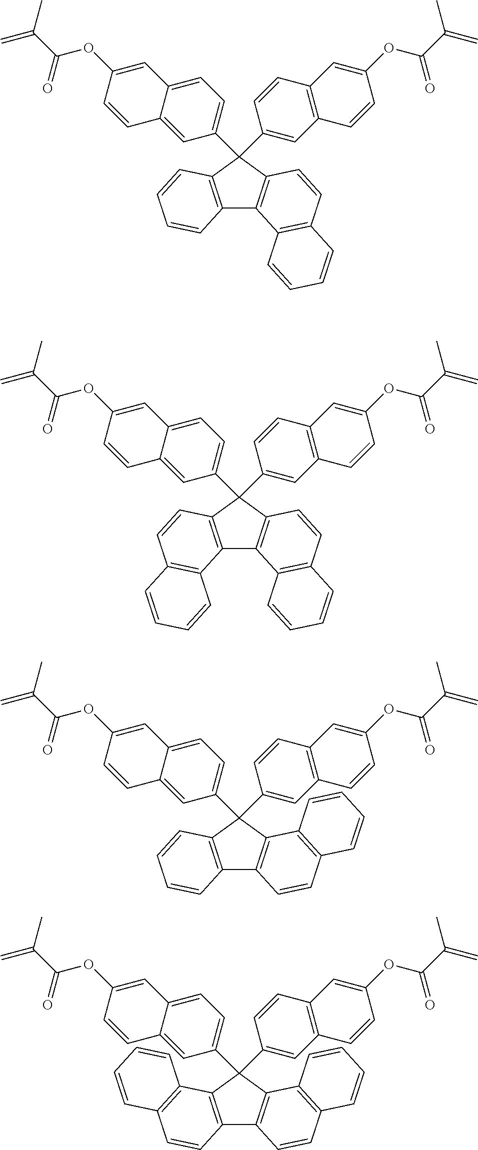

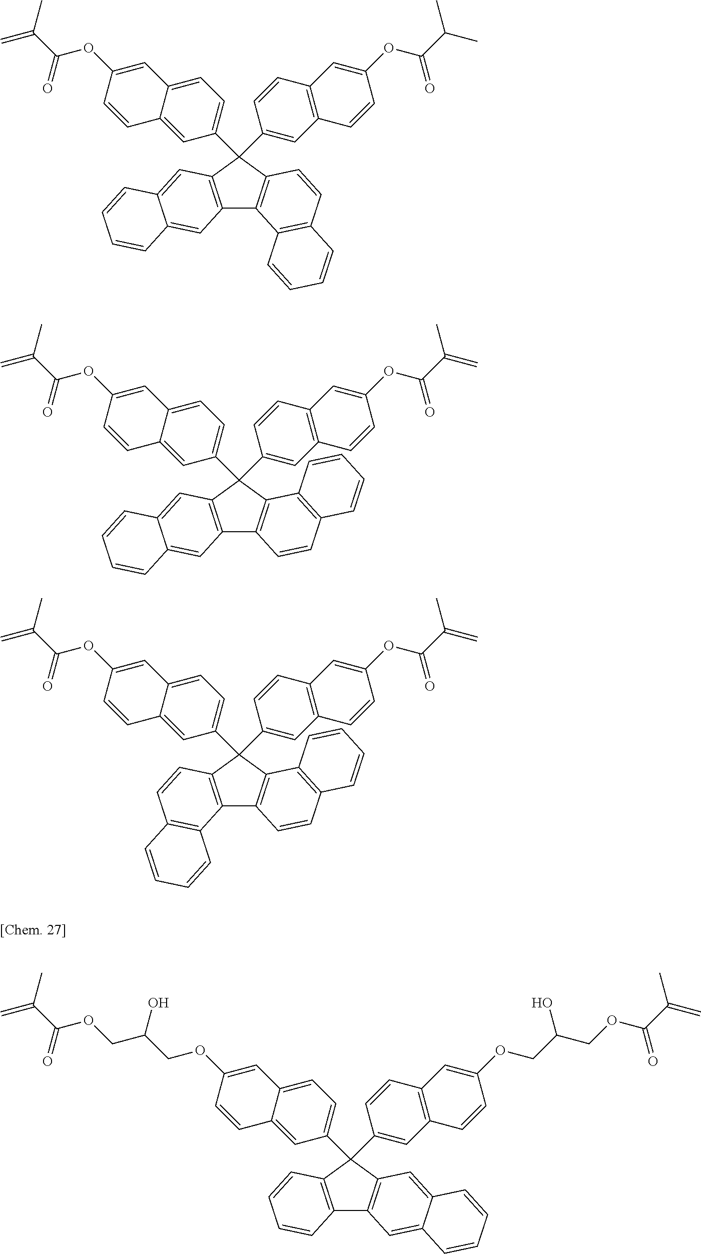

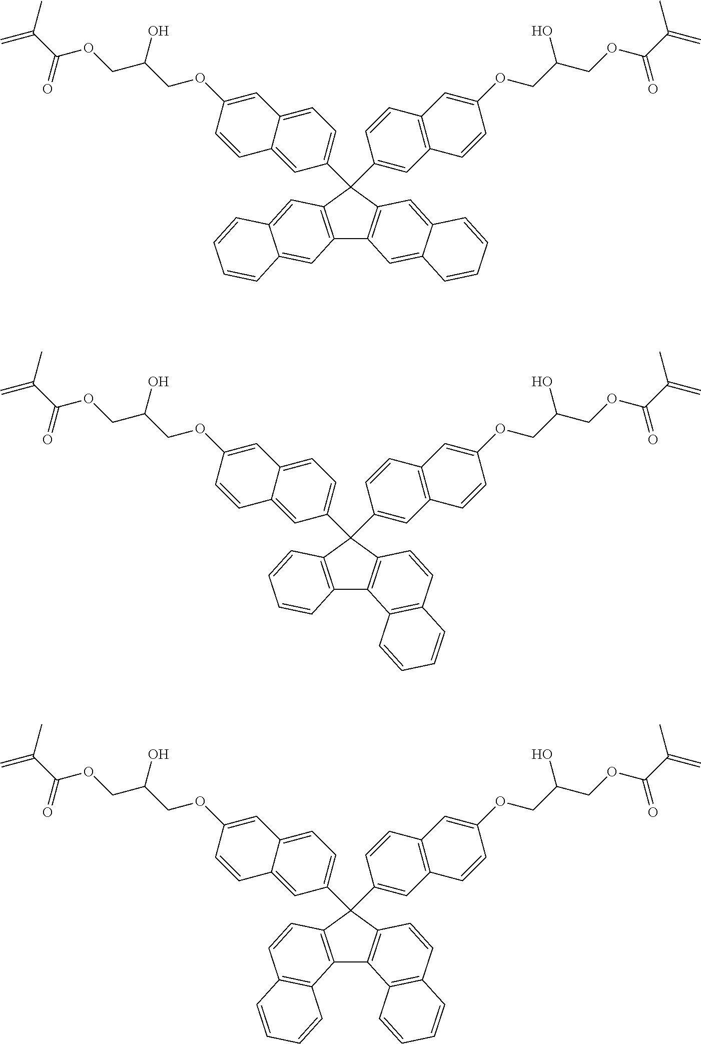

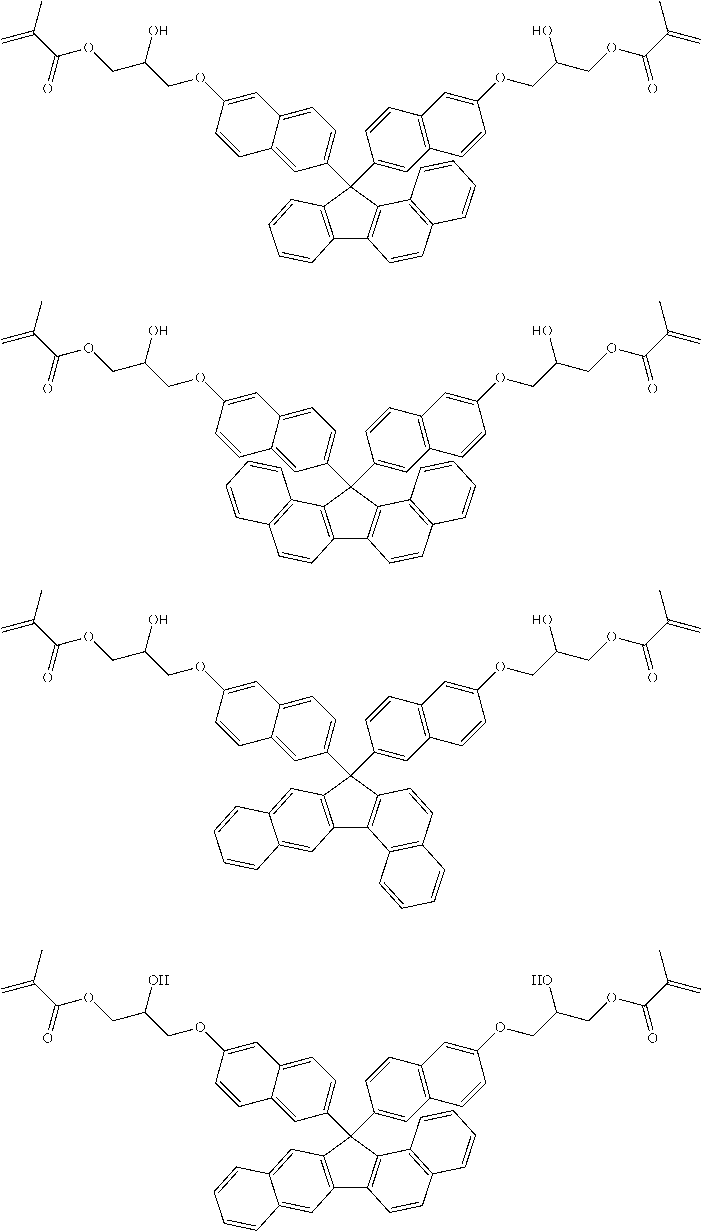

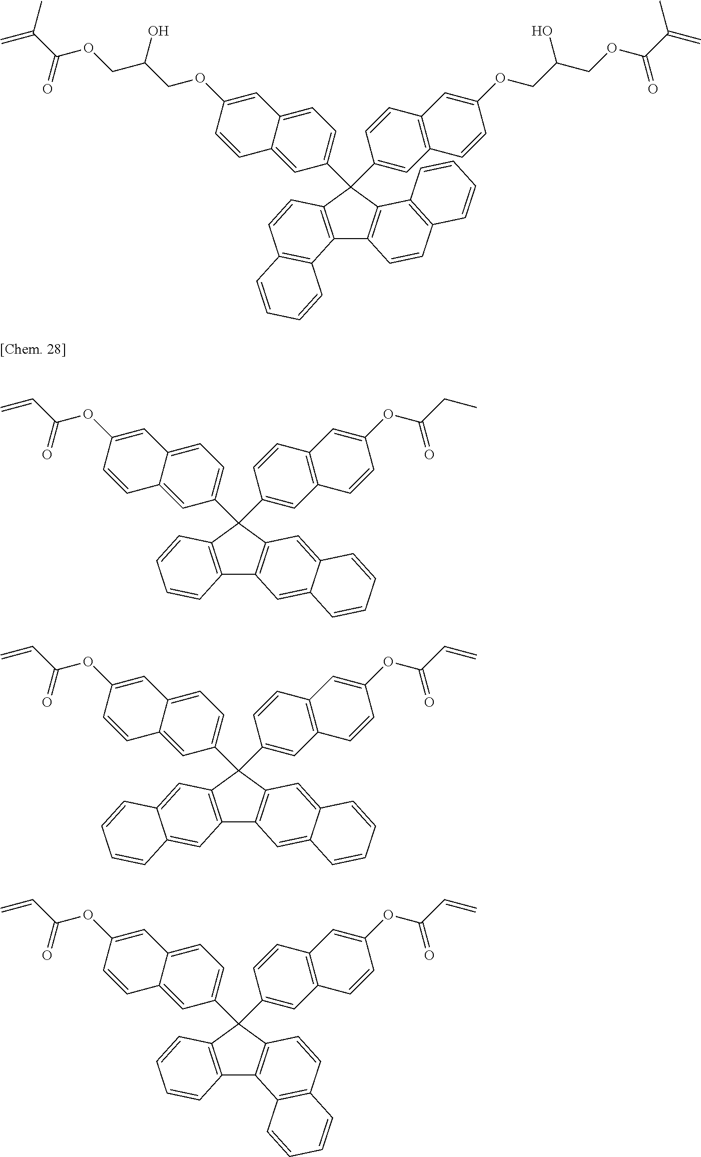

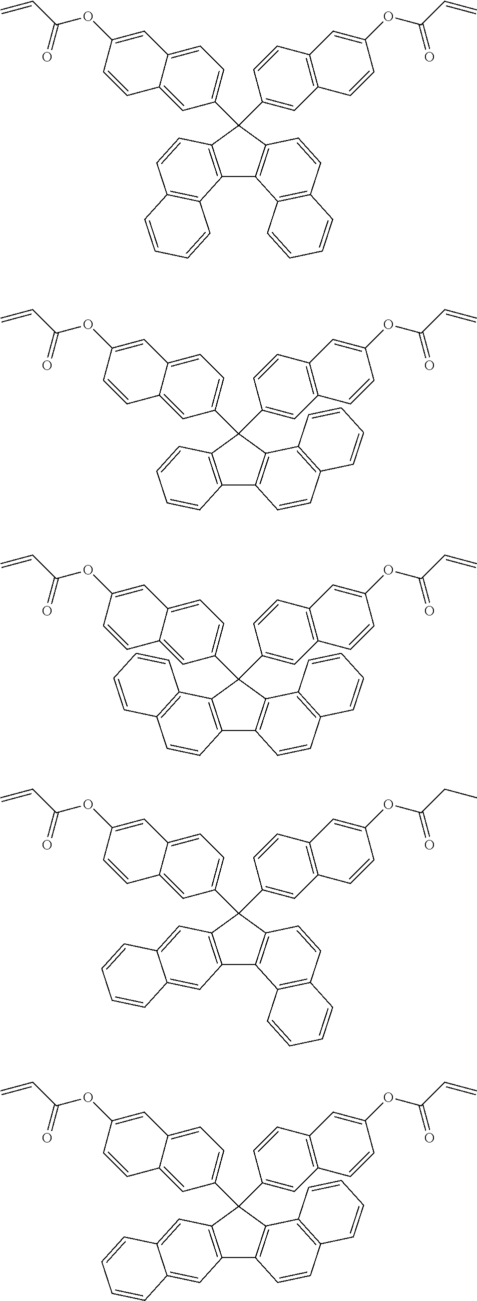

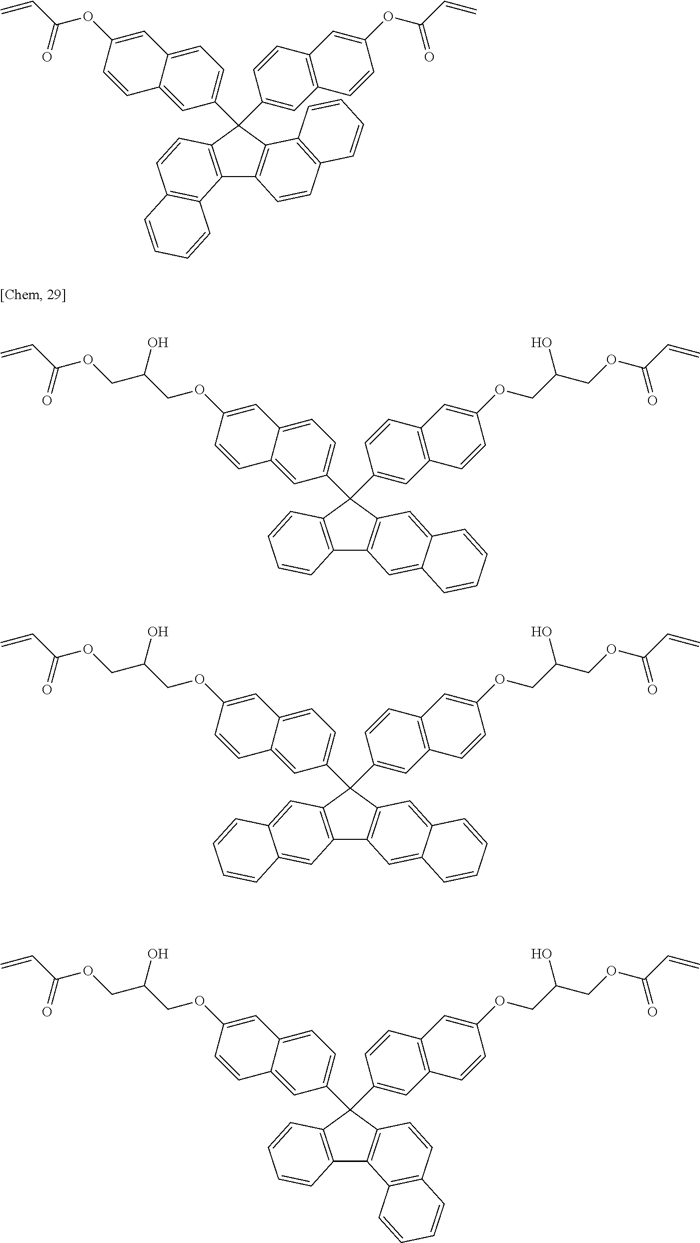

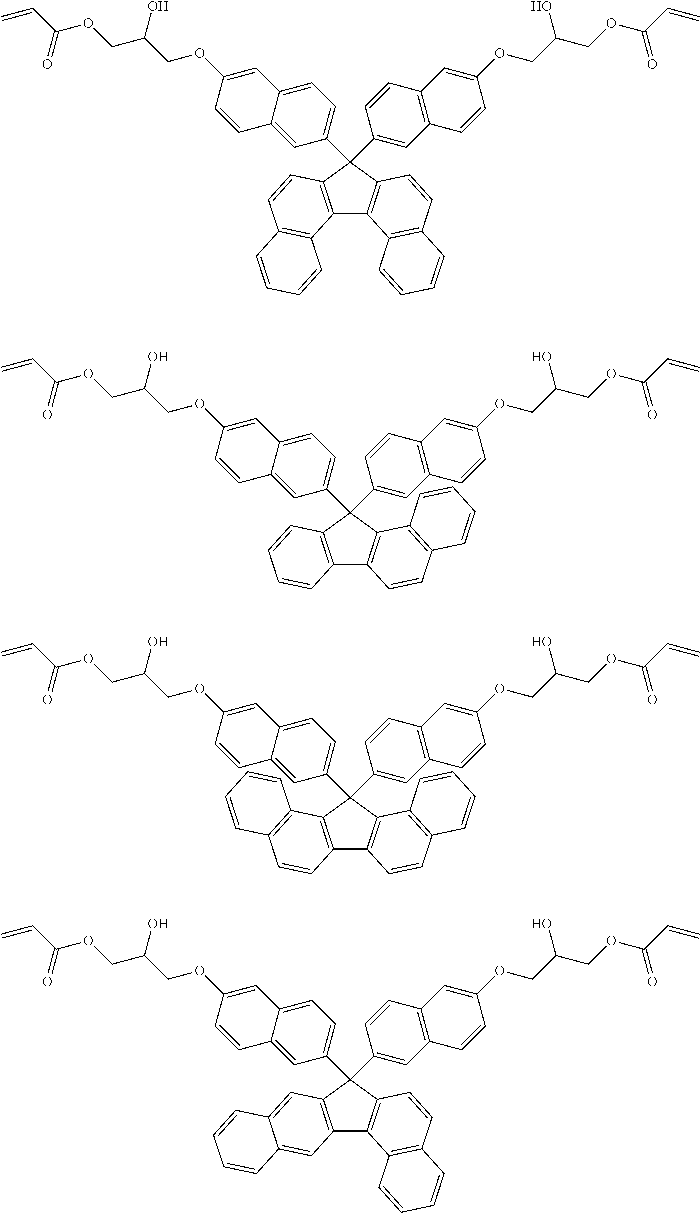

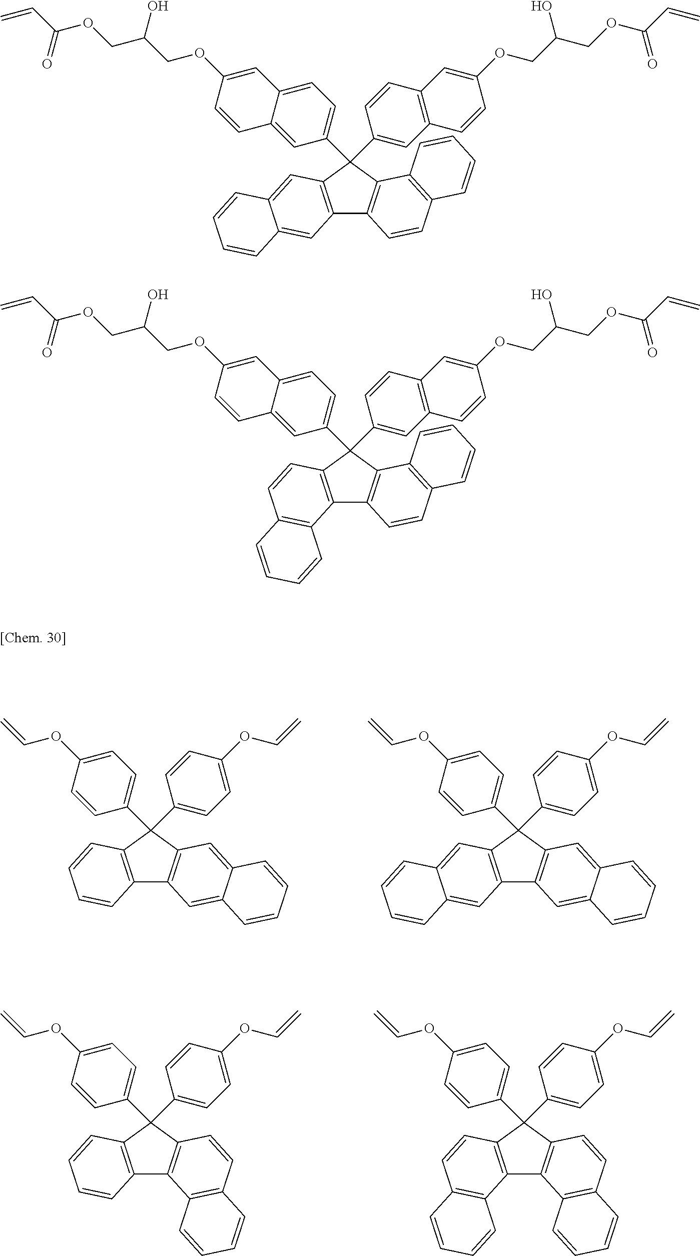

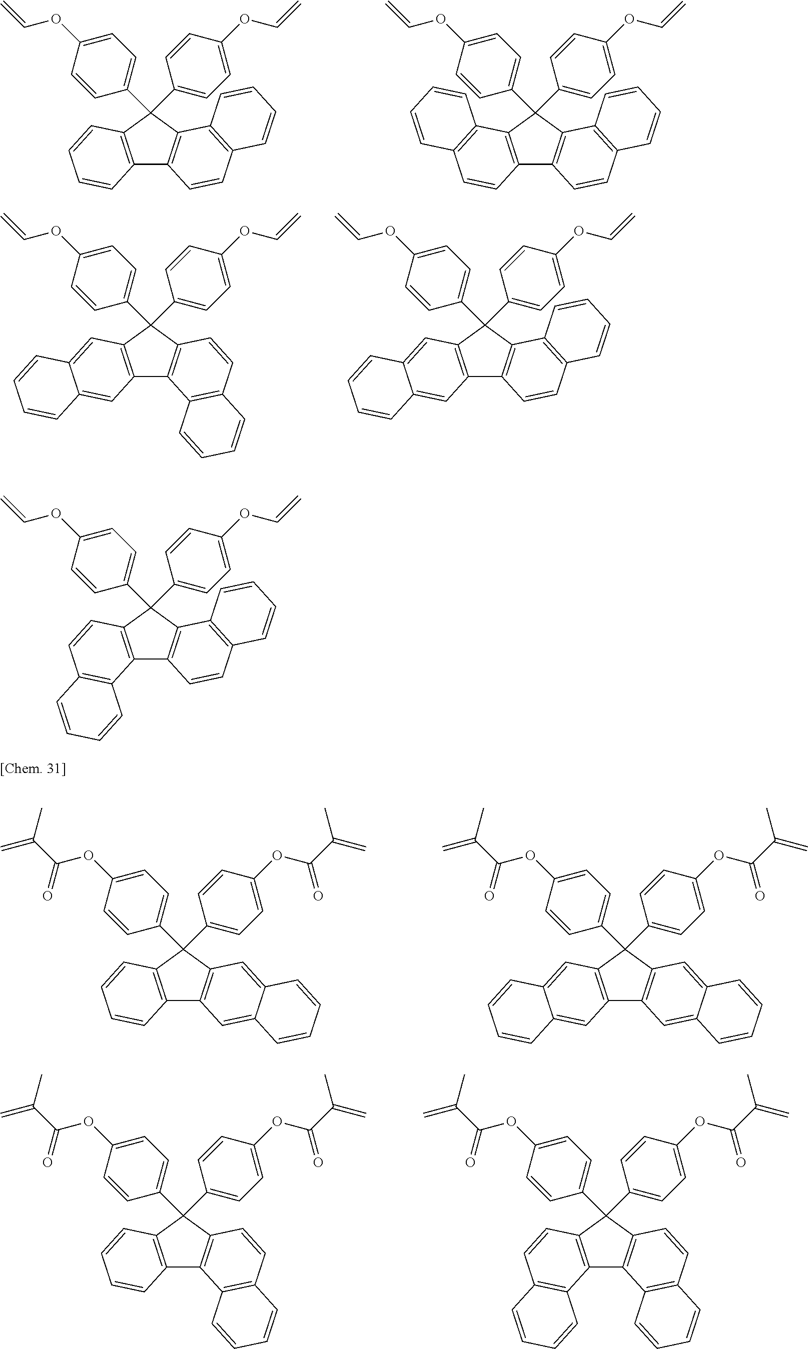

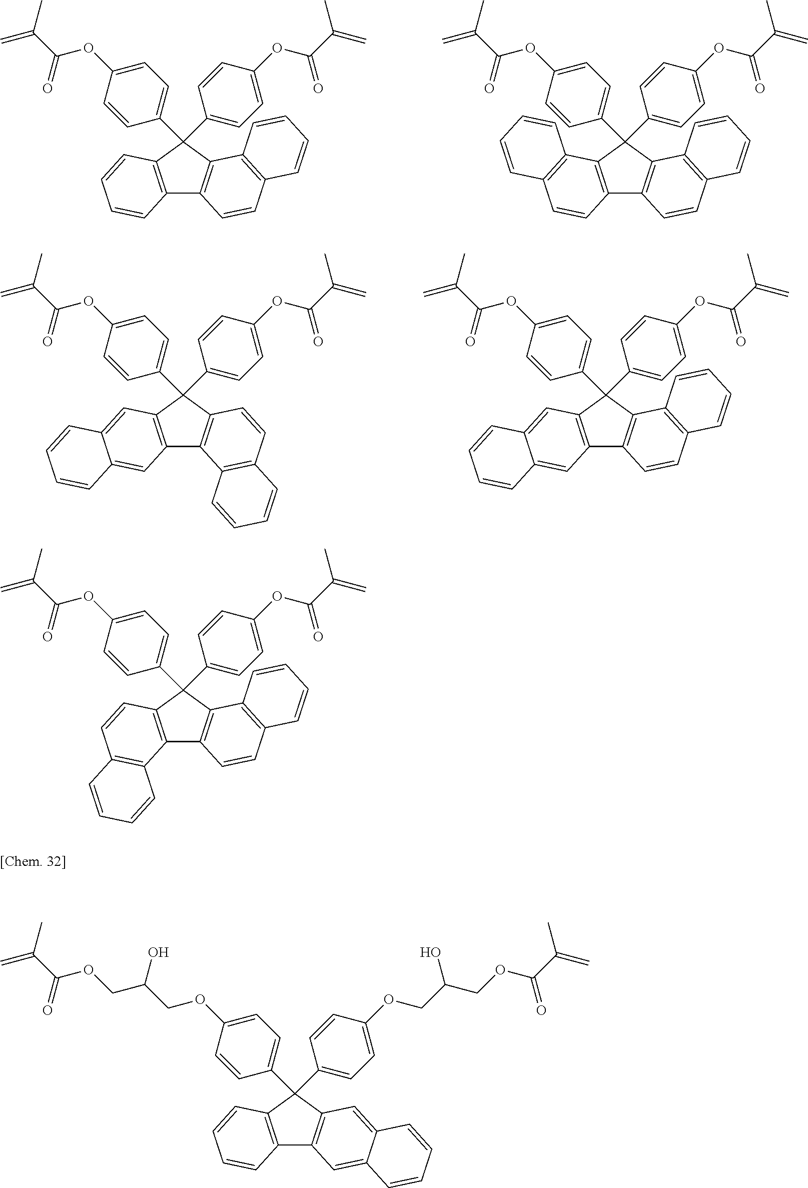 [SMILES: C=C(C)C(=O)Oc1ccc(C2(c3ccc(OC(=O)C(=C)C)cc3)c3ccccc3-c3ccc4ccccc4c32)cc1 ; C=C(C)C(=O)Oc1ccc(C2(c3ccc(OC(=O)C(=C)C)cc3)c3c(ccc4ccccc34)-c3ccc4ccccc4c32)cc1 ; C=C(C)C(=O)Oc1ccc(C2(c3ccc(OC(=O)C(=C)C)cc3)c3cc4ccccc4cc3-c3c2ccc2ccccc32)cc1 ; C=C(C)C(=O)Oc1ccc(C2(c3ccc(OC(=O)C(=C)C)cc3)c3cc4ccccc4cc3-c3ccc4ccccc4c32)cc1 ; C=C(C)C(=O)Oc1ccc(C2(c3ccc(OC(=O)C(=C)C)cc3)c3ccc4ccccc4c3-c3ccc4ccccc4c32)cc1 ; C=C(C)C(=O)OCC(O)COc1ccc(C2(c3ccc(OCC(O)COC(=O)C(=C)C)cc3)c3ccccc3-c3cc4ccccc4cc32)cc1]

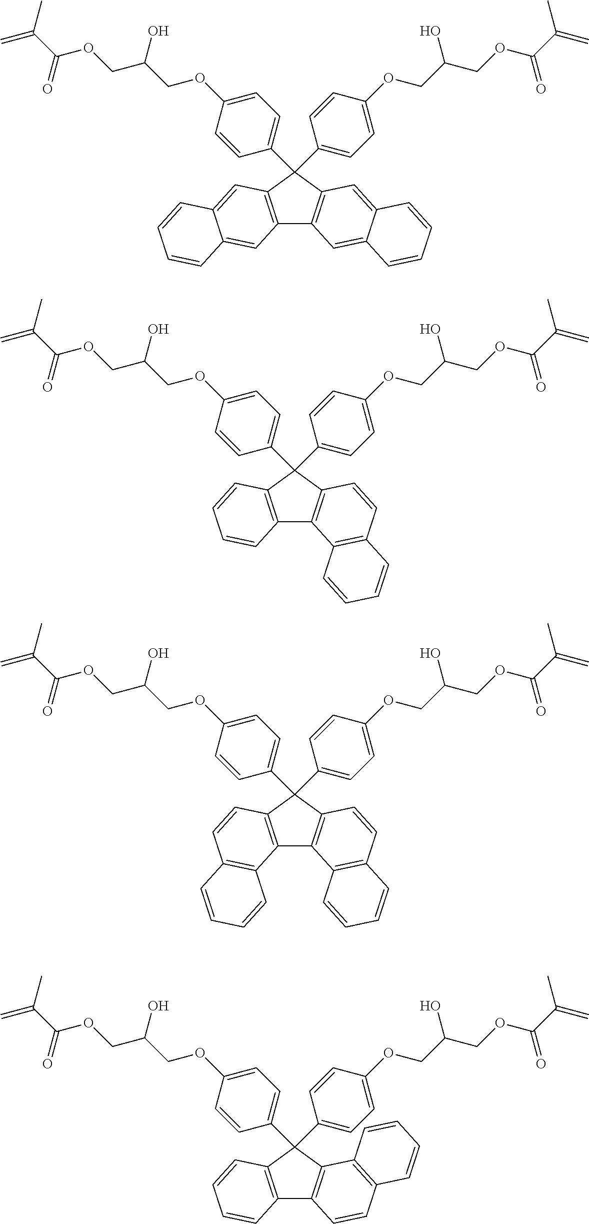

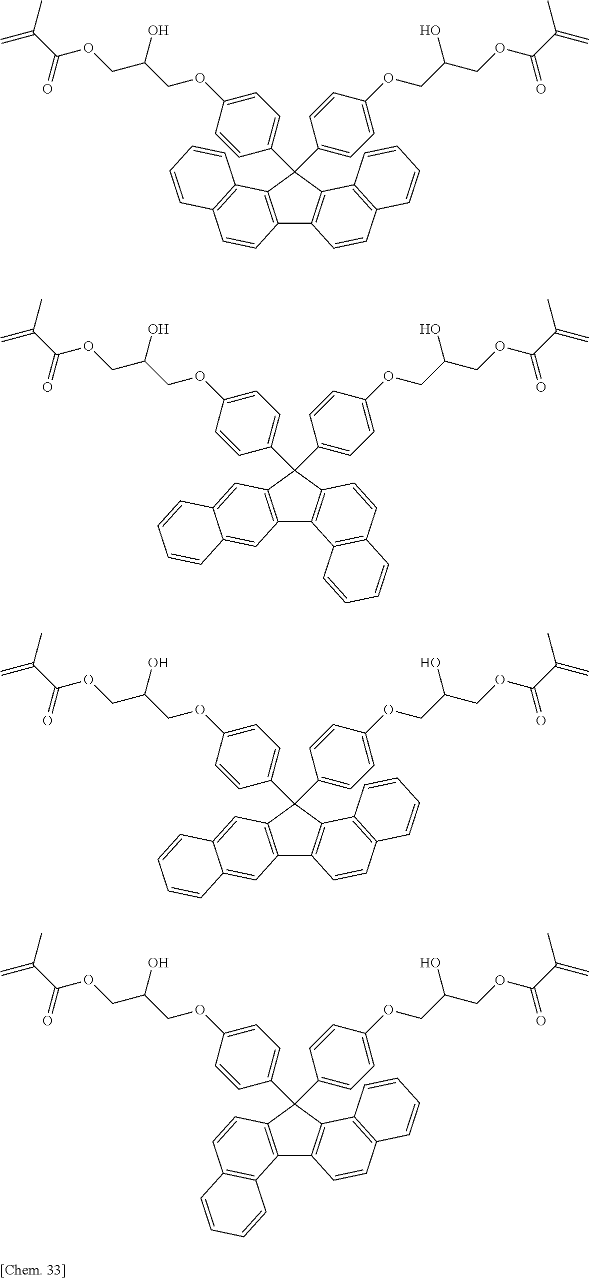

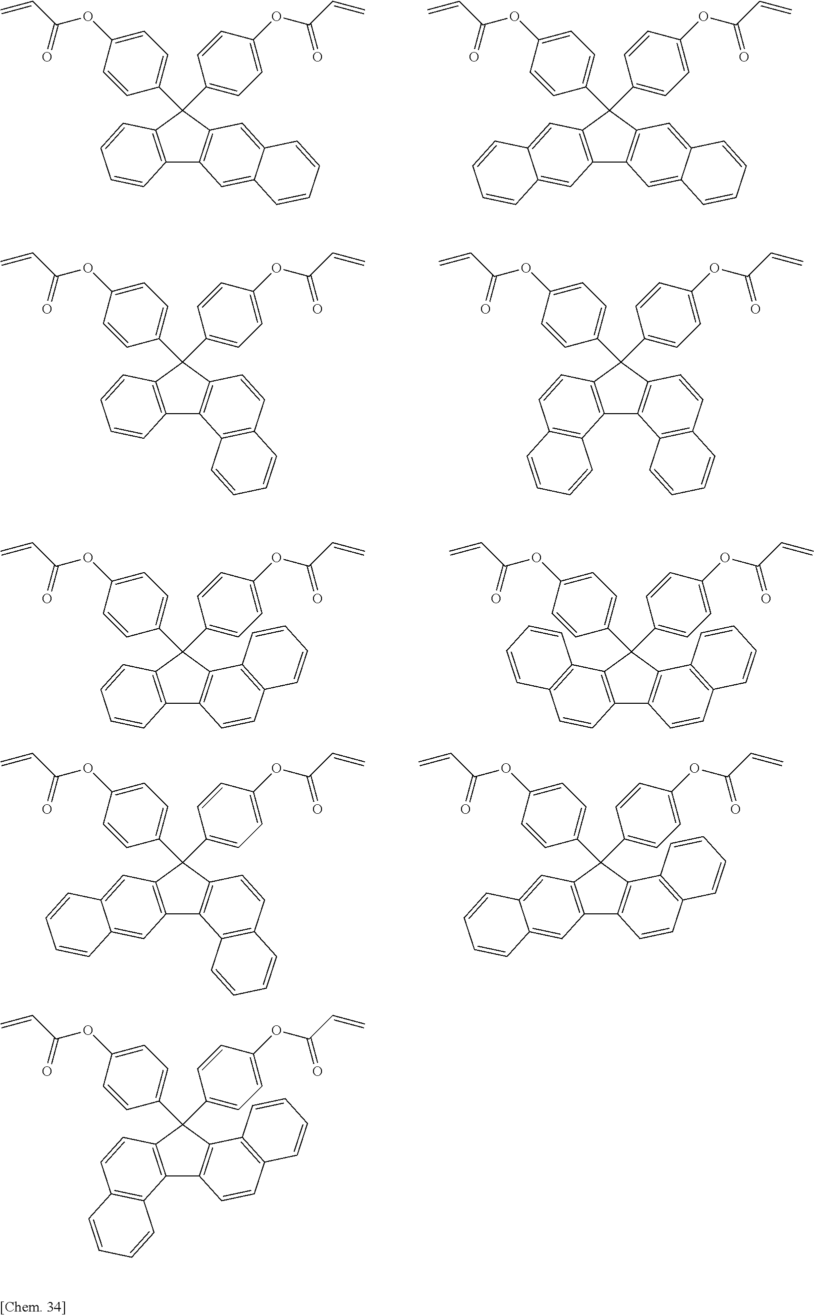

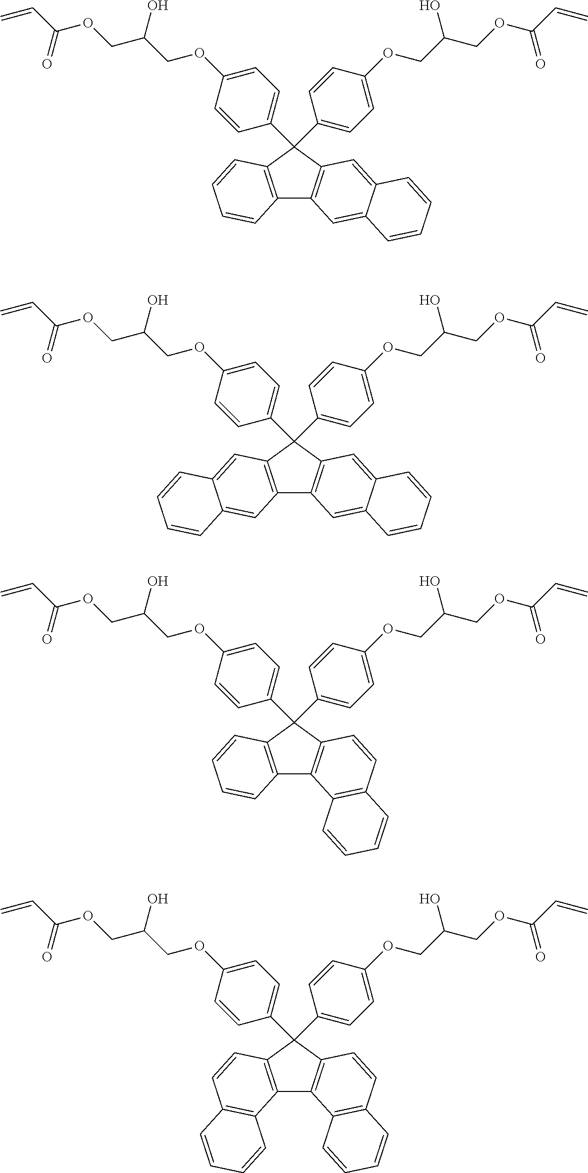

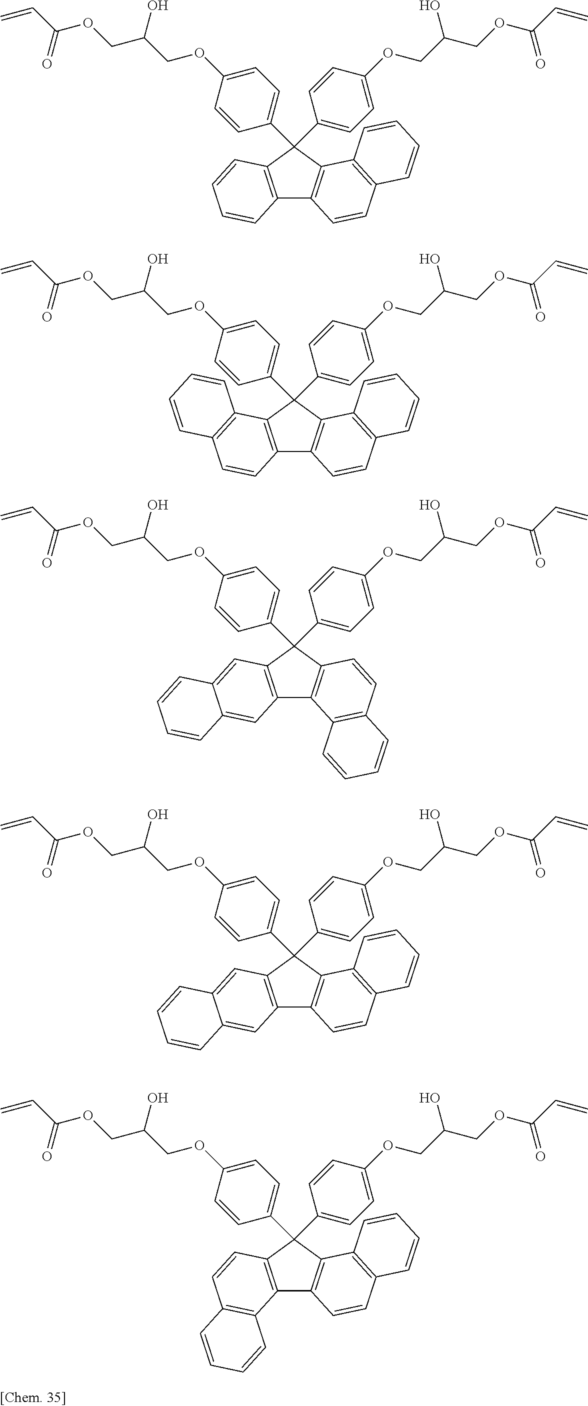

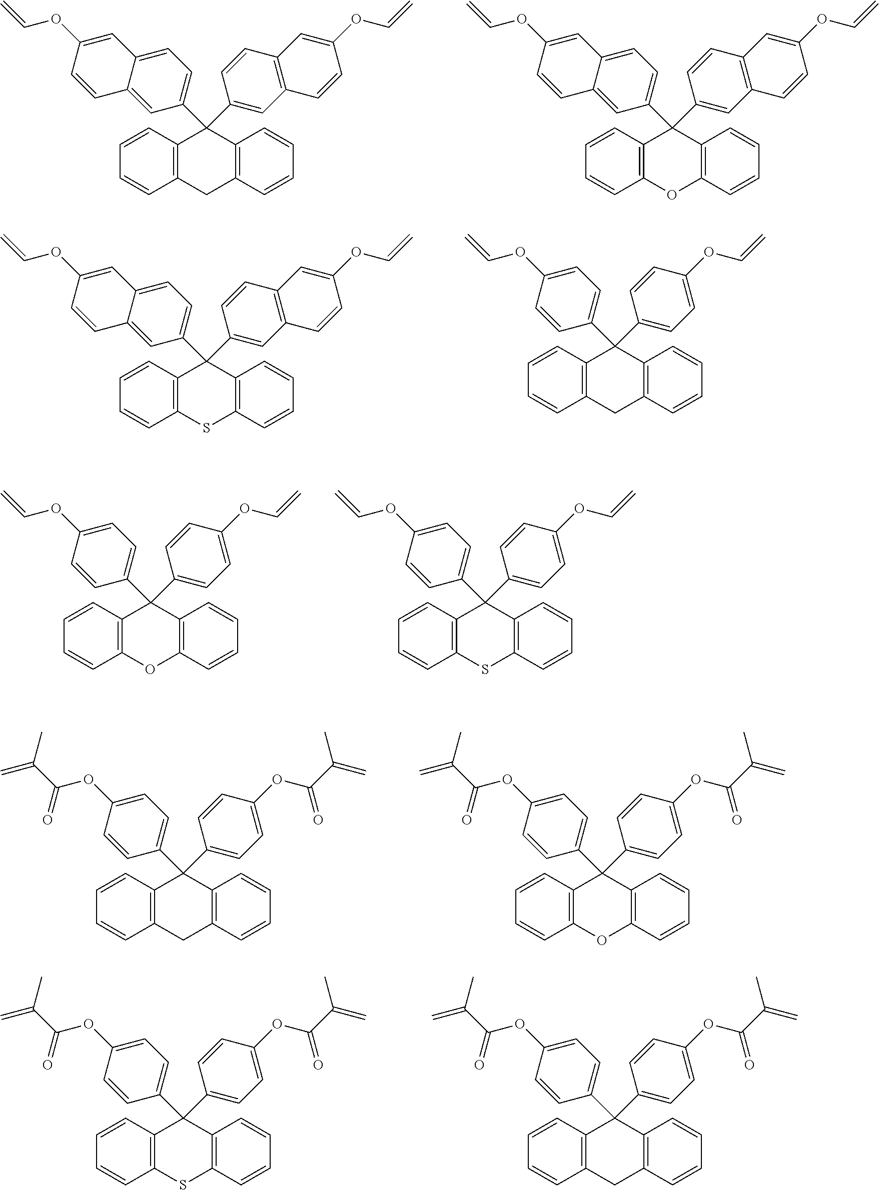

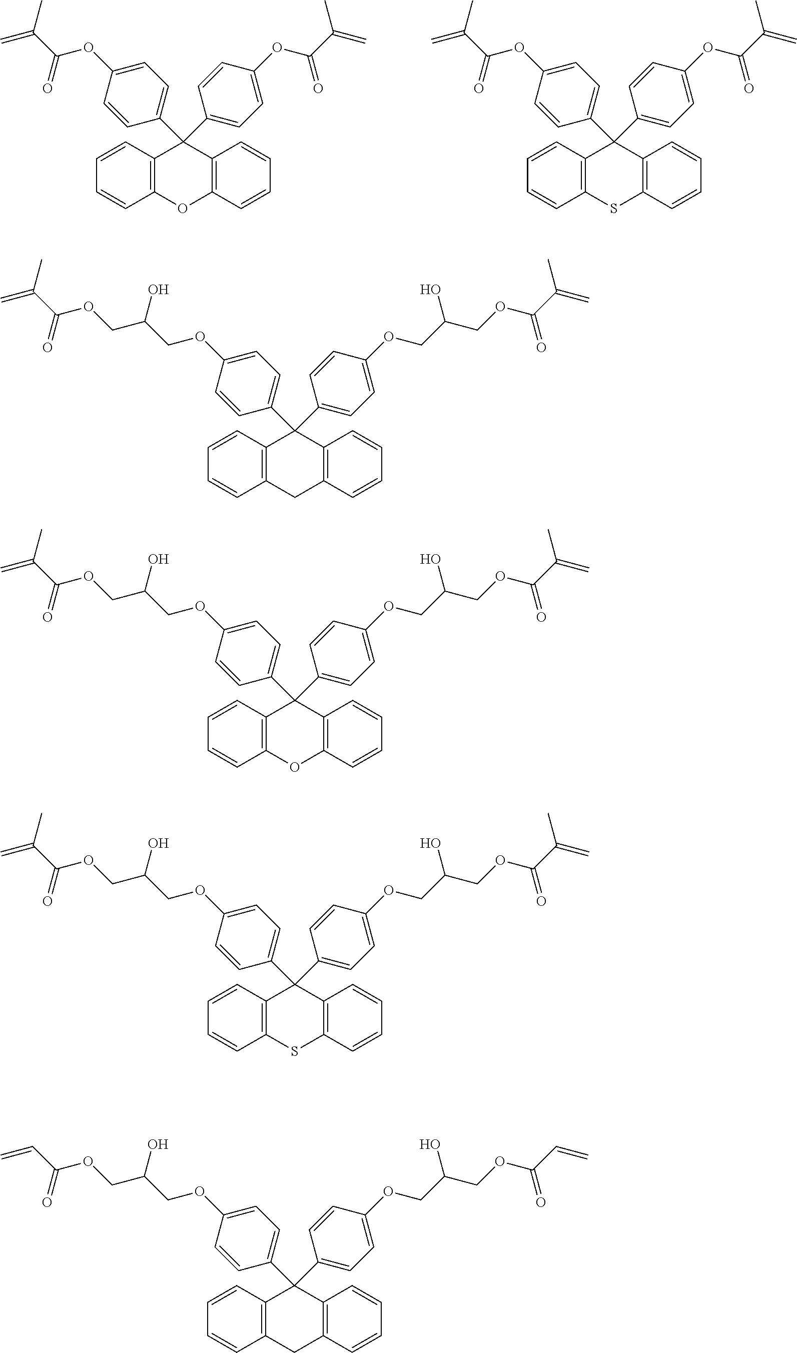

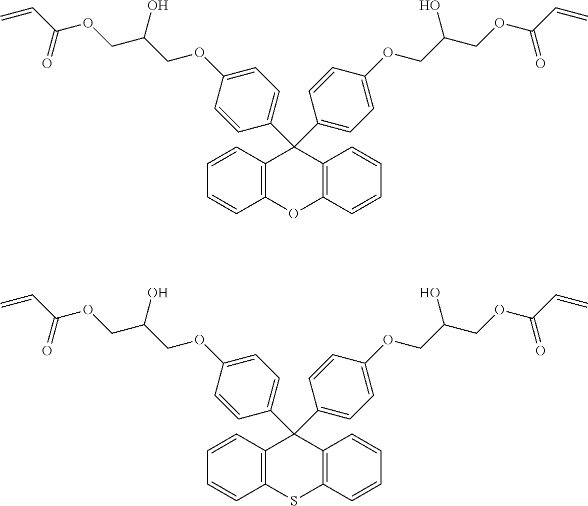

When the cured product with high refractive index is formed, it is also preferable that the photopolymerizable monomer (A2) includes a sulfide compound (A2-1) having the following structure and a (meth) acrylate compound (A-2) having the following structure in combination. In this case, whether the photosensitive composition includes a solvent (S) or not, the low-viscosity photosensitive composition applicable to inkjet method and the like can be prepared.

### (Sulfide Compound (A2-1))

The sulfide compound (A2-1) is a compound represented by the following formula (a2-1).

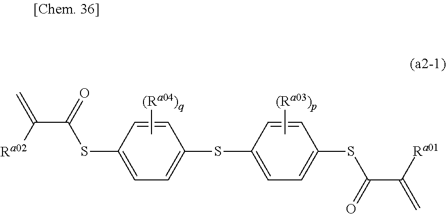

In the formula (a2-1), R^{a01} and R^{a02} are each independently a hydrogen atom or a methyl group. R^{a03} and R^{a}O4 are each independently an alkyl group having 1 or more and 5 or less carbon atoms. p and q are each independently 0 or 1.

R^{a01} and R^{a02} are each independently a hydrogen atom or a methyl group. R^{a01} and R^{a02} are may be the same or different. R^{a01} and R^{a02} are preferably the same in view of ease of synthesis and availability of the sulfide compound (A2-1).

R^{a03} and R^{a04} are each independently an alkyl group having 1 or more and 5 or less carbon atoms. R^{a03} and R^{a04} are may be the same or different. R^{a03} and R^{a04} are preferably the same in view of ease of synthesis and availability of the sulfide compound (A2-1).

The alkyl group having 1 or more and 5 or less carbon atoms as R^{a03} and R^{a04} can be liner or branched. Examples of the alkyl group having 1 or more and 5 or less carbon atoms as R^{a03} and R^{a04} include a methyl group, an ethyl group, an n-propyl group, an isopropyl group, an n-butyl group, an isobutyl group, a sec-butyl group, a tert-butyl group, an n-pentyl group, an isopentyl group, and tert-pentyl group.

Suitable examples of the sulfide compound (A2-1) include following compounds.

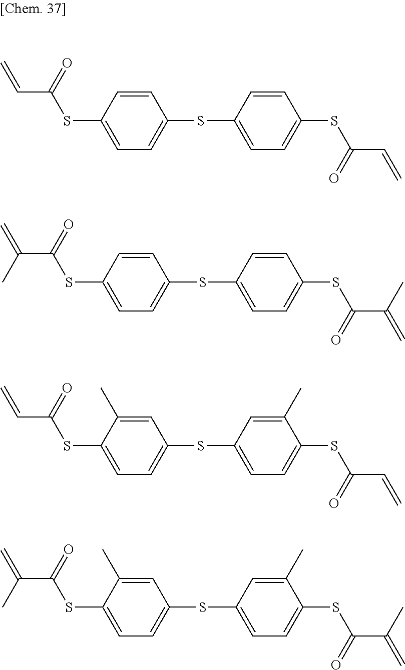

### ((Meth)Acrylate Compound (A2-2))

The (meth)acrylate compound (A2-2) is a compound represented by the following formula (a2-2).

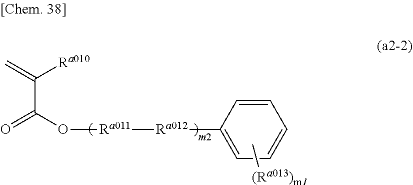

In the formula (a2-2), R^{a010} is a hydrogen atom or a methyl group. R^{a011} is an alkylene group having 1 or more and 3 or less carbon atoms. R^{a012} is a single bond, an oxygen atom, or a sulfur atom. R^{a013} is an alkyl group having 1 or more and 4 or less carbon atoms, an alkoxy group having 1 or more and 4 or less carbon atoms. m1 is an integer of 0 or more and 5 or less. m2 is 1 or 2.

In the formula (a2-2), when m2 is 2, the plurality of R^{a011} may be the same or different, and preferably the same. When m2 is 2, the plurality of R^{a012} may be the same or different, and preferably the same.

R^{a011} is an alkylene group having 1 or more ad 3 or less carbon atoms. Specific examples of the alkylene group include a methylene group, an ethane-1,2-diyl group (an ethylene group), an ethane-1,1-diyl group, a propane-1,3-diyl group, a propane-1,2-diyl group, and a propane-2,2-diyl group. Among these, the methylene group, the ethane-1,2-diyl group (the ethylene group), and the propane-1,2-diyl group are preferable, and the ethane-1,2-diyl group (the ethylene group) is more preferable.

R^{a012} is a single bond, an oxygen atom, or a sulfur atom, and the single bond is preferable. When R^{a012} is the single bond, m2 is preferably 1.

R^{a013} is an alkyl group having 1 or more and 4 or less carbon atoms, or an alkoxy group having 1 or more and 4 or less carbon atoms. Specific examples of the alkyl group include a methyl group, an ethyl group, an n-propyl group, an isopropyl group, an n-butyl group, an isobutyl group, a sec-butyl group, and a tert-butyl group. Among these, the methyl group and the ethyl group are preferable, and the methyl group is more preferable. Specific examples of the alkoxy group include a methoxy group, an ethoxy group, an n-propyloxy group, an isopropyloxy group, an n-butyloxy group, an isobutyloxy group, a sec-butyloxy group, and a tert-butyloxy group. Among these, the methoxy group and the ethoxy group is preferable, and the methoxy group is more preferable. m1 is an integer of 0 or more and 5 or less, preferably 0 or 1, and more preferably 0.

Suitable examples of the (meth)acrylate compound (A2-2) include following compounds.

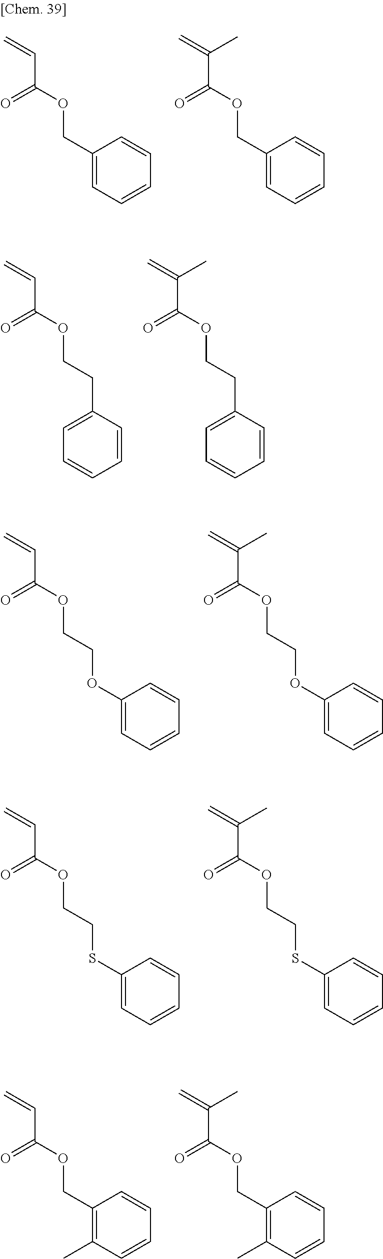

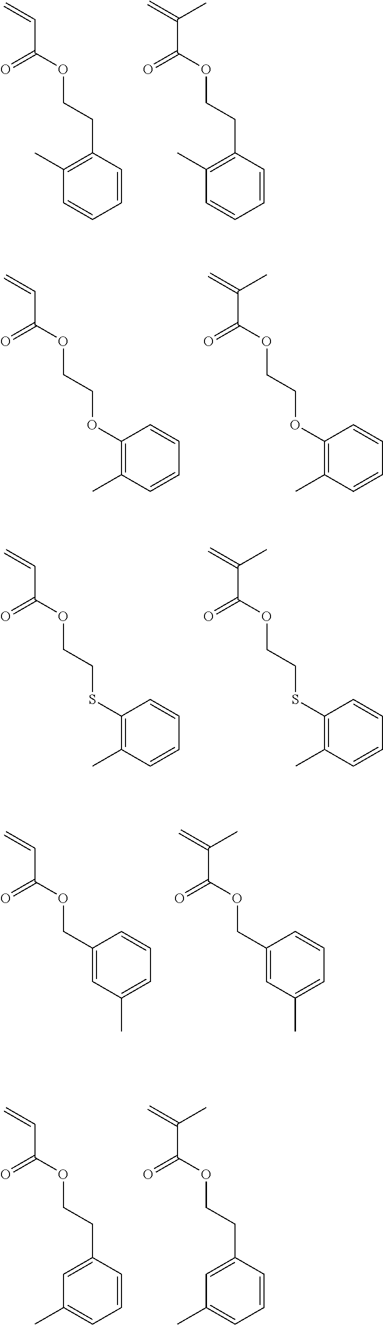

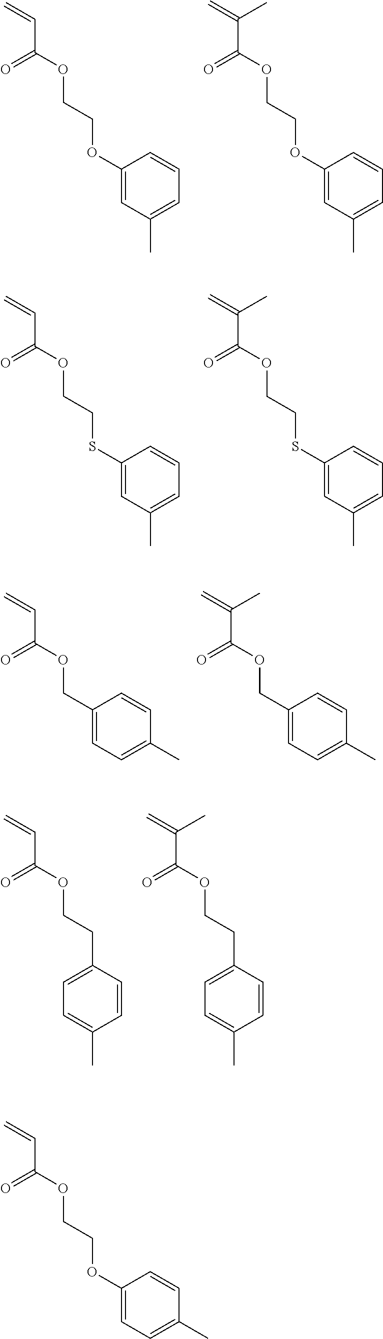

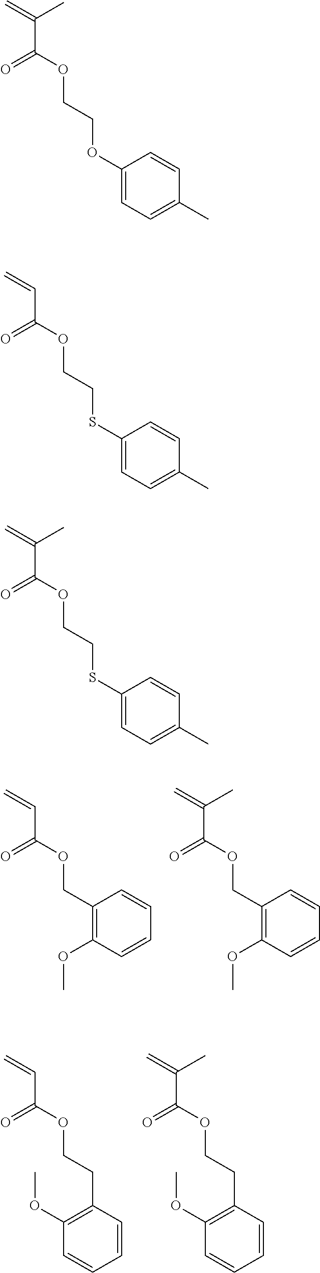

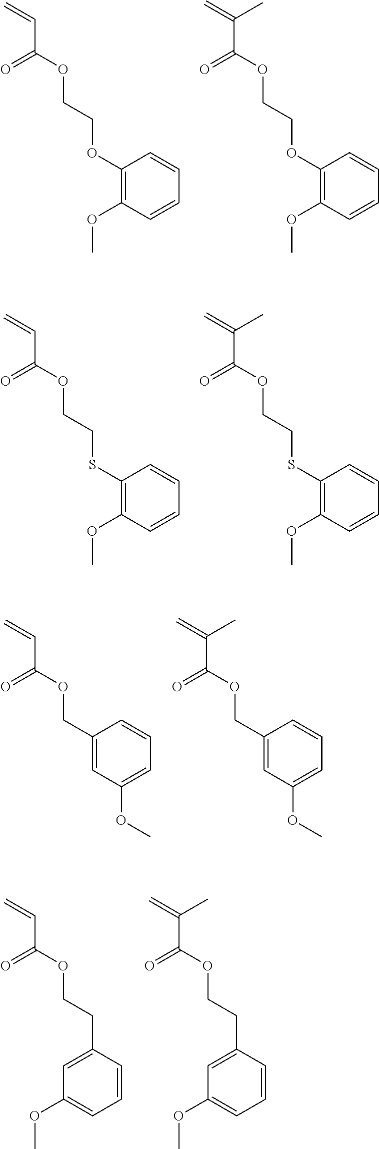

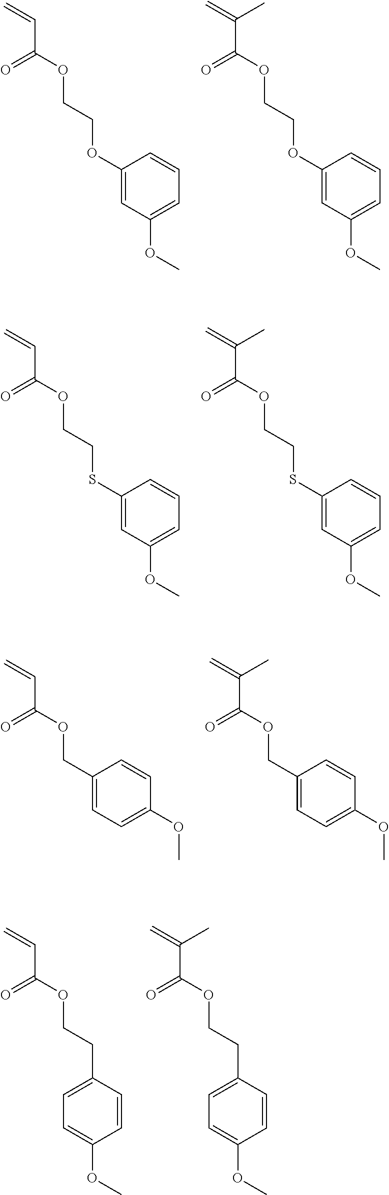

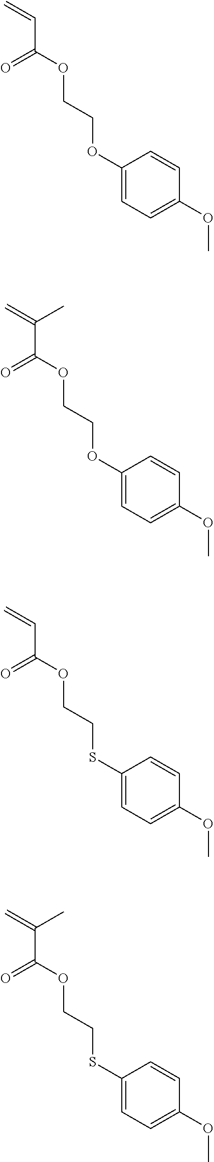

In case that the photosensitive composition includes the sulfide compound (A2-1) and the (meth)acrylate compound (2-2) in combination as the photopolymerizable monomer (A2), a ratio of sum of a mass of the sulfide compound (A2-1) and a mass of the (meth)acrylate compound (A2-2) is preferably 80% by mass or more, more preferably 90% by mass or more, further preferably 95% by mass or more, and most preferably 100% by mass relative to a mass of the base component (A).

When the photosensitive composition includes the sulfide compound (A2-1) and the (meth)acrylate compound (A2-2) in combination as the photopolymerizable monomer (A2), the ratio of the mass of the sulfide compound (A2-1) relative to the mass of the photosensitive composition excluding the mass of the solvent (S) is preferably 5% by mass or more and 30% by mass or less, more preferably 7% by mass ore more and 25% by mass or less, and further preferably 9% by mass or more and 20% by mass or less.

When the photosensitive composition includes the sulfide compound (A2-1) and the (meth)acrylate compound (A2-2) in combination as the photopolymerizable monomer (A2), the ratio of the mass of the (meth)acrylate compound (A2-2) relative to the mass of the photosensitive composition excluding the mass of the solvent (S) is preferably 10% by mass or more and 50% by mass or less, more preferably 20% by mass or more and 45% by mass or less, and further preferably 30% by mass or more and 40% by mass or less.

In case that the photosensitive composition includes the sulfide compound (A2-1) and the (meth)acrylate compound (A2-2) in combination as the photopolymerizable monomer (A2), when the photopolymerizable compound (A) includes the sulfide compound (A2-1) and the (meth)acrylate compound (A2-2) in an amount within the above range, the photosensitive composition is highly photocurable and has low viscosity, and the cured product with a high refractive index can be formed by using the photosensitive composition.

In case that the photosensitive composition includes the sulfide compound (A2-1) and the (meth)acrylate compound (2-2) in combination as the photopolymerizable monomer (A2), it is preferable that the mass of the (meth)acrylate compound (A2-2) is more than the mass of the sulfide compound (A1), since the cured product with high refractive index is easily formed by using the photosensitive composition.

A content of the base component (A) is not particularly limited as long as the objects of the present invention are not inhibited. A content of the base component (A) in the photosensitive composition is preferably 10% by mass or more and 99.5% by mass or less, and more preferably 20% by mass or more and 90% by mass or less relative to the mass of the photosensitive composition excluding the mass of the solvent (S).

A content of the resin (A1) in the photosensitive composition is preferably 99.5% by mass or less, more preferably 20% by mass or more and 85% by mass or less, and further preferably 25% by mass or more and 75% by mass or less relative to the mass of the photosensitive composition excluding the mass of the solvent (S).

A content of the photopolymerizable monomer (A2) in the photosensitive composition is preferably 99.5% by mass or less, more preferably 1% by mass or more and 50% by mass or less, and further preferably 5% by mass or more and 40% by mass or less relative to the mass of the photosensitive composition excluding a mass of the solvent (S). When the content is in above-mentioned range, good balance of sensitivity, developability, and resolution tends to be easily achieved.

### <Photopolymerization Initiator (B)>

Photosensitive composition includes a phosphine oxide compound (B1) and an oxime ester compound in combination. By using the photopolymerization initiator (B), a cured product with a high refractive index and a high transparency can be formed by using the photosensitive composition. The photopolymerization initiator (B) including the phosphine oxide compound (B1) and the oxime ester compound (B2) in combination contributes in particular to the transparency of the cured product.

The photosensitive composition may include other photopolymerization initiator (B3) other than the phosphine oxide compound (B1) and the oxime ester compound (B2). A ratio of sum of a mass of the phosphine oxide compound (B1) and a mass of the oxime ester compound (B2) is preferably 80% by mass or more, more preferably 90% by mass or more, further preferably 95% by mass or more, and particularly preferably 100% by mass relative to a mass of the photopolymerization initiator (B), since desired effect is easily obtained.

### [Phosphine Oxide Compound (B1)]

The phosphine oxide compound (B1) is a pentavalent phosphorus compound having P═O bond. As the phosphine oxide compound (B1), a pentavalent phosphorous compound conventionally used as a photopolymerization initiator and having a P═O bond can be used without any particular limitation. Examples of the phosphine oxide compound include a compound represented by the following formula (b-I).

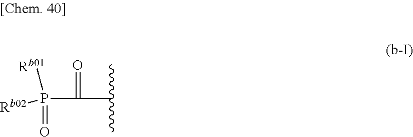

In the formula (b-I), R^{b01} and R^{b02} are each independently an alkyl group, a cycloalkyl group, an aryl group, an aliphatic acyl group having 2 or more and 20 or less carbon atoms, or an aromatic acyl group having 7 or more and 20 or less carbon atoms. However, both R^{b01} and R^{b02} cannot be the aliphatic acyl group or the aromatic acyl groups.

The number of carbon atoms of the alkyl group as R^{b01} and R^{b02} is preferably 1 or more and 12 or less, more preferably 1 or more and 8 or less, and further preferably 1 or more and 4 or less. The alkyl group as R^{b01} and R^{b02} can be liner or branched. Specific examples of the alkyl group include a methyl group, an ethyl group, an n-propyl group, an isopropyl group, an n-butyl group, an isobutyl group, a sec-butyl group, a tert-butyl group, an n-pentyl group, an isopentyl group, a tert-pentyl group, an n-hexyl group, an n-heptyl group, an n-octyl group, a 2,4,4-trimethylpentyl group, a 2-ethylhexyl group, an n-nonyl group, an n-decyl group, an n-undecyl group, and an n-dodecyl group.

The number of carbon atoms of the cycloalkyl group as R^{b01} and R^{b02} is preferably 5 or more and 12 or less. Specific examples of the cycloalkyl group include a cyclopentyl group, a cyclohexyl group, a cycloheptyl group, a cyclooctyl group, a cyclononyl group, a cyclodecyl group, a cycloundecyl group, and a cyclododecyl group.

The number of carbon atoms of the aryl group as R^{b01} and R^{b02} is preferably 6 or more and 12 or less. The aryl group may have a substituent. Examples of the substituent include a halogen atom, an alkyl group having 1 or more and 4 or less carbon atoms, an alkoxy group having 1 or more and 4 or less carbon atoms, and the like. Specific examples of the aryl group include a phenyl group and a naphthyl group.

The number of carbon atoms of the aliphatic acyl group as R^{b01} and R^{b02} is 2 or more and 20 or less, preferably 2 or more and 12 or less, more preferably 2 or more and 8 or less, and further preferably 2 or more and 6 or less. The aliphatic acyl group can be liner or branched. Specific examples of the aliphatic acyl group include an acetyl group, a propionyl group, a butanoyl group, a pentanoyl group, a hexanoyl group, a heptanoyl group, an octanoyl group, a nonanoyl group, a decanoyl group, an undecanoyl group, a dodecanoyl group, a tridecanoyl group, a tetradecanoyl group, a pentadecanoyl group, a hexadecanoyl group, a heptadecanoyl group, an octadecanoyl group, a nonadecanoyl group, and an icosanoyl group.

The number of carbon atoms of the aromatic acyl group as R^{b01} and R^{b02} is 7 or more and 20. The aromatic acyl group may have a substituent. Examples of the substituent include a halogen atom, an alkyl group having 1 or more and 4 or less carbon atoms, an alkoxy group having 1 or more and 4 or less carbon atoms, and the like. Specific examples of the aromatic acyl group include a benzoyl group, an o-tolyl group, a m-tolyl group, a p-tolyl group, a 2,6-dimethylbenzoyl group, a 2,6-dimethoxybenzoyl group, a 2,4,6-trimethylbenzoyl group, an α-naphthoyl group, and a β-naphthoyl group.

Specific examples of the phosphine oxide compound having the partial structure represented by the formula (b-I) include 2,4,6-trimethylbenzoyldihenylphosphin oxide, bis(2,4,6-trimethylbenzoyl)-phenylphosphine oxide, and bis(2,6-dimethoxybenzoyl)-2,4,4-trimethyl-pentylphosphine oxide.

### [Oxime Ester Compound (B2)]

The oxime ester compound (B2) is a compound having a bond represented by >C═N—O—CO—. As the oxime ester compound (B2), a compound conventionally used as a photopolymerization initiator and having a bond represented by >C═N—O—CO— can be used without any particular limitation.

When only the oxime ester compound (B2) is used as the photopolymerization initiator (B), formation of the cured product with sufficiently high transparency is often difficult. On the other hand, when the oxime ester compound (B2) is used with the phosphine oxide compound (B1) in combination, the cured product with high transparency can be easily formed.

The oxime ester compound (B2) is preferably a compound that does not include a compound having a peak in a wavelength range of 320 nm or longer and 400 nm or shorter in the absorption spectrum and showing a gram absorption coefficient of 10 or more at any one or more wavelength in the wavelength range of 400 nm or longer. In this case, the cured product with particularly good transparency is easily formed.

For example, an oxime ester compound represented by the following formula (b1) is preferred as the oxime ester compound (B2).

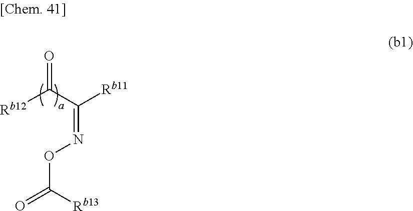

In the formula (b1), R^{b11} represents an optionally substituted alkyl group having 1 or more and 10 or less carbon atom, an optionally substituted phenyl group, or an optionally substituted carbazolyl group. a is 0 or 1. R^{b12} represents an optionally substituted alkyl group having 1 or more and 10 or less carbon atom, an optionally substituted phenyl group, or an optionally substituted carbazolyl group. R^{b13} represents a hydrogen atom, an alkyl group having 1 or more and 6 or less carbon atoms, or an optionally substituted phenyl group.

When R^{b11} is the alkyl group having 1 or more and 10 or less carbon atoms, type of a substituent possessed by the alkyl group is not particularly limited as long as the objects of the present invention are not inhibited.

Examples of suitable substituents which the alkyl group having 1 or more and 10 or less carbon atoms may have include an alkoxy group having 1 or more and 20 or less carbon atoms, a cycloalkyl group having 3 or more and 10 or less carbon atoms, a cycloalkoxy group having 3 or more and 10 or less carbon atoms, a saturated aliphatic acyl group having 2 or more and 20 or less carbon atoms, an alkoxycarbonyl group having 2 or more and 20 or less carbon atoms, a saturated aliphatic acyloxy group having 2 or more and 20 or less carbon atoms, an optionally substituted phenyl group, an optionally substituted phenoxy group, an optionally substituted phenylthio group, an optionally substituted benzoyl group, an optionally substituted phenoxycarbonyl group, an optionally substituted benzoyloxy group, an optionally substituted phenylalkyl group having 7 or more and 20 or less carbon atoms, an optionally substituted naphthyl group, an optionally substituted naphthoxy group, an optionally substituted naphthoyl group, an optionally substituted naphthoxycarbonyl group, an optionally substituted naphthoyloxy group, an optionally substituted naphthylalkyl group having 11 or more and 20 or less carbon atoms, an optionally substituted heterocyclyl group, an optionally substituted heterocyclylcarbonyl group, an amino group, an amino group substituted with 1 or 2 organic groups, a morpholine-1-yl group, a piperazine-1-yl group, halogen, a nitro group, a cyano group and the like.

The alkyl group having 1 or more and 10 or less carbon atoms may be linear or branched. In this case, the number of carbon atoms of the alkyl group is preferably 1 or more and 8 or less, and more preferably 1 or more and 5 or less.

When R^{b11} is an optionally substituted phenyl group, the type of the substituent is not particularly limited as long as the objects of the present invention are not inhibited. Examples of a suitable substituent that the phenyl group may have include an alkyl group, an alkoxy group, an cycloalkyl group, an cycloalkoxy group, a saturated aliphatic acyl group, an alkoxycarbonyl group, a saturated aliphatic acyloxy group, an optionally substituted phenyl group, an optionally substituted phenoxy group, an optionally substituted benzoyl group, an optionally substituted phenoxycarbonyl group, an optionally substituted benzoyloxy group, an optionally substituted phenylalkyl group, an optionally substituted naphthyl group, an optionally substituted naphthoxy group, an optionally substituted naphthoyl group, an optionally substituted naphthoxycarbonyl group, an optionally substituted naphthoyloxy group, an optionally substituted naphthylalkyl group, an optionally substituted heterocyclyl group, an amino group, an amino group substituted with one or two organic groups, a morpholin-1-yl group, a piperazin-1-yl group, a halogen, a nitro group, a cyano group, and the like. When R^{b11} is an optionally substituted phenyl group and the phenyl group has a plurality of substituents, the plurality of substituents may be the same as or different from each other.

When a substituent of the phenyl group is an alkyl group, the number of carbon atoms of the alkyl group is preferably 1 or more and 20 or less, more preferably 1 or more and 10 or less, further preferably 1 or more and 6 or less, particularly preferably 1 or more and 3 or less, and most preferably 1. The alkyl group may be linear or branched. When a substituent of the phenyl group is an alkyl group, specific examples thereof include a methyl group, an ethyl group, an n-propyl group, an isopropyl group, an n-butyl group, an isobutyl group, a sec-butyl group, a tert-butyl group, an n-pentyl group, an isopentyl group, a sec-pentyl group, a tert-pentyl group, an n-hexyl group, an n-heptyl group, an n-octyl group, an isooctyl group, a sec-octyl group, a tert-octyl group, an n-nonyl group, an isononyl group, an n-decyl group, an isodecyl group, and the like. The alkyl group may have an ether bond (—O—) in the carbon chain. In this case, examples of a substituent of the phenyl group include an alkoxyalkyl group and an alkoxyalkoxyalkyl group. When a substituent of the phenyl group is an alkoxyalkyl group, a group represented by —R^{b14}—O—R^{b15} is preferable. R^{b14} represents a linear or branched alkylene group having 1 or more and 10 or less carbon atoms. R^{b15} represents a linear or branched alkyl group having 1 or more and 10 or less carbon atoms. The number of carbon atoms of R^{b14} is preferably 1 or more and 8 or less, more preferably 1 or more and 5 or less, and particularly preferably 1 or more and 3 or less. The number of carbon atoms of R^{b15} is preferably 1 or more and 8 or less, more preferably 1 or more and 5 or less, particularly preferably 1 or more and 3 or less, and most preferably 1. Examples of the alkyl group having an ether bond in the carbon chain include a methoxyethyl group, an ethoxyethyl group, a methoxyethoxyethyl group, an ethoxyethoxyethyl group, a propyloxyethoxyethyl group, a methoxypropyl group, and the like.

When a substituent of the phenyl group is an alkoxy group, the number of carbon atoms of the alkoxy group is preferably 1 or more and 20 or less, and more preferably 1 or more and 6 or less. The alkoxy group may be linear or branched. When a substituent of the phenyl group is an alkoxy group, specific examples include a methoxy group, an ethoxy group, an n-propyloxy group, an isopropyloxy group, an n-butyloxy group, an isobutyloxy group, a sec-butyloxy group, a tert-butyloxy group, an n-pentyloxy group, an isopentyloxy group, a sec-pentyloxy group, a tert-pentyloxy group, an n-hexyloxy group, an n-heptyloxy group, an n-octyloxy group, an isooctyloxy group, a sec-octyloxy group, a tert-octyloxy group, an n-nonyloxy group, an isononyloxy group, an n-decyloxy group, an isodecyloxy group, and the like. The alkoxy group may include an ether bond (—O—) in the carbon chain. Examples of the alkoxy group having an ether bond in the carbon chain include a methoxyethoxy group, an ethoxyethoxy group, a 2-methoxy-1-methylethoxy group, a methoxyethoxyethoxy group, an ethoxyethoxyethoxy group, a propyloxyethoxyethoxy group, a methoxypropyloxy group, and the like.

When a substituent of the phenyl group is a cycloalkyl group or a cycloalkoxy group, the number of carbon atoms of the cycloalkyl group or the cycloalkoxy group is preferably 3 or more and 10 or less, and more preferably 3 or more and 6 or less. When a substituent of the phenyl group is a cycloalkyl group, specific examples thereof include a cyclopropyl group, a cyclobutyl group, a cyclopentyl group, a cyclohexyl group, a cycloheptyl group, a cyclooctyl group, and the like. When a substituent of the phenyl group is a cycloalkoxy group, specific examples include a cyclopropyloxy group, a cyclobutyloxy group, a cyclopentyloxy group, a cyclohexyloxy group, a cycloheptyloxy group, a cyclooctyloxy group, and the like.

When a substituent of the phenyl group is a saturated aliphatic acyl group or a saturated aliphatic acyloxy group, the number of carbon atoms of the saturated aliphatic acyl group or the saturated aliphatic acyloxy group is preferably 2 or more and 20 or less, and more preferably 2 or more and 7 or less. When a substituent of the phenyl group is a saturated aliphatic acyl group, specific examples thereof include an acetyl group, a propanoyl group, an n-butanoyl group, a 2-methylpropanoyl group, an n-pentanoyl group, a 2,2-dimethylpropanoyl group, an n-hexanoyl group, an n-heptanoyl group, an n-octanoyl group, an n-nonanoyl group, an n-decanoyl group, an n-undecanoyl group, an n-dodecanoyl group, an n-tridecanoyl group, an n-tetradecanoyl group, an n-pentadecanoyl group, an n-hexadecanoyl group, and the like. When a substituent of the phenyl group is a saturated aliphatic acyloxy group, specific examples thereof include an acetyloxy group, a propanoyloxy group, an n-butanoyloxy group, a 2-methylpropanoyloxy group, an n-pentanoyloxy group, a 2,2-dimethylpropanoyloxy group, an n-hexanoyloxy group, an n-heptanoyloxy group, an n-octanoyloxy group, an n-nonanoyloxy group, an n-decanoyloxy group, an n-undecanoyloxy group, an n-dodecanoyloxy group, an n-tridecanoyloxy group, an n-tetradecanoyloxy group, an n-pentadecanoyloxy group, an n-hexadecanoyloxy group, and the like.

When a substituent of the phenyl group is an alkoxycarbonyl group, the number of carbon atoms of the alkoxycarbonyl group is preferably 2 or more and 20 or less, and more preferably 2 or more and 7 or less. When a substituent of the phenyl group is an alkoxycarbonyl group, specific examples include a methoxycarbonyl group, an ethoxycarbonyl group, an n-propyloxycarbonyl group, an isopropyloxycarbonyl group, an n-butyloxycarbonyl group, an isobutyloxycarbonyl group, a sec-butyloxycarbonyl group, a tert-butyloxycarbonyl group, an n-pentyloxycarbonyl group, an isopentyloxycarbonyl group, a sec-pentyloxycarbonyl group, a tert-pentyloxycarbonyl group, an n-hexyloxycarbonyl group, an n-heptyloxycarbonyl group, an n-octyloxycarbonyl group, an isooctyloxycarbonyl group, a sec-octyloxycarbonyl group, a tert-octyloxycarbonyl group, an n-nonyloxycarbonyl group, an isononyloxycarbonyl group, an n-decyloxycarbonyl group, an isodecyloxycarbonyl group, and the like.

When a substituent of the phenyl group is a phenylalkyl group, the number of carbon atoms of the phenylalkyl group is preferably 7 or more and 20 or less, more preferably 7 or more and 10 or less. When a substituent of the phenyl group is a naphthylalkyl group, the number of carbon atoms of the naphthylalkyl group is preferably 11 or more and 20 or less, more preferably 11 or more and 14 or less. When a substituent of the phenyl group is a phenylalkyl group, specific examples thereof include a benzyl group, a 2-phenylethyl group, a 3-phenylpropyl group, and a 4-phenylbutyl group. When a substituent of the phenyl group is a naphthylalkyl group, specific examples include an a-naphthylmethyl group, a β-naphthylmethyl group, a 2-(a-naphthyl)ethyl group, and a 2-(D-naphthyl)ethyl group. When a substituent of the phenyl group is a phenylalkyl group or a naphthylalkyl group, the substituent may further have a substituent on the phenyl group or the naphthyl group.

When a substituent of the phenyl group is a heterocyclyl group, the heterocyclyl group is a 5- or 6-membered monocycle including one or more N, S, and O, or a heterocyclyl group in which these monocycles are condensed with each other, or the monocycle and a benzene ring are condensed. When the heterocyclyl group is a condensed ring, the number of rings constituting the condensed ring is 3 or less. Examples of the heterocycle constituting the heterocyclyl group include furan, thiophene, pyrrole, oxazole, isoxazole, thiazole, thiadiazole, isothiazole, imidazole, pyrazole, triazole, pyridine, pyrazine, pyrimidine, pyridazine, benzofuran, benzothiophene, indole, isoindole, indolizine, benzimidazole, benzotriazole, benzoxazole, benzothiazole, carbazole, purine, quinoline, isoquinoline, quinazoline, phthalazine, cinnoline, quinoxaline, and the like. When a substituent of the phenyl group is a heterocyclyl group, the heterocyclyl group may further have a substituent.

When a substituent of the phenyl group is an amino group substituted with one or two organic groups, suitable examples of the organic group include an alkyl group having 1 or more and 20 or less carbon atoms, a cycloalkyl group having 3 or more and 10 or less carbon atoms, a saturated aliphatic acyl group having 2 or more and 20 or less carbon atoms, a saturated aliphatic acyloxy group having 2 or more and 20 or less carbon atoms, an optionally substituted phenyl group, an optionally substituted benzoyl group, an optionally substituted phenylalkyl group having 7 or more and 20 or less carbon atoms, an optionally substituted naphthyl group, an optionally substituted naphthoyl group, an optionally substituted naphthylalkyl group having 11 or more and 20 or less carbon atoms, a heterocyclyl group, and the like. Specific examples of suitable organic groups are the same as the groups described above as the substituent of the phenyl group. Specific examples of the amino group substituted with one or two organic groups include a methylamino group, an ethylamino group, a diethylamino group, an n-propylamino group, a di-n-propylamino group, an isopropylamino group, an n-butylamino group, a di-n-butylamino group, an n-pentylamino group, an n-hexylamino group, an n-heptylamino group, an n-octylamino group, an n-nonylamino group, an n-decylamino group, a phenylamino group, a naphthylamino group, an acetylamino group, a propanoylamino group, an n-butanoylamino group, an n-pentanoylamino group, an n-hexanoylamino group, an n-heptanoylamino group, an n-octanoylamino group, an n-decanoylamino group, a benzoylamino group, an a-naphthoylamino group, a P-naphthoylamino group, an N-acetyl-N-acetyloxyamino group, and the like.

When a phenyl group, a naphthyl group, and a heterocyclyl group included in a substituent of the phenyl group further have a substituent, examples of the further substituent include an alkyl group having 1 or more and 6 or less carbon atoms, an alkoxy group having 1 or more and 6 or less carbon atoms, a saturated aliphatic acyl group having 2 or more and 7 or less carbon atoms, an alkoxycarbonyl group having 2 or more and 7 or less carbon atoms, a saturated aliphatic acyloxy group having 2 or more and 7 or less carbon atoms, a monoalkylamino group which has an alkyl group having 1 or more and 6 or less carbon atoms, a dialkylamino group which has an alkyl group having 1 or more and 6 or less carbon atoms, a morpholin-1-yl group, a piperazin-1-yl group, halogen, a nitro group, a cyano group, and the like. When a phenyl group, a naphthyl group, and a heterocyclyl group included in a substituent of the phenyl group further have a substituent, the number of further substituents is not particularly limited as long as the object of the present invention is not inhibited, and is preferably 1 or more and 4 or less. When a phenyl group, a naphthyl group, and a heterocyclyl group included in a substituent of the phenyl group have a plurality of substituents, the plurality of substituents may be the same as or different from each other.

Substituents for the case in which R^{b11} is an optionally substituted phenyl group are described above. Among those substituents, an alkyl group or an alkoxyalkyl group is preferable.

When R^{b11} is an optionally substituted phenyl group, neither the number of substituents nor the position to which a substituent is bonded is particularly limited as long as the objects of the present invention are not inhibited. When R^{b11} is an optionally substituted phenyl group, the optionally substituted phenyl group is preferably an optionally substituted o-tolyl group for excellent efficiency of base generation.

When R^{b11} is an optionally substituted carbazolyl group, the type of the substituent is not particularly limited as long as the objects of the present invention are not inhibited. Examples of a suitable substituent that the carbazolyl group may have on a carbon atom include an alkyl group having 1 or more and 20 or less carbon atoms, an alkoxy group having 1 or more and 20 or less carbon atoms, a cycloalkyl group having 3 or more and 10 or less carbon atoms, a cycloalkoxy group having 3 or more and 10 or less carbon atoms, a saturated aliphatic acyl group having 2 or more and 20 or less carbon atoms, an alkoxycarbonyl group having 2 or more and 20 or less carbon atoms, a saturated aliphatic acyloxy group having 2 or more and 20 or less carbon atoms, an optionally substituted phenyl group, an optionally substituted phenoxy group, an optionally substituted phenylthio group, an optionally substituted phenylcarbonyl group, an optionally substituted benzoyl group, an optionally substituted phenoxycarbonyl group, an optionally substituted benzoyloxy group, an optionally substituted phenylalkyl group having 7 or more and 20 or less carbon atoms, an optionally substituted naphthyl group, an optionally substituted naphthoxy group, an optionally substituted naphthylcarbonyl group, an optionally substituted naphthoyl group, an optionally substituted naphthoxycarbonyl group, an optionally substituted naphthoyloxy group, an optionally substituted naphthylalkyl group having 11 or more and 20 or less carbon atoms, an optionally substituted heterocyclyl group, an optionally substituted heterocyclylcarbonyl group, an amino group, an amino group substituted with one or two organic groups, a morpholin-1-yl group, a piperazin-1-yl group, a halogen, a nitro group, and a cyano group.

When R^{b11} is an optionally substituted carbazolyl group, examples of a suitable substituent that the carbazolyl group may have on the nitrogen atom include an alkyl group having 1 or more and 20 or less carbon atoms, a cycloalkyl group having 3 or more and 10 or less carbon atoms, a saturated aliphatic acyl group having 2 or more and 20 or less carbon atoms, an alkoxycarbonyl group having 2 or more and 20 or less carbon atoms, an optionally substituted phenyl group, an optionally substituted benzoyl group, an optionally substituted phenoxycarbonyl group, an optionally substituted phenylalkyl group having 7 or more and 20 or less carbon atoms, an optionally substituted naphthyl group, an optionally substituted naphthoyl group, an optionally substituted naphthoxycarbonyl group, an optionally substituted naphthylalkyl group having 11 or more and 20 or less carbon atoms, an optionally substituted heterocyclyl group, and an optionally substituted heterocyclylcarbonyl group. Among these substituents, an alkyl group having 1 or more and 20 or less carbon atoms is preferable, an alkyl group having 1 or more and 6 or less carbon atoms is more preferable, and an ethyl group is particularly preferable.

For an alkyl group, an alkoxy group, a cycloalkyl group, a cycloalkoxy group, a saturated aliphatic acyl group, an alkoxycarbonyl group, a saturated aliphatic acyloxy group, an optionally substituted phenylalkyl group, an optionally substituted naphthylalkyl group, an optionally substituted heterocyclyl group, and an amino group substituted with one or two organic groups, specific examples of the substituent that the carbazolyl group may have are the same as the examples of a substituent of the phenyl group when R^{b11} is an optionally substituted phenyl group.

For R^{b11}, when a phenyl group, a naphthyl group, and a heterocyclyl group in a substituent of the carbazolyl group further have a substituent, examples of the further substituent include an alkyl group having 1 or more and 6 or less carbon atoms; an alkoxy group having 1 or more and 6 or less carbon atoms; a saturated aliphatic acyl group having 2 or more and 7 or less carbon atoms; an alkoxycarbonyl group having 2 or more and 7 or less carbon atoms; a saturated aliphatic acyloxy group having 2 or more and 7 or less carbon atoms; a phenyl group; a naphthyl group; a benzoyl group; a naphthoyl group; a benzoyl group substituted with a group selected from the group consisting of an alkyl group having 1 or more and 6 or less carbon atoms, a morpholin-1-yl group, a piperazin-1-yl group, and a phenyl group; a monoalkylamino group having an alkyl group having 1 or more and 6 or less carbon atoms; a dialkylamino group having an alkyl group having 1 or more and 6 or less carbon atoms; a morpholin-1-yl group; a piperazin-1-yl group; a halogen; a nitro group; and a cyano group. When a phenyl group, a naphthyl group, and a heterocyclyl group in a substituent of the carbazolyl group further have a substituent, the number of further substituents is not limited as long as the objects of the present invention are not inhibited, and is preferably 1 or more and 4 or less. When the phenyl group, the naphthyl group, and the heterocyclyl group have a plurality of substituents, the plurality of substituents may be the same as or different from each other.

R^{b12} represents an optionally substituted alkyl group having 1 or more and 10 or less carbon atoms, an optionally substituted phenyl group, or an optionally substituted carbazolyl group.

When R^{b12} is an optionally substituted alkyl group having 1 or more and 10 or less carbon atoms, the alkyl group may be linear or branched. In this case, the number of carbon atoms of the alkyl group is preferably 1 or more and 8 or less, and more preferably 1 or more and 5 or less.

For R^{b12}, there is no particular limitation for substituents on the alkyl group, or the phenyl group as long as the object of the present invention is not inhibited. Examples of suitable substituents which the alkyl group may have on the carbon atom include an alkoxy group having 1 or more and 20 or less carbon atoms, a cycloalkyl group having 3 or more and 10 or less carbon atoms, a cycloalkoxy group having 3 or more and 10 or less carbon atoms, a saturated aliphatic acyl group having 2 or more and 20 or less carbon atoms, an alkoxycarbonyl group having 2 or more and 20 or less carbon atoms, a saturated aliphatic acyloxy group having 2 or more and 20 or less carbon atoms, an optionally substituted phenyl group, an optionally substituted phenoxy group, an optionally substituted phenylthio group, an optionally substituted benzoyl group, an optionally substituted phenoxycarbonyl group, an optionally substituted benzoyloxy group, an optionally substituted phenylalkyl group having 7 or more and 20 or less carbon atoms, an optionally substituted naphthyl group, an optionally substituted naphthoxy group, an optionally substituted naphthoyl group, an optionally substituted naphthoxycarbonyl group, an optionally substituted naphthoyloxy group, an optionally substituted naphthylalkyl group having 11 or more and 20 or less carbon atoms, an optionally substituted heterocyclyl group, an optionally substituted heterocyclylcarbonyl group, an amino group, an amino group substituted with one or two organic groups, a morpholin-1-yl group, a piperazin-1-yl group, halogen, a nitro group, a cyano group and the like. Examples of a suitable substituent that the phenyl group may have on a carbon atom include the above examples of groups as a suitable substituent that the alkyl group may have on a carbon atom and an alkyl group having 1 or more and 20 or less carbon atoms.

For an alkyl group, an alkoxy group, a cycloalkyl group, a cycloalkoxy group, a saturated aliphatic acyl group, an alkoxycarbonyl group, a saturated aliphatic acyloxy group, an optionally substituted phenylalkyl group, an optionally substituted naphthylalkyl group, an optionally substituted heterocyclyl group and an amino group substituted with one or two organic groups, specific examples of optional substituents on the alkyl group, or the phenyl group are the same as the examples of a substituent of the phenyl group when R^{b11} is an optionally substituted phenyl group.

In a case where the phenyl group, the naphthyl group and the heterocyclyl group included in the substituent on the alkyl group or the phenyl group in R^{b12} further have a substituent, examples of the further substituent include an alkyl group having 1 or more and 6 or less carbon atoms; an alkoxy group having 1 or more and 6 or less carbon atoms; a saturated aliphatic acyl group having 2 or more and 7 or less carbon atoms; an alkoxycarbonyl group having 2 or more and 7 or less carbon atoms; a saturated aliphatic acyloxy group having 2 or more and 7 or less carbon atoms; a phenyl group; a naphthyl group; a benzoyl group; a naphthoyl group; a benzoyl group substituted with a group selected from the group consisting of an alkyl group having 1 or more and 6 or less carbon atoms, a morpholin-1-yl group, a piperazin-1-yl group and a phenyl group; a monoalkylamino group having an alkyl group having 1 or more and 6 or less carbon atoms; a dialkylamino group having an alkyl group having 1 or more and 6 or less carbon atoms; a morpholin-1-yl group; a piperazin-1-yl group; halogen; a nitro group; and a cyano group. In a case where the phenyl group, the naphthyl group and the heterocyclyl group included in the substituent on the alkyl group or the phenyl group further have a substituent, the number of further substituents is not limited as long as the objects of the present invention are not inhibited, and is preferably 1 or more and 4 or less. In a case where the phenyl group, the naphthyl group and the heterocyclyl group have a plurality of substituents, the substituents may be the same as or different from each other.

When R^{b12} is an optionally substituted carbazolyl group, the type of the substituent possessed by the carbazolyl group is not particularly limited as long as the objects of the present invention are not inhibited. Suitable examples of the substituent that the carbazolyl group may have are the same as the examples of a substituent of the substituent when R^{b11} is the optionally substituted carbazolyl group.

In view of reactivity of the compound represented by formula (cl), R^{b12} is preferably a group represented by the following formula (b2) or (b3).

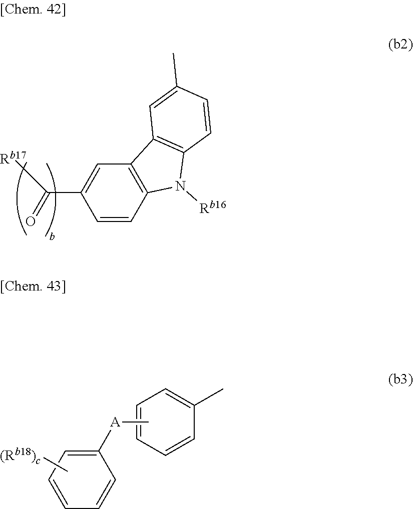

In the formula (b2), R^{b16} and R^{b17} is respectively a monovalent organic group, and b is 0 or 1. In the formula (b3), R^{b18} is a group selected from the group consisting of a monovalent organic group, an amino group, a halogen atom, a nitro group, and a cyano group, A is S or O, and c is an integer of 0 or more and 4 or less.

R^{cb6} in the formula (b2) can be selected from various kinds of organic groups as long as objects of the present invention are not inhibited. Suitable examples of R^{b16} include a hydrogen atom, an alkyl group having 1 or more and 20 or less carbon atoms, a cycloalkyl group having 3 or more and 10 or less carbon atoms, a saturated aliphatic acyl group having 2 or more and 20 or less carbon atoms, an alkoxycarbonyl group having 2 or more and 20 or less carbon atoms, an optionally substituted phenyl group, an optionally substituted benzoyl group, an optionally substituted phenoxycarbonyl group, an optionally substituted phenylalkyl group having 7 or more and 20 or less carbon atoms, an optionally substituted naphthyl group, an optionally substituted naphthoyl group, an optionally substituted naphthoxycarbonyl group, an optionally substituted naphthylalkyl group having 11 or more and 20 or less carbon atoms, an optionally substituted heterocyclyl group, an optionally substituted heterocyclylcarbonyl group, and the like.

For R^{b16}, the alkyl group having 1 or more and 20 or less carbon atoms is preferable, the alkyl group having 1 or more and 6 or less carbon atoms is more preferable, and the ethyl group is particularly preferable.

R^{b17} in the formula (b2) can be selected from various kinds of organic groups as long as objects of the present invention are not inhibited. Specific examples of the suitable group as R^{b17} include a hydrogen atom, an alkyl group having 1 or more and 20 or less carbon atoms, an optionally substituted phenyl group, an optionally substituted naphthyl group, and an optionally substituted heterocyclyl group. For R^{b17}, among these groups, the optionally substituted phenyl group and the optionally substituted naphthyl group are more preferable, and a 2-methylphenyl group and a naphthyl group are particularly preferable.

When a phenyl group, a naphthyl group, and a heterocyclyl group included in R^{b16} or R^{b17} further has a substituent, examples of the substituent include an alkyl group having 1 or more and 6 or less carbon atoms, an alkoxy group having 1 or more and 6 or less carbon atoms, a saturated aliphatic acyl group having 2 or more and 7 or less carbon atoms, an alkoxycarbonyl group having 2 or more and 7 or less carbon atoms, a saturated aliphatic acyloxy group having 2 or more and 7 or less carbon atoms, a monoalkylamino group having an alkyl group which has 1 or more and 6 or less carbon atoms, a dialkylamino group having an alkyl group which has 1 or more and 6 or less carbon atoms, a morpholin-1-yl group, a piperazin-1-yl group, halogen, a nitro group, and a cyano group. When a phenyl group, a naphthyl group, and a heterocyclyl group included in R^{b16} or R^{b17} further have a substituent, the number of substituents is not particularly limited as long as the object of the present invention is not inhibited, and is preferably 1 or more and 4 or less. When a phenyl group, a naphthyl group, and a heterocyclyl group included in R^{b16} or R^{b17} have plural substituents, plural substituents may be the same as or different each other.

When R^{b18} in the formula (b3) is the organic group, R^{b18} can be selected from various kinds of organic groups as long as objects of the present invention are not inhibited. When R^{b18} is the organic group in the formula (b3), suitable examples include an alkyl group having 1 or more and 6 or less carbon atoms; an alkoxy group having 1 or more and 6 or less carbon atoms; a saturated aliphatic acyl group having 2 or more and 7 or less carbon atoms; an alkoxycarbonyl group having 2 or more and 7 or less carbon atoms; a saturated aliphatic acyloxy group having 2 or more and 7 or less carbon atoms; a phenyl group; a naphthyl group; a benzoyl group; a naphthoyl group; a benzoyl group substituted with a group selected from the group consisting of an alkyl group having 1 or more and 6 or less carbon atoms, morpholin-1-yl group, piperazin-1-yl group, and a phenyl group; a monoalkylamino group having an alkyl group having 1 or more and 6 or less carbon atoms; a dialkylamino group having alkyl groups having 1 or more and 6 or less carbon atoms; a morpholin-1-yl group; a piperazin-1-yl group; a halogen atom; a nitro group; a cyano group; a 2-methylphenylc carbonyl group; a 4-(piperazine-1-yl)phenylcarbonyl group; 4-(phenyl)phenylcarbonyl group.

Among R^{b18}, a benzoyl group; a naphthoyl group; a benzoyl groups substituted with a group selected from the group consisting of an alkyl group having 1 or more and 6 or less carbon atoms, a morpholine-1-yl group, a piperazine-1-yl group, and a phenyl group; and a nitro group are preferred, and a benzoyl group; a naphthoyl group; a 2-methylphenyl carbonyl group; a 4-(piperazine-1-yl) phenyl carbonyl group; and a 4-(phenyl) phenyl carbonyl group are more preferred.

In formula (b3), c is preferably an integer of 0 or more and 3 or less, more preferably an integer of 0 or more and 2 or less, and particularly preferably 0 or 1. When c is 1, the position at which R^{b18} bonds is preferably the para-position to the bonding through which the phenyl group (to which R^{b18} bonds) bonds to an oxygen atom or a sulfur atom.

R^{b13} is a hydrogen atom, an alkyl group having 1 or more and 6 or less carbon atoms, or an optionally substituted phenyl group. When R^{b13} is the optionally substituted phenyl group, a substituent that the phenyl group may have is the same as that in the case where R^{b11} is the optionally substituted phenyl group. R^{b13} is preferably a methyl group, an ethyl group, or a phenyl group, and more preferably a methyl group or a phenyl group.

As a suitable compound among the compounds represented by the formula (b1), a compound represented by the formula (b4) is exemplified.

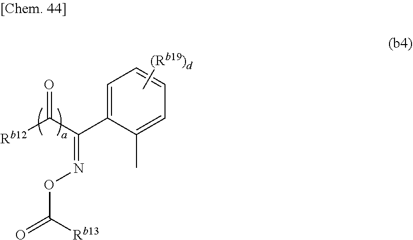

a, R^{b12}, and R^{b13} in the formula (b4) are the same as described previously. R^{b19} is a group selected from the group consisting of a monovalent organic group, an amino group, a halogen atom, a nitro group, and a cyano group, and d is an integer of 0 or more and 4 or less.

In the above formula (b4), R^{b19} is not particularly limited as long as objects of the present invention are not inhibited, and is appropriately selected from various organic groups, when R^{c19} is the organic group. Suitable examples of the R^{b19} include an alkyl group, an alkoxy group, a cycloalkyl group, a cycloalkoxy group, a saturated aliphatic acyl group, a saturated aliphatic acyloxy group, an alkoxycarbonyl group, an optionally substituted phenyl group, an optionally substituted phenoxy group, an optionally substituted benzoyl group, an optionally substituted phenoxycarbonyl group, an optionally substituted benzoyloxy group, an optionally substituted phenylalkyl group, an optionally substituted naphthyl group, an optionally substituted naphthoxy group, an optionally substituted naphthoyl group, an optionally substituted naphthoxycarbonyl group, an optionally substituted naphthoyloxy group, an optionally substituted naphthylalkyl group, an optionally substituted heterocyclyl group, an amino group, an amino group substituted with one or two organic groups, a morpholin-1-yl group, a piperazin-1-yl group, a halogen atom, a nitro group, a cyano group, and the like. When s is an integer of 2 or more and 4 or less, the plurality of R^{b19} may be the same or different. The number of carbon atoms of the substituent does not include the number of carbon atoms of the further substituent that the substituent has.

When R^{b19} is the alkyl group, the number of carbon atoms is preferably 1 or more and 20 or less, and more preferably 1 or more and 6 or less. In addition, when R^{b19} is the alkyl group, the alkyl group may be linear or branched. When R^{b19} is the alkyl group, specific examples include a methyl group, an ethyl group, an n-propyl group, an isopropyl group, an n-butyl group, an isobutyl group, a sec-butyl group, a tert-butyl group, an n-pentyl group, an isopentyl group, a sec-pentyl group, a tert-pentyl group, an n-hexyl group, an n-heptyl group, an n-octyl group, an isooctyl group, a sec-octyl group, a tert-octyl group, an n-nonyl group, an isononyl group, an n-decyl group, an isodecyl group, and the like. In addition, when R^{b19} is the alkyl group, the alkyl group may include ether bond(s) in the carbon chain. Examples of the alkyl group including ether bond(s) in the carbon chain include a methoxyethyl group, an ethoxyethyl group, a methoxyethoxyethyl group, an ethoxyethoxyethyl group, a propyloxyethoxyethyl group, a methoxypropyl group, and the like.

When R^{b19} is the alkoxy group, the number of carbon atoms is preferably 1 or more and 20 or less, and more preferably 1 or more and 6 or less. In addition, when R^{b19} is the alkoxy group, the alkoxy group may be linear or branched. When R^{b19} is the alkoxy group, specific examples include a methoxy group, an ethoxy group, an n-propyloxy group, an isopropyloxy group, an n-butyloxy group, an isobutyloxy group, a sec-butyloxy group, a tert-butyloxy group, an n-pentyloxy group, an isopentyloxy group, a sec-pentyloxy group, a tert-pentyloxy group, an n-hexyloxy group, an n-heptyloxy group, an n-octyloxy group, an isooctyloxy group, a sec-octyloxy group, a tert-octyloxy group, an n-nonyloxy group, an isononyloxy group, an n-decyloxy group, an isodecyloxy group, and the like. When R^{b19} is the alkoxy group, the alkoxy group may include an ether bond (—O—) in the carbon chain. Examples of the alkoxy group having an ether bond in the carbon chain include a methoxyethoxy group, an ethoxyethoxy group, a methoxyethoxyethoxy group, an ethoxyethoxyethoxy group, a propyloxyethoxyethoxy group, a methoxypropyloxy group, and the like.

When R^{b19} is a cycloalkyl group or a cycloalkoxy group, the number of carbon atoms of the cycloalkyl group or cycloalkoxy group is preferably 3 or more and 10 or less, and more preferably 3 or more and 6 or less. When R^{b19} is the cycloalkyl group, specific examples include a cyclopropyl group, a cyclobutyl group, a cyclopentyl group, a cyclohexyl group, a cycloheptyl group, a cyclooctyl group, and the like. When R^{b19} is the cycloalkoxy group, specific examples include a cyclopropyloxy group, a cyclobutyloxy group, a cyclopentyloxy group, a cyclohexyloxy group, a cycloheptyloxy group, a cyclooctyloxy group, and the like.

When R^{b19} is the saturated aliphatic acyl group or the saturated aliphatic acyloxy group, the number of carbo atoms is preferably 2 or more and 20 or less, and more preferably 2 or more and 7 or less. When R^{b19} is the saturated aliphatic acyl group, specific examples include an acetyl group, a propanoyl group, an n-butanoyl group, a 2-methylpropanoyl group, an n-pentanoyl group, a 2,2-dimethylpropanoyl group, an n-hexanoyl group, an n-heptanoyl group, an n-octanoyl group, an n-nonanoyl group, an n-decanoyl group, an n-undecanoyl group, an n-dodecanoyl group, an n-tridecanoyl group, an n-tetradecanoyl group, an n-pentadecanoyl group, an n-hexadecanoyl group, and the like. When R^{b19} is the saturated aliphatic acyloxy group, specific examples include an acetyloxy group, a propanoyloxy group, an n-butanoyloxy group, a 2-methylpropanoyloxy group, an n-pentanoyloxy group, a 2,2-dimethylpropanoyloxy group, an n-hexanoyloxy group, an n-heptanoyloxy group, an n-octanoyloxy group, an n-nonanoyloxy group, an n-decanoyloxy group, an n-undecanoyloxy group, an n-dodecanoyloxy group, an n-tridecanoyloxy group, an n-tetradecanoyloxy group, an n-pentadecanoyloxy group, an n-hexadecanoyloxy group, and the like.

When R^{b19} is the alkoxycarbonyl group, the number of carbon atoms is preferably 2 or more and 20 or less, and more preferably 2 or more and 7 or less. When R^{b19} is the alkoxycarbonyl group, specific examples include a methoxycarbonyl group, an ethoxycarbonyl group, an n-propyloxycarbonyl group, an isopropyloxycarbonyl group, an n-butyloxycarbonyl group, an isobutyloxycarbonyl group, a sec-butyloxycarbonyl group, a tert-butyloxycarbonyl group, an n-pentyloxycarbonyl group, an isopentyloxycarbonyl group, a sec-pentyloxycarbonyl group, a tert-pentyloxycarbonyl group, an n-hexyloxycarbonyl group, an n-heptyloxycarbonyl group, an n-octyloxycarbonyl group, an isooctyloxycarbonyl group, a sec-octyloxycarbonyl group, a tert-octyloxycarbonyl group, an n-nonyloxycarbonyl group, an isononyloxycarbonyl group, an n-decyloxycarbonyl group, an isodecyloxycarbonyl group, and the like.

When R^{b19} is the phenylalkyl group, the number of carbon atoms is preferably 7 or more and 20 or less, and more preferably 7 or more and 10 or less. When R^{b19} is the naphthylalkyl group, the number of carbon atoms is preferably 11 or more and 20 or less, and more preferably 11 or more and 14 or less. When R^{b19} is the phenyl alkyl group, specific examples include a benzyl group, a 2-phenylethyl group, 3-phenylpropyl group and 4-phenylbutyl group. When R^{b19} is the naphthylalkyl group, specific examples include an a-naphthylmethyl group, a P-naphthylmethyl group, a 2-(a-naphthyl)ethyl group, and a 2-(D-naphthyl)ethyl group. When R^{b19} is the phenylalkyl group or the naphthylalkyl group, R^{b19} may further have substituent(s) on the phenyl group or the naphthyl group.

When R^{b19} is a heterocyclyl group, the heterocyclyl group is a 5-membered or 6-membered monocycle containing one or more N, S, and O, or a heterocyclyl group in which these monocycles are fused, or the monocycle and a benzene ring are fused. When the heterocyclyl group is a fused ring, the number of rings constituting the fused ring is 3 or less. Examples of the heterocycle constituting the heterocyclic group include furan, thiophene, pyrrole, oxazole, isoxazole, thiazole, thiadiazole, isothiazole, imidazole, pyrazole, triazole, pyridine, pyrazine, pyrimidine, pyridazine, benzofuran, benzothiophene, indole, isoindole, indolizine, benzimidazole, benzotriazole, benzoxazole, benzothiazole, carbazole, purine, quinoline, isoquinoline, quinazoline, phthalazine, cinnoline, quinoxaline, and the like. When R^{b19} is a heterocyclyl group, the heterocyclyl group may have a substituent.

When R^{b19} is an amino group substituted with one or two organic groups, suitable examples of the organic group include an alkyl group having 1 or more and 20 or less carbon atoms, a cycloalkyl group having 3 or more and 10 or less carbon atoms, a saturated aliphatic acyl group having 2 or more and 20 or less carbon atoms, a phenyl group which may have a substituent, a benzoyl group which may have a substituent, a phenylalkyl group having 7 or more and 20 or less carbon atoms which may have a substituent, a naphthyl group which may have a substituent, a naphthoyl group which may have a substituent, a naphthylalkyl group having 11 or more and 20 or less carbon atoms which may have a substituent, a heterocyclyl group, and the like. Specific examples of suitable organic group are the same as those in R^{b19}. Specific examples of the amino group substituted with one 1 or 2 organic groups include a methylamino group, an ethylamino group, a diethylamino group, an n-propylamino group, a di-n-propylamino group, an isopropylamino group, an n-butylamino group, a di-n-butylamino group, an n-pentylamino group, an n-hexylamino group, an n-heptylamino group, an n-octylamino group, an n-nonylamino group, an n-decylamino group, a phenylamino group, a naphthylamino group, an acetylamino group, a propanoylamino group, an n-butanoylamino group, an n-pentanoyl amino group, an n-hexanoylamino group, an n-heptanoylamino group, an n-octanoylamino group, an n-decanoylamino group, a benzoylamino group, an a-naphthoyl group, a R-naphthoyl group, and the like.

When an phenyl group, an naphthyl group, and a heterocyclyl group included in R^{b19} further have a substituent, examples of the substituent include an alkyl group having 1 or more and 6 or less carbon atoms, an alkoxy group having 1 or more and 6 or less carbon atoms, a saturated aliphatic acyl group having 2 or more and 7 or less carbon atoms, an alkoxycarbonyl group having 2 or more and 7 or less carbon atoms, a saturated aliphatic acyloxy group having 2 or more and 7 or less carbon atoms, a monoalkylamino group which has an alkyl group having 1 or more and 6 or less carbon atoms, a dialkylamino group which has two alkyl groups having 1 or more and 6 or less carbon atoms, a morpholin-1-yl group, an piperazin-1-yl group, halogen, a nitro group, a cyano group, and the like. When a phenyl group, a naphthyl group, and a heterocyclyl group included in R^{b19} further have a substituent, the number of substituents is not particularly limited as long as the object of the present invention is not inhibited, and is preferably 1 or more and 4 or less. When a phenyl group, a naphthyl group, and a heterocyclyl group included in R^{b19} have plural substituents, plural substituents may be the same as or different each other.

Among R^{b19}, a group selected from the group consisting of an alkyl group having 1 or more and 6 or less carbon atoms, an alkoxy group having 1 or more and 6 or less carbon atoms, and a saturated aliphatic acyl group having 2 or more and 7 or less carbon atoms is preferred, an alkyl group having 1 or more and 6 or less carbon atoms is more preferred, and a methyl group is particularly preferable from the viewpoint of chemical stability and easiness of synthesis of an oxime ester compound with less steric hindrance.

When the position of a bond of a phenyl group and a main skeleton of an oxime ester compound is regarded as the 1-position and the position of a methyl group is regarded as the 2-position with respect to the phenyl group to which R^{b19} is bonded, the position at which R^{b19} is bonded to a phenyl group is preferably the 4-position or the 5-position, more preferably the 5-position. d is preferably an integer of 0 or more and 3 or less, more preferably an integer of 0 or more and 2 or less, and particularly preferably 0 or 1.

R^{b13} in the formula (b4) is a hydrogen atom, an alkyl group having 1 or more and 6 or less carbon atoms, or an optionally substituted phenyl group. Specific examples of R^{b13} are the same as described previously for the formula (b1). As R^{b13} in the formula (b4), a methyl group, an ethyl group, and a phenyl group are preferable, and a methyl group, and phenyl group are more preferable.

Among the oxime ester compounds, suitable examples of a compound included in the formula (b1) but not in the formula (b4) include the following compounds.

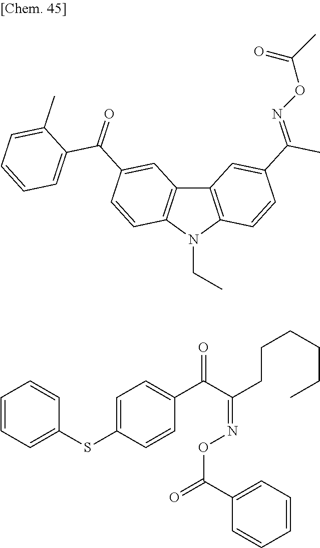 [SMILES: CCn1c2ccc(C(=O)c3ccccc3C)cc2c2cc(/C(C)=N/OC(C)=O)ccc21 ; CCCCCC/C(=N/OC(=O)c1ccccc1)C(=O)c1ccc(Sc2ccccc2)cc1]

Among the oxime ester compounds represented by the formula (b4) that is particularly suitable as the oxime ester compound, examples of the particularly suitable compound include the following compounds.

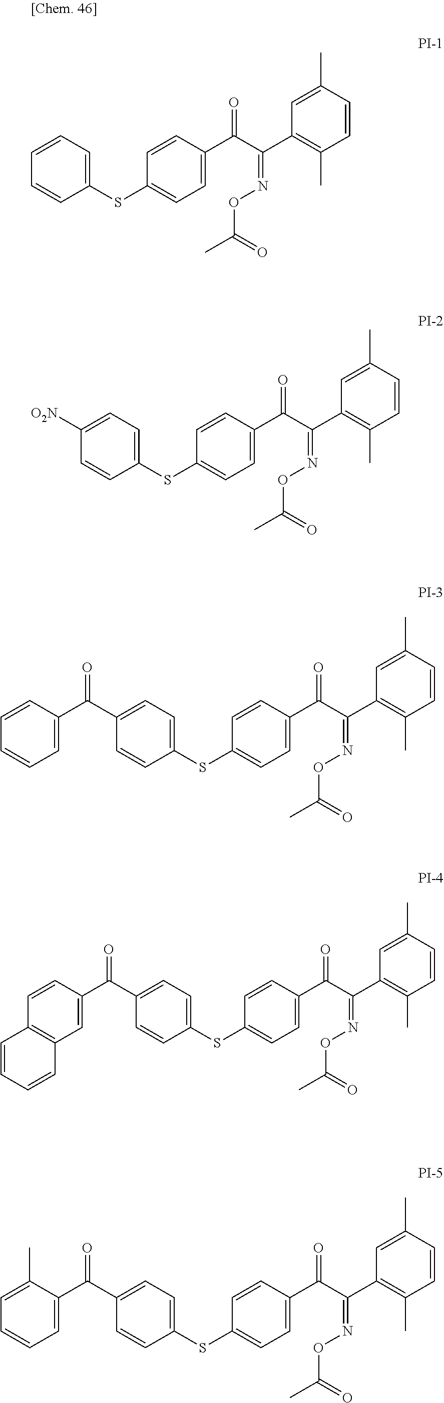 [SMILES: CC(=O)O/N=C(\C(=O)c1ccc(Sc2ccccc2)cc1)c1cc(C)ccc1C ; CC(=O)O/N=C(\C(=O)c1ccc(Sc2ccc([N+](=O)[O-])cc2)cc1)c1cc(C)ccc1C ; CC(=O)O/N=C(\C(=O)c1ccc(Sc2ccc(C(=O)c3ccccc3)cc2)cc1)c1cc(C)ccc1C ; CC(=O)O/N=C(\C(=O)c1ccc(Sc2ccc(C(=O)c3ccc4ccccc4c3)cc2)cc1)c1cc(C)ccc1C ; CC(=O)O/N=C(\C(=O)c1ccc(Sc2ccc(C(=O)c3ccccc3C)cc2)cc1)c1cc(C)ccc1C]

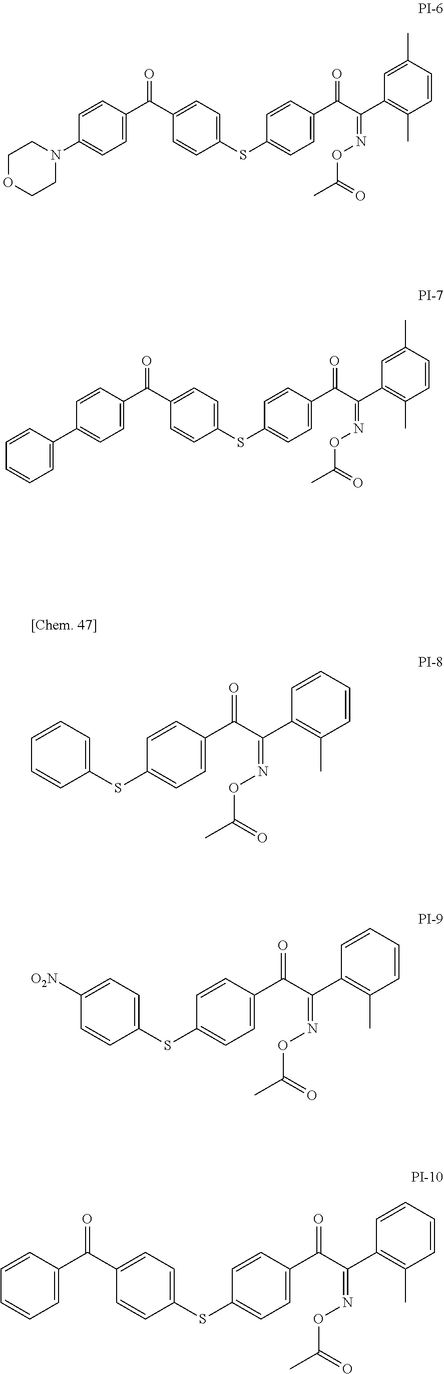 [SMILES: CC(=O)O/N=C(\C(=O)c1ccc(Sc2ccc(C(=O)c3ccc(N4CCOCC4)cc3)cc2)cc1)c1cc(C)ccc1C ; CC(=O)O/N=C(\C(=O)c1ccc(Sc2ccc(C(=O)c3ccc(-c4ccccc4)cc3)cc2)cc1)c1cc(C)ccc1C ; CC(=O)O/N=C(\C(=O)c1ccc(Sc2ccccc2)cc1)c1ccccc1C ; CC(=O)O/N=C(\C(=O)c1ccc(Sc2ccc([N+](=O)[O-])cc2)cc1)c1ccccc1C ; CC(=O)O/N=C(\C(=O)c1ccc(Sc2ccc(C(=O)c3ccccc3)cc2)cc1)c1ccccc1C]

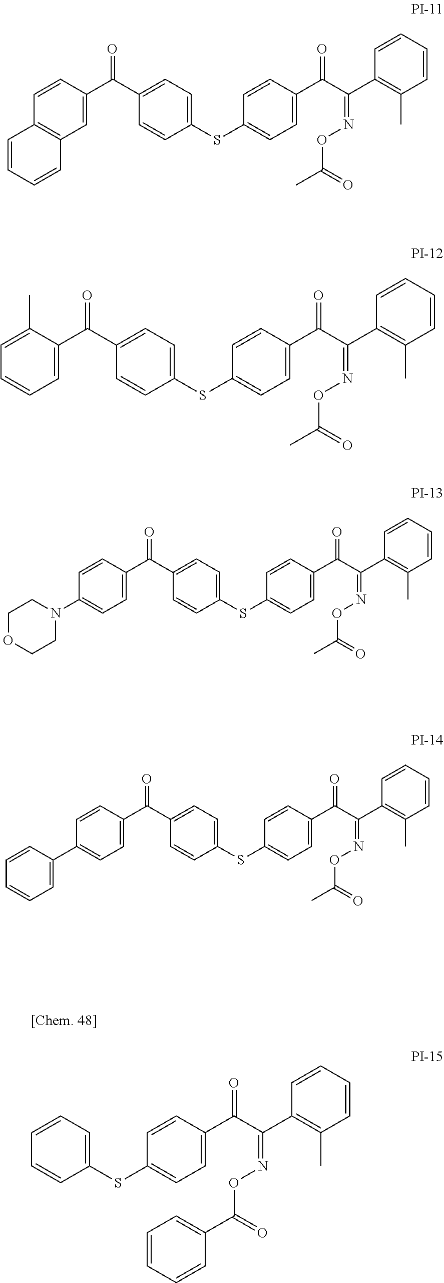 [SMILES: CC(=O)O/N=C(\C(=O)c1ccc(Sc2ccc(C(=O)c3ccc4ccccc4c3)cc2)cc1)c1ccccc1C ; CC(=O)O/N=C(\C(=O)c1ccc(Sc2ccc(C(=O)c3ccccc3C)cc2)cc1)c1ccccc1C ; CC(=O)O/N=C(\C(=O)c1ccc(Sc2ccc(C(=O)c3ccc(N4CCOCC4)cc3)cc2)cc1)c1ccccc1C ; CC(=O)O/N=C(\C(=O)c1ccc(Sc2ccc(C(=O)c3ccc(-c4ccccc4)cc3)cc2)cc1)c1ccccc1C ; Cc1ccccc1/C(=N/OC(=O)c1ccccc1)C(=O)c1ccc(Sc2ccccc2)cc1]

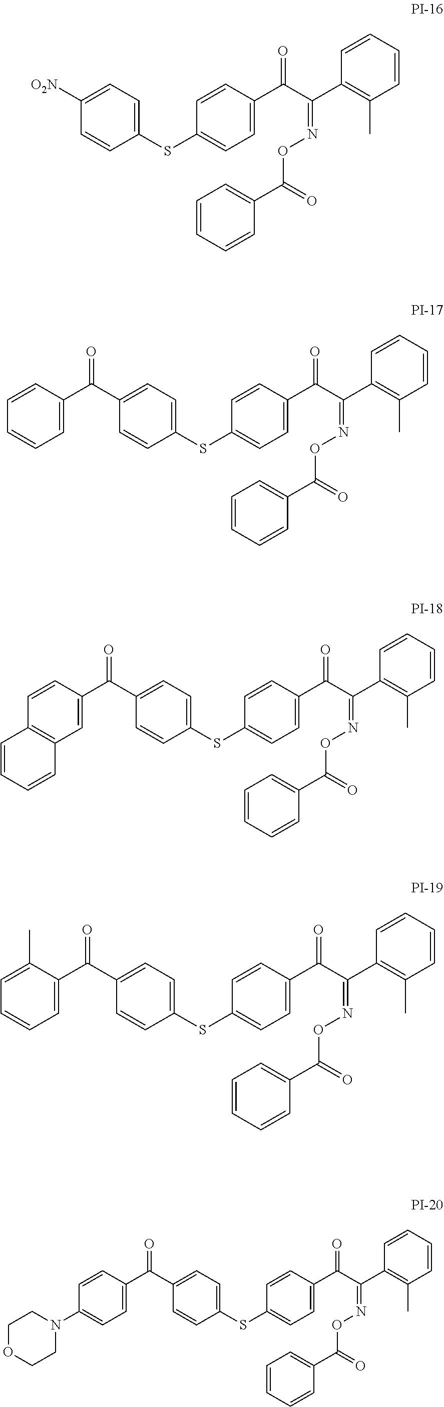 [SMILES: Cc1ccccc1/C(=N/OC(=O)c1ccccc1)C(=O)c1ccc(Sc2ccc([N+](=O)[O-])cc2)cc1 ; Cc1ccccc1/C(=N/OC(=O)c1ccccc1)C(=O)c1ccc(Sc2ccc(C(=O)c3ccccc3)cc2)cc1 ; Cc1ccccc1/C(=N/OC(=O)c1ccccc1)C(=O)c1ccc(Sc2ccc(C(=O)c3ccc4ccccc4c3)cc2)cc1 ; Cc1ccccc1C(=O)c1ccc(Sc2ccc(C(=O)/C(=N\OC(=O)c3ccccc3)c3ccccc3C)cc2)cc1 ; Cc1ccccc1/C(=N/OC(=O)c1ccccc1)C(=O)c1ccc(Sc2ccc(C(=O)c3ccc(N4CCOCC4)cc3)cc2)cc1]

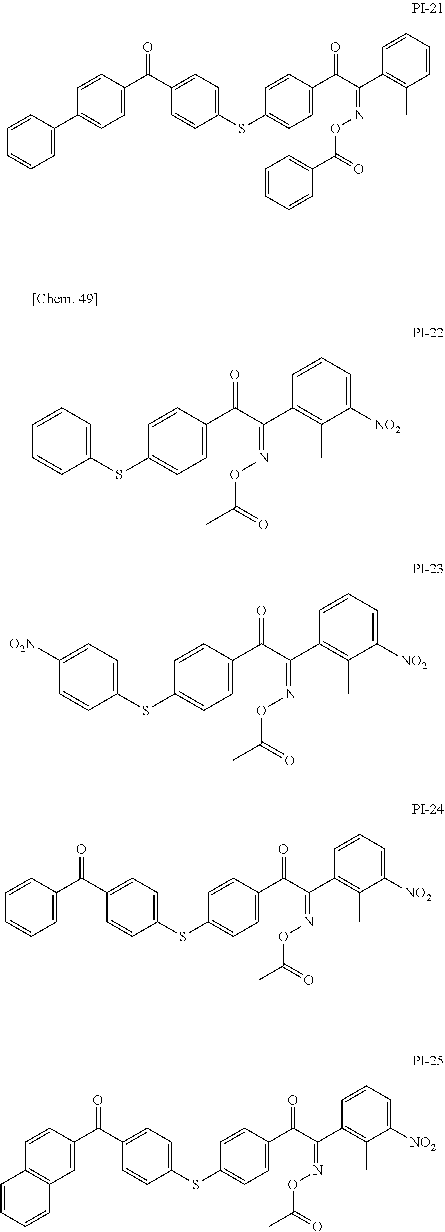 [SMILES: Cc1ccccc1/C(=N/OC(=O)c1ccccc1)C(=O)c1ccc(Sc2ccc(C(=O)c3ccc(-c4ccccc4)cc3)cc2)cc1 ; CC(=O)O/N=C(\C(=O)c1ccc(Sc2ccccc2)cc1)c1cccc([N+](=O)[O-])c1C ; CC(=O)O/N=C(\C(=O)c1ccc(Sc2ccc([N+](=O)[O-])cc2)cc1)c1cccc([N+](=O)[O-])c1C ; CC(=O)O/N=C(\C(=O)c1ccc(Sc2ccc(C(=O)c3ccccc3)cc2)cc1)c1cccc([N+](=O)[O-])c1C ; CC(=O)O/N=C(\C(=O)c1ccc(Sc2ccc(C(=O)c3ccc4ccccc4c3)cc2)cc1)c1cccc([N+](=O)[O-])c1C]

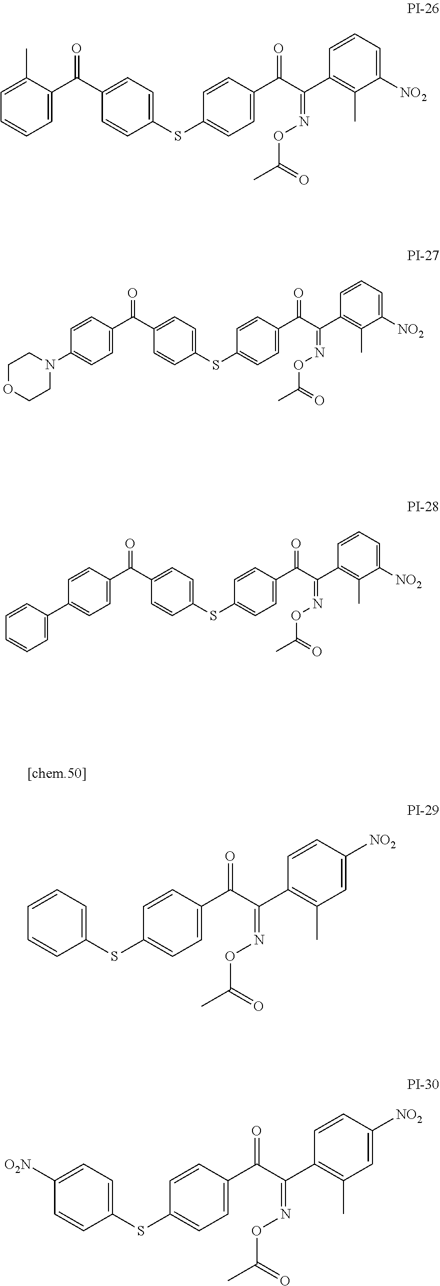 [SMILES: CC(=O)O/N=C(\C(=O)c1ccc(Sc2ccc(C(=O)c3ccccc3C)cc2)cc1)c1cccc([N+](=O)[O-])c1C ; CC(=O)O/N=C(\C(=O)c1ccc(Sc2ccc(C(=O)c3ccc(N4CCOCC4)cc3)cc2)cc1)c1cccc([N+](=O)[O-])c1C ; CC(=O)O/N=C(\C(=O)c1ccc(Sc2ccc(C(=O)c3ccc(-c4ccccc4)cc3)cc2)cc1)c1cccc([N+](=O)[O-])c1C ; CC(=O)O/N=C(\C(=O)c1ccc(Sc2ccccc2)cc1)c1ccc([N+](=O)[O-])cc1C ; CC(=O)O/N=C(\C(=O)c1ccc(Sc2ccc([N+](=O)[O-])cc2)cc1)c1ccc([N+](=O)[O-])cc1C]

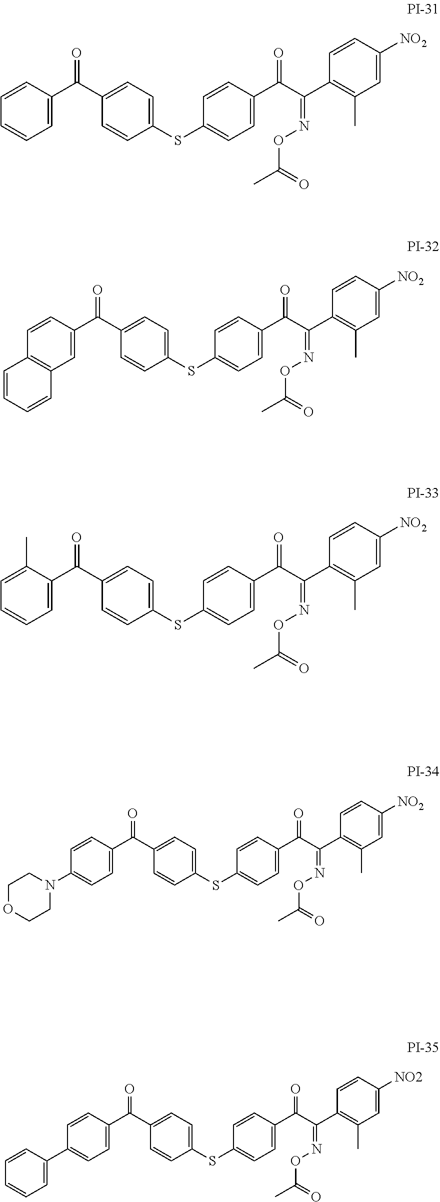 [SMILES: CC(=O)O/N=C(\C(=O)c1ccc(Sc2ccc(C(=O)c3ccccc3)cc2)cc1)c1ccc([N+](=O)[O-])cc1C ; CC(=O)O/N=C(\C(=O)c1ccc(Sc2ccc(C(=O)c3ccc4ccccc4c3)cc2)cc1)c1ccc([N+](=O)[O-])cc1C ; CC(=O)O/N=C(\C(=O)c1ccc(Sc2ccc(C(=O)c3ccccc3C)cc2)cc1)c1ccc([N+](=O)[O-])cc1C ; CC(=O)O/N=C(\C(=O)c1ccc(Sc2ccc(C(=O)c3ccc(N4CCOCC4)cc3)cc2)cc1)c1ccc([N+](=O)[O-])cc1C ; CC(=O)O/N=C(\C(=O)c1ccc(Sc2ccc(C(=O)c3ccc(-c4ccccc4)cc3)cc2)cc1)c1ccc([N+](=O)[O-])cc1C]

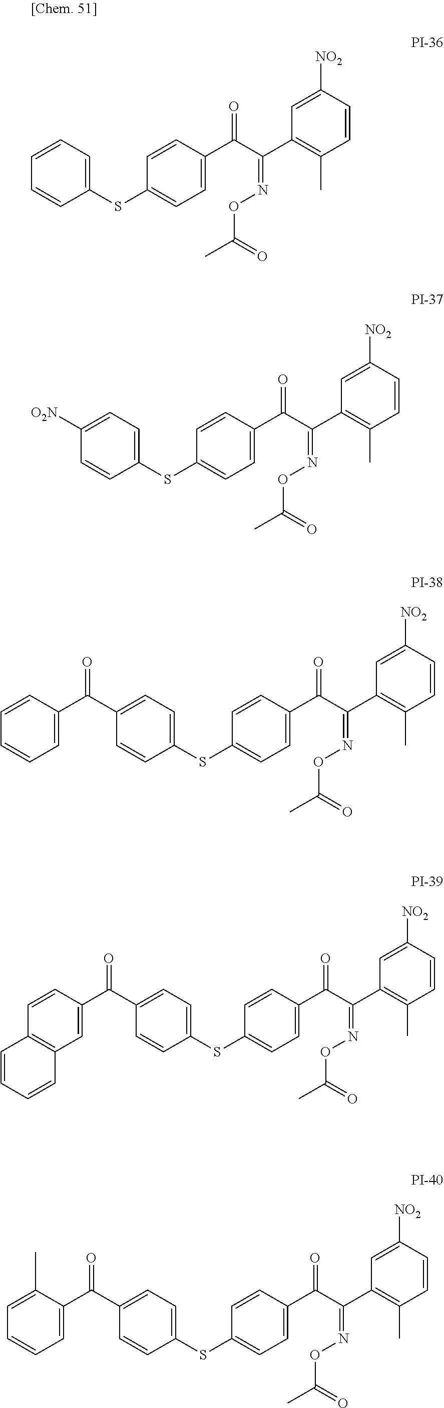 [SMILES: CC(=O)O/N=C(\C(=O)c1ccc(Sc2ccccc2)cc1)c1cc([N+](=O)[O-])ccc1C ; CC(=O)O/N=C(\C(=O)c1ccc(Sc2ccc([N+](=O)[O-])cc2)cc1)c1cc([N+](=O)[O-])ccc1C ; CC(=O)O/N=C(\C(=O)c1ccc(Sc2ccc(C(=O)c3ccccc3)cc2)cc1)c1cc([N+](=O)[O-])ccc1C ; CC(=O)O/N=C(\C(=O)c1ccc(Sc2ccc(C(=O)c3ccc4ccccc4c3)cc2)cc1)c1cc([N+](=O)[O-])ccc1C ; CC(=O)O/N=C(\C(=O)c1ccc(Sc2ccc(C(=O)c3ccccc3C)cc2)cc1)c1cc([N+](=O)[O-])ccc1C]

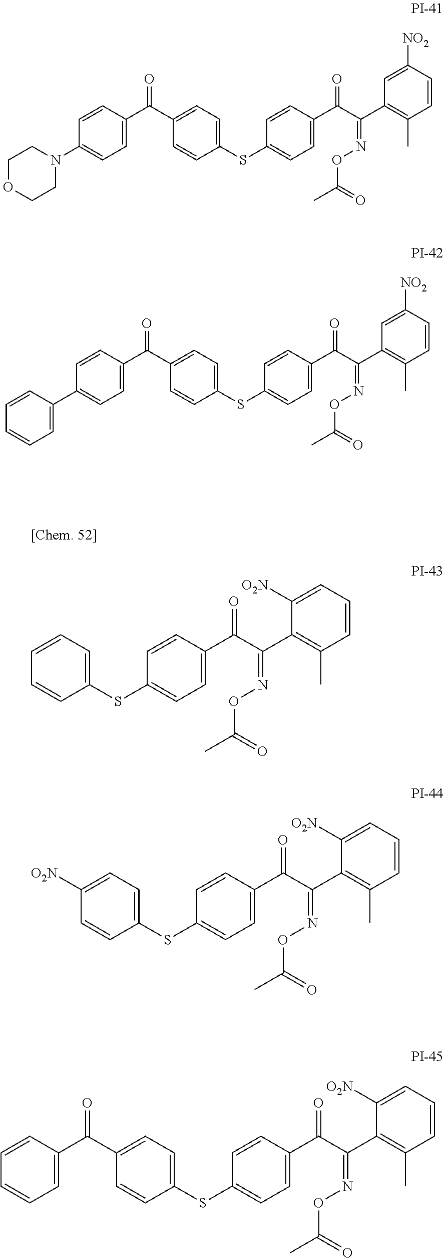 [SMILES: CC(=O)O/N=C(\C(=O)c1ccc(Sc2ccc(C(=O)c3ccc(N4CCOCC4)cc3)cc2)cc1)c1cc([N+](=O)[O-])ccc1C ; CC(=O)O/N=C(\C(=O)c1ccc(Sc2ccc(C(=O)c3ccc(-c4ccccc4)cc3)cc2)cc1)c1cc([N+](=O)[O-])ccc1C ; CC(=O)O/N=C(\C(=O)c1ccc(Sc2ccccc2)cc1)c1c(C)cccc1[N+](=O)[O-] ; CC(=O)O/N=C(\C(=O)c1ccc(Sc2ccc([N+](=O)[O-])cc2)cc1)c1c(C)cccc1[N+](=O)[O-] ; CC(=O)O/N=C(\C(=O)c1ccc(Sc2ccc(C(=O)c3ccccc3)cc2)cc1)c1c(C)cccc1[N+](=O)[O-]]

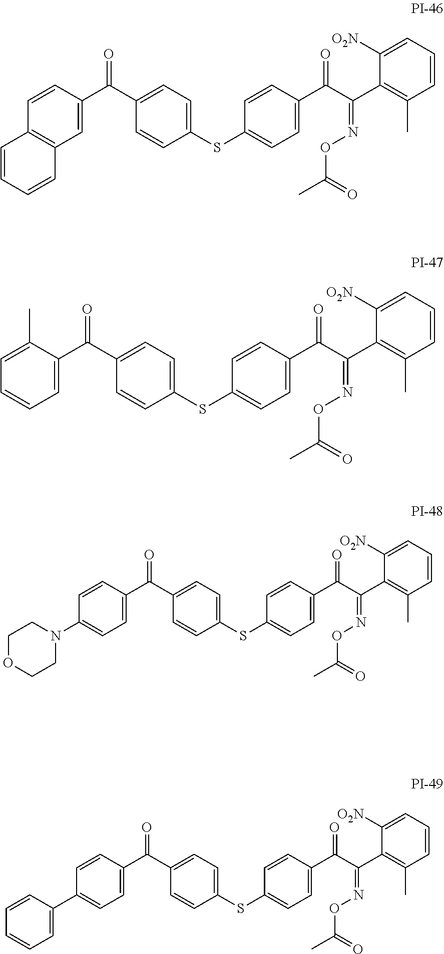 [SMILES: CC(=O)O/N=C(\C(=O)c1ccc(Sc2ccc(C(=O)c3ccc4ccccc4c3)cc2)cc1)c1c(C)cccc1[N+](=O)[O-] ; CC(=O)O/N=C(\C(=O)c1ccc(Sc2ccc(C(=O)c3ccccc3C)cc2)cc1)c1c(C)cccc1[N+](=O)[O-] ; CC(=O)O/N=C(\C(=O)c1ccc(Sc2ccc(C(=O)c3ccc(N4CCOCC4)cc3)cc2)cc1)c1c(C)cccc1[N+](=O)[O-] ; CC(=O)O/N=C(\C(=O)c1ccc(Sc2ccc(C(=O)c3ccc(-c4ccccc4)cc3)cc2)cc1)c1c(C)cccc1[N+](=O)[O-]]

In addition, in view of sensitivity of the photosensitive composition and transparency of the cured product, for the oxime ester compound, an oxime ester compound represented by the following formula (1) is particularly preferable as the oxime ester compound (B2).

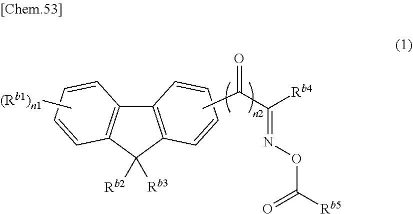

In the formula (1), R^{b1} is a hydrogen atom, a nitro group, or a monovalent organic group, R^{b2} and R^{b3} each represent an optionally substituted chain alkyl group, an optionally substituted cyclic organic group, or a hydrogen atom, R^{b2} and R^{b3} may be bonded to one another to form a ring, R^{b4} is a monovalent organic group, R^{b}s is a hydrogen atom, an optionally substituted alkyl group having 1 or more and 11 or less carbon atoms, or an optionally substituted aryl group, n1 is an integer of 0 or more and 4 or less, and n2 is 0 or 1.

In the formula (1), R^{b1} is the hydrogen atom, the nitro group, or the monovalent organic group. R^{b1} bonds to a 6-membered aromatic ring other than a 6-membered aromatic ring that bonds to a group represented by —(CO)ₙ₂— on the fluorene ring in the formula (1). In the formula (1), a position on the fluorene ring to which R^{b1} bonds is not particularly limited. When the compound represented by the formula (1) has 1 or more R^{b1}, one of 1 or more R^{b1} preferably bonds to 2-position in the fluorene ring in view of ease of synthesis of the compound represented by the formula (1). When a plurality of R^{b1} exist, the plurality of R^{b1} may be the same or different.

When R^{b1} is the organic group, R^{b1} is not particularly limited as long as the object of the present invention is not inhibited, and is appropriately selected from various organic groups. When R^{b1} is the organic group, suitable examples include an alkyl group, an alkoxy group, a cycloalkyl group, a cycloalkoxy group, a saturated aliphatic acyl group, a saturated aliphatic acyloxy group, an alkoxycarbonyl group, an optionally substituted phenyl group, an optionally substituted phenoxy group, an optionally substituted benzoyl group, an optionally substituted phenoxycarbonyl group, an optionally substituted benzoyloxy group, an optionally substituted phenylalkyl group, an optionally substituted naphthyl group, an optionally substituted naphthoxy group, an optionally substituted naphthoyl group, an optionally substituted naphthoxycarbonyl group, an optionally substituted naphthoyloxy group, an optionally substituted naphthylalkyl group, an optionally substituted heterocyclyl group, an optionally substituted heterocyclylcarbonyl group, an amino group substituted with one or two organic groups, a morpholin-1-yl group, a piperazin-1-yl group, and the like.

When R^{b1} is the alkyl group, the number of carbon atoms of the alkyl group is preferably 1 or more and 20 or less, and more preferably 1 or more and 6 or less. In addition, when R^{b1} is the alkyl group, the alkyl group may be linear or branched. When R^{b1} is the alkyl group, specific examples include a methyl group, an ethyl group, an n-propyl group, an isopropyl group, an n-butyl group, an isobutyl group, a sec-butyl group, a tert-butyl group, an n-pentyl group, an isopentyl group, a sec-pentyl group, a tert-pentyl group, an n-hexyl group, an n-heptyl group, an n-octyl group, an isooctyl group, a sec-octyl group, a tert-octyl group, an n-nonyl group, an isononyl group, an n-decyl group, an isodecyl group, and the like. In addition, when R^{b1} is the alkyl group, the alkyl group may include ether bond(s) in the carbon chain. Examples of the alkyl group including ether bond(s) in the carbon chain include a methoxyethyl group, an ethoxyethyl group, a methoxyethoxyethyl group, an ethoxyethoxyethyl group, a propyloxyethoxyethyl group, a methoxypropyl group, and the like.

When R^{b1} is the alkoxy group, the number of carbon atoms of the alkoxy group is preferably 1 or more and 20 or less, and more preferably 1 or more and 6 or less. In addition, when R^{b1} is the alkoxy group, the alkoxy group may be linear or branched. When R^{b1} is an alkoxy group, specific examples include a methoxy group, an ethoxy group, an n-propyloxy group, an isopropyloxy group, an n-butyloxy group, an isobutyloxy group, a sec-butyloxy group, a tert-butyloxy group, an n-pentyloxy group, an isopentyloxy group, a sec-pentyloxy group, a tert-pentyloxy group, an n-hexyloxy group, an n-heptyloxy group, an n-octyloxy group, an isooctyloxy group, a sec-octyloxy group, a tert-octyloxy group, an n-nonyloxy group, an isononyloxy group, an n-decyloxy group, an isodecyloxy group, and the like. When R^{b1} is an alkoxy group, the alkoxy group may include an ether bond (—O—) in the carbon chain. Examples of the alkoxy group having an ether bond in the carbon chain include a methoxyethoxy group, an ethoxyethoxy group, a methoxyethoxyethoxy group, an ethoxyethoxyethoxy group, a propyloxyethoxyethoxy group, a methoxypropyloxy group, and the like.

When R^{b1} is a cycloalkyl group or a cycloalkoxy group, the number of carbon atoms of the cycloalkyl group or cycloalkoxy group is preferably 3 or more and 10 or less, and more preferably 3 or more and 6 or less. When R^{b1} is a cycloalkyl group, specific examples include a cyclopropyl group, a cyclobutyl group, a cyclopentyl group, a cyclohexyl group, a cycloheptyl group, a cyclooctyl group, and the like. When R^{b1} is the cycloalkoxy group, specific examples include a cyclopropyloxy group, a cyclobutyloxy group, a cyclopentyloxy group, a cyclohexyloxy group, a cycloheptyloxy group, a cyclooctyloxy group, and the like.

When R^{b1} is the saturated aliphatic acyl group or the saturated aliphatic acyloxy group, the number of carbon atoms of the saturated aliphatic acyl group or the saturated aliphatic acyloxy group is preferably 2 or more and 21 or less, and more preferably 2 or more and 7 or less. When R^{b1} is the saturated aliphatic acyl group, specific examples include an acetyl group, a propanoyl group, an n-butanoyl group, a 2-methylpropanoyl group, an n-pentanoyl group, a 2,2-dimethylpropanoyl group, an n-hexanoyl group, an n-heptanoyl group, an n-octanoyl group, an n-nonanoyl group, an n-decanoyl group, an n-undecanoyl group, an n-dodecanoyl group, an n-tridecanoyl group, an n-tetradecanoyl group, an n-pentadecanoyl group, an n-hexadecanoyl group, and the like. When R^{b1} is the saturated aliphatic acyloxy group, specific examples include an acetyloxy group, a propanoyloxy group, an n-butanoyloxy group, a 2-methylpropanoyloxy group, an n-pentanoyloxy group, a 2,2-dimethylpropanoyloxy group, an n-hexanoyloxy group, an n-heptanoyloxy group, an n-octanoyloxy group, an n-nonanoyloxy group, an n-decanoyloxy group, an n-undecanoyloxy group, an n-dodecanoyloxy group, an n-tridecanoyloxy group, an n-tetradecanoyloxy group, an n-pentadecanoyloxy group, an n-hexadecanoyloxy group, and the like.

When R^{b1} is the alkoxycarbonyl group, the number of carbon atoms of the alkoxycarbonyl group is preferably 2 or more and 20 or less, and more preferably 2 or more and 7 or less. When R^{b1} is an alkoxycarbonyl group, specific examples include a methoxycarbonyl group, an ethoxycarbonyl group, an n-propyloxycarbonyl group, an isopropyloxycarbonyl group, an n-butyloxycarbonyl group, an isobutyloxycarbonyl group, a sec-butyloxycarbonyl group, a tert-butyloxycarbonyl group, an n-pentyloxycarbonyl group, an isopentyloxycarbonyl group, a sec-pentyloxycarbonyl group, a tert-pentyloxycarbonyl group, an n-hexyloxycarbonyl group, an n-heptyloxycarbonyl group, an n-octyloxycarbonyl group, an isooctyloxycarbonyl group, a sec-octyloxycarbonyl group, a tert-octyloxycarbonyl group, an n-nonyloxycarbonyl group, an isononyloxycarbonyl group, an n-decyloxycarbonyl group, an isodecyloxycarbonyl group, and the like.

When R^{b1} is the phenylalkyl group, the number of carbon atoms of the phenylalkyl group is preferably 7 or more and 20 or less, and more preferably 7 or more and 10 or less. When R^{b1} is the naphthylalkyl group, the number of carbon atoms of the naphthylalkyl group is preferably 11 or more and 20 or less, and more preferably 11 or more and 14 or less. When R^{b1} is the phenyl alkyl group, specific examples include a benzyl group, a 2-phenylethyl group, 3-phenylpropyl group and 4-phenylbutyl group. When R^{b1} in the naphthylalkyl group, specific examples include an a-naphthylmethyl group, a β-naphthylmethyl group, a 2-(α-naphthyl)ethyl group, and a 2-(β-naphthyl)ethyl group. When R^{b1} in the phenylalkyl group or the naphthylalkyl group, R^{b1} may further have substituent(s) on the phenyl group or the naphthyl group.

When R^{b1} is a heterocyclyl group, the heterocyclyl group is a 5-membered or 6-membered monocycle containing one or more N, S, and O, or a heterocyclyl group in which these monocycles are fused, or the monocycle and a benzene ring are fused. When the heterocyclyl group is a fused ring, the number of rings constituting the fused ring is 3 or less. The heterocyclyl group may be either an aromatic group (heteroaryl group) or a non-aromatic group. Examples of the heterocycle constituting the heterocyclic group include furan, thiophene, pyrrole, oxazole, isoxazole, thiazole, thiadiazole, isothiazole, imidazole, pyrazole, triazole, pyridine, pyrazine, pyrimidine, pyridazine, benzofuran, benzothiophene, indole, isoindole, indolizine, benzimidazole, benzotriazole, benzoxazole, benzothiazole, carbazole, purine, quinoline, isoquinoline, quinazoline, phthalazine, cinnoline, quinoxaline, piperidine, piperazine, morpholine, piperidine, tetrahydropyran, tetrahydrofuran, and the like. When R^{b1} is a heterocyclyl group, the heterocyclyl group may have a substituent.

When R^{b1} is the heterocyclylcarbonyl group, the heterocyclyl group included in the heterocyclylcarbonyl group is the same as that in the case where R^{b1} is the heterocyclyl group.

When R^{b1} is an amino group substituted with one or two organic groups, suitable examples of the organic group include an alkyl group having 1 or more and 20 or less carbon atoms, a cycloalkyl group having 3 or more and 10 or less carbon atoms, a saturated aliphatic acyl group having 2 or more and 21 or less carbon atoms, a phenyl group which may have a substituent, a benzoyl group which may have a substituent, a phenylalkyl group having 7 or more and 20 or less carbon atoms which may have a substituent, a naphthyl group which may have a substituent, a naphthoyl group which may have a substituent, a naphthylalkyl group having 11 or more and 20 or less carbon atoms which may have a substituent, a heterocyclyl group, and the like. Specific examples of suitable organic group are the same as those in R^{b1}. Specific examples of the amino group substituted with one 1 or 2 organic groups include a methylamino group, an ethylamino group, a diethylamino group, an n-propylamino group, a di-n-propylamino group, an isopropylamino group, an n-butylamino group, a di-n-butylamino group, an n-pentylamino group, an n-hexylamino group, an n-heptylamino group, an n-octylamino group, an n-nonylamino group, an n-decylamino group, a phenylamino group, a naphthylamino group, an acetylamino group, a propanoylamino group, an n-butanoylamino group, an n-pentanoyl amino group, an n-hexanoylamino group, an n-heptanoylamino group, an n-octanoylamino group, an n-decanoylamino group, a benzoylamino group, an α-naphthoyl group, a β-naphthoyl group, and the like.

When an phenyl group, an naphthyl group, and a heterocyclyl group included in R^{b1} further have a substituent, examples of the substituent include an alkyl group having 1 or more and 6 or less carbon atoms, an alkoxy group having 1 or more and 6 or less carbon atoms, a saturated aliphatic acyl group having 2 or more and 7 or less carbon atoms, an alkoxycarbonyl group having 2 or more and 7 or less carbon atoms, a saturated aliphatic acyloxy group having 2 or more and 7 or less carbon atoms, a monoalkylamino group which has an alkyl group having 1 or more and 6 or less carbon atoms, a dialkylamino group which has two alkyl groups having 1 or more and 6 or less carbon atoms, a morpholin-1-yl group, an piperazin-1-yl group, halogen, a nitro group, a cyano group, and the like. When a phenyl group, a naphthyl group, and a heterocyclyl group included in R^{b1} further have a substituent, the number of substituents is not particularly limited as long as the object of the present invention is not inhibited, and is preferably 1 or more and 4 or less. When a phenyl group, a naphthyl group, and a heterocyclyl group included in R^{b1} have plural substituents, plural substituents may be the same as or different each other.

Among the above-described groups, R^{b1} is preferably a nitro group or a group represented as R^{b10}—CO— since the sensitivity tends to be enhanced. R^{b10} is not particularly limited as long as it does not interfere with the object of the present invention, and can be selected from various organic groups. Examples of the group suitable as R^{b10} include an alkyl group having 1 or more and 20 or less carbon atoms, an optionally substituted phenyl group, an optionally substituted naphthyl group, and an optionally substituted heterocyclyl group. Among these groups, R^{b10} is particularly preferably a 2-methylphenyl group, a thiophen-2-yl group, and an α-naphthyl group. Moreover, it is preferred that R^{b1} is a hydrogen atom since the transparency tends to be satisfactory. Note here that when R^{b1} is a hydrogen atom and R^{b4} is a group represented by the formula (1a) or (1b) mentioned later, the transparency tends to be even more satisfactory.

In the formula (1), R^{b2} and R^{b3} each represent an optionally substituted chain alkyl group, an optionally substituted cyclic organic group, or a hydrogen atom. R^{b2} and R^{b3} may be bonded to one another to form a ring. Among these groups, preferably, R^{b2} and R^{b3} are optionally substituted chain alkyl groups. When R^{b2} and R^{b3} are optionally substituted chain alkyl groups, a chain alkyl group may be either a linear alkyl group or a branched alkyl group.

When R^{b2} and R^{b3} are chain alkyl groups having no substituent, the number of carbon atoms of the chain alkyl group is preferably 1 or more and 20 or less, more preferably 1 or more and 10 or less, and particularly preferably 1 or more and 6 or less. When R^{b2} and R^{b3} are chain alkyl groups, specific examples include a methyl group, an ethyl group, an n-propyl group, an isopropyl group, an n-butyl group, an isobutyl group, a sec-butyl group, a tert-butyl group, an n-pentyl group, an isopentyl group, a sec-pentyl group, a tert-pentyl group, an n-hexyl group, an n-heptyl group, an n-octyl group, an isooctyl group, a sec-octyl group, a tert-octyl group, an n-nonyl group, an isononyl group, an n-decyl group, an isodecyl group, and the like. When R^{b2} and R^{b3} are alkyl groups, the alkyl group may have an ether bond (—O—) in a carbon chain. Examples of the alkyl group having an ether bond in a carbon chain include a methoxyethyl group, an ethoxyethyl group, a methoxyethoxyethyl group, an ethoxyethoxyethyl group, a propyloxyethoxyethyl group, and a methoxypropyl group.

When R^{b2} and R^{b3} are chain alkyl groups having a substituent, the number of carbon atoms of the chain alkyl group is preferably 1 or more and 20 or less, more preferably 1 or more and 10 or less, and particularly preferably 1 or more and 6 or less. In this case, the number of carbon atoms of the substituent is not included in the number of carbon atoms of the chain alkyl group. The chain alkyl group having a substituent is preferably a linear group. The substituent, with which the alkyl group is optionally substituted, is not particularly limited as long as the object of the present invention is not inhibited. Suitable examples of the substituent include a cyano group, a halogen atom, a cyclic organic group, and an alkoxycarbonyl group. A fluorine atom, a chlorine atom, a bromine atom, and an iodine atom are exemplified as the halogen atom. Among these, the fluorine atom, the chlorine atom, and the bromine atom are preferred. A cycloalkyl group, an aromatic hydrocarbon group, and a heterocyclyl group are exemplified as the cyclic organic group. Specific examples of the cycloalkyl group are the same as the suitable examples of the cycloalkyl group as R^{b1}. The specific examples of the heterocyclyl group are the same as the suitable examples of the heterocyclyl group as R^{b1}. When R^{b1} is the alkoxycarbonyl group, an alkoxy group included in the alkoxycarbonyl group may be linear or branched, and is preferably linear. The number of carbon atoms of the alkoxy group included in the alkoxycarbonyl group is preferably 1 or more and 10 or less, and more preferably 1 or more and 6 or less.

When the chain alkyl group has one or more substituents, the number of substituents is not particularly limited. The preferred number of substituents depends on the number of carbon atoms in the chain alkyl group. The number of substituents is typically 1 or more and 20 or less, preferably 1 or more and 10 or less, and more preferably 1 or more and 6 or less.

When R^{b2} and R^{b3} are cyclic organic groups, the cyclic organic group may be either an alicyclic group or an aromatic group. Examples of the cyclic organic group include an aliphatic cyclic hydrocarbon group, an aromatic hydrocarbon group, and a heterocyclyl group. When R^{b2} and R^{b3} are cyclic organic groups, the substituent, which the cyclic organic group may have, is the same as in a case where R^{b2} and R^{b3} are chain alkyl groups.

When R^{b2} and R^{b3} are aromatic hydrocarbon groups, the aromatic hydrocarbon group is preferably a phenyl group, or a group formed by bonding plural benzene rings through a carbon-carbon bond, or a group formed by fusion of plural benzene rings. When the aromatic hydrocarbon group is a phenyl group, or a group formed by bonding or fusing plural benzene rings, the number of rings of a benzene ring included in the aromatic hydrocarbon group is not particularly limited, and is preferably 3 or less, more preferably 2 or less, and particularly preferably 1. Preferred specific examples of the aromatic hydrocarbon group include a phenyl group, a naphthyl group, a biphenylyl group, an anthryl group, a phenanthryl group, and the like.

When R^{b2} and R^{b3} are aliphatic cyclic hydrocarbon groups, the aliphatic cyclic hydrocarbon group may be either a monocyclic or polycyclic group. The number of carbon atoms of the aliphatic cyclic hydrocarbon group is not particularly limited, and is preferably 3 or more 20 or less, and more preferably 3 or more and 10 or less. Examples of the monocyclic cyclic hydrocarbon group include cyclopropyl group, a cyclobutyl group, a cyclopentyl group, a cyclohexyl group, a cycloheptyl group, a cyclooctyl group, a norbornyl group, an isobornyl group, a tricyclononyl group, a tricyclodecyl group, a tetracyclododecyl group, an adamantyl group, and the like.

When R^{b2} and R^{b3} are heterocyclyl groups, the heterocyclyl group is a 5-membered or 6-membered monocycle containing one or more N, S, and O, or a heterocyclyl group in which these monocycles are fused, or the monocycle and a benzene ring are fused. When the heterocyclyl group is a fused ring, the number of rings constituting the fused ring is 3 or less. The heterocyclyl group may be either an aromatic group (heteroaryl group) or a non-aromatic group. Examples of the heterocycle constituting the heterocyclic group include furan, thiophene, pyrrole, oxazole, isoxazole, thiazole, thiadiazole, isothiazole, imidazole, pyrazole, triazole, pyridine, pyrazine, pyrimidine, pyridazine, benzofuran, benzothiophene, indole, isoindole, indolizine, benzimidazole, benzotriazole, benzoxazole, benzothiazole, carbazole, purine, quinoline, isoquinoline, quinazoline, phthalazine, cinnoline, quinoxaline, piperidine, piperazine, morpholine, piperidine, tetrahydropyran, tetrahydrofuran, and the like.

R^{b2} and R^{b3} may be bonded to one another to form a ring. The group composed of the ring formed by R^{b2} and R^{b3} is preferably a cycloalkylidene group. When R^{b2} and R^{b3} are bonded to form a cycloalkylidene group, the ring constituting the cycloalkylidene group is preferably a 5-membered ring or a 6-membered ring, and more preferably a 5-membered ring.

When the group formed by bonding R^{b2} and R^{b3} is a cycloalkylidene group, the cycloalkylidene group may be fused with one or more other rings. Examples of the ring which may be fused with the cycloalkylidene group include a benzene ring, a naphthalene ring, a cyclobutane ring, a cyclopentane ring, a cyclohexane ring, a cycloheptane ring, a cyclooctane ring, a furan ring, a thiophene ring, a pyrrole ring, a pyridine ring, a pyrazine ring, a pyrimidine ring, and the like.

Examples of suitable group among R^{b2} and R^{b3} descried above include a group represented by the formula: -A¹-A². In the formula, A¹ is a linear chain alkylene group, and A² is an alkoxy group, a cyano group, a halogen atom, a halogenated alkyl group, a cyclic organic group, or an alkoxycarbonyl group.

The number of carbon atoms of the linear alkylene group for A¹ is preferably 1 or more and 10 or less, and more preferably 1 or more and 6 or less. When A² is an alkoxy group, the alkoxy group may be a linear or branched alkoxy group, and preferably a linear alkoxy group. The number of carbon atoms of the alkoxy group is preferably 1 or more and 10 or less, and more preferably 1 or more and 6 or less. When A² is a halogen atom, a fluorine atom, a chlorine atom, a bromine atom, or an iodine atom is preferable, and a fluorine atom, a chlorine atom, or a bromine atom is more preferable. When A² is a halogenated alkyl group, a halogen atom included in the halogenated alkyl group is preferably a fluorine atom, a chlorine atom, a bromine atom, or an iodine atom, and more preferably is a fluorine atom, a chlorine atom, or a bromine atom. The halogenated alkyl group may be a linear or branched halogenated alkyl group, preferably a linear halogenated alkyl group. When A² is a cyclic organic group, examples of the cyclic organic group are the same as the cyclic organic group possessed by R^{b2} and R^{b3} as a substituent. When A² is an alkoxycarbonyl group, examples of the alkoxycarbonyl group are the same as the alkoxycarbonyl group possessed by R^{b2} and R^{b3} as a substituent.

Suitable specific examples of R^{b2} and R^{b3} include alkyl groups such as an ethyl group, an n-propyl group, an n-butyl group, an n-hexyl group, an n-heptyl group, and an n-octyl group; alkoxyalkyl groups such as a 2-methoxyethyl group, a 3-methoxy-n-propyl group, a 4-methoxy-n-butyl group, a 5-methoxy-n-pentyl group, a 6-methoxy-n-hexyl group, a 7-methoxy-n-heptyl group, a 8-methoxy-n-octyl group, a 2-ethoxyethyl group, a 3-ethoxy-n-propyl group, a 4-ethoxy-n-butyl group, a 5-ethoxy-n-pentyl group, a 6-ethoxy-n-hexyl group, a 7-ethoxy-n-heptyl group, and a 8-ethoxy-n-octyl group; cyanoalkyl groups such as a 2-cyanoethyl group, a 3-cyano-n-propyl group, a 4-cyano-n-butyl group, a 5-cyano-n-pentyl group, a 6-cyano-n-hexyl group, a 7-cyano-n-heptyl group, and a 8-cyano-n-octyl group; phenylalkyl groups such as a 2-phenylethyl group, a 3-phenyl-n-propyl group, a 4-phenyl-n-butyl group, a 5-phenyl-n-pentyl group, a 6-phenyl-n-hexyl group, a 7-phenyl-n-heptyl group, and a 8-phenyl-n-octyl group; cycloalkylalkyl groups such as a 2-cyclohexylethyl group, a 3-cyclohexyl-n-propyl group, a 4-cyclohexyl-n-butyl group, a 5-cyclohexyl-n-pentyl group, a 6-cyclohexyl-n-hexyl group, a 7-cyclohexyl-n-heptyl group, a 8-cyclohexyl-n-octyl group, a 2-cyclopentylethyl group, a 3-cyclopentyl-n-propyl group, a 4-cyclopentyl-n-butyl group, a 5-cyclopentyl-n-pentyl group, a 6-cyclopentyl-n-hexyl group, a 7-cyclopentyl-n-heptyl group, and a 8-cyclopentyl-n-octyl group; alkoxycarbonylalkyl groups such as a 2-methoxycarbonylethyl group, a 3-methoxycarbonyl-n-propyl group, a 4-methoxycarbonyl-n-butyl group, a 5-methoxycarbonyl-n-pentyl group, a 6-methoxycarbonyl-n-hexyl group, a 7-methoxycarbonyl-n-heptyl group, a 8-methoxycarbonyl-n-octyl group, a 2-ethoxycarbonylethyl group, a 3-ethoxycarbonyl-n-propyl group, a 4-ethoxycarbonyl-n-butyl group, a 5-ethoxycarbonyl-n-pentyl group, a 6-ethoxycarbonyl-n-hexyl group, a 7-ethoxycarbonyl-n-heptyl group, and a 8-ethoxycarbonyl-n-octyl group; and halogenated alkyl groups such as a 2-chloroethyl group, a 3-chloro-n-propyl group, a 4-chloro-n-butyl group, a 5-chloro-n-pentyl group, a 6-chloro-n-hexyl group, a 7-chloro-n-heptyl group, a 8-chloro-n-octyl group, a 2-bromoethyl group, a 3-bromo-n-propyl group, a 4-bromo-n-butyl group, a 5-bromo-n-pentyl group, a 6-bromo-n-hexyl group, a 7-bromo-n-heptyl group, a 8-bromo-n-octyl group, a 3,3,3-trifluoropropyl group, and a 3,3,4,4,5,5,5-heptafluoro-n-pentyl group.

Among groups mentioned above, groups suitable as R^{b2} and R^{b3} are an ethyl group, an n-propyl group, an n-butyl group, an n-pentyl group, a 2-methoxyethyl group, a 2-cyanoethyl group, a 2-phenylethyl group, a 2-cyclohexylethyl group, a 2-methoxycarbonylethyl group, a 2-chloroethyl group, a 2-bromoethyl group, a 3,3,3-trifluoropropyl group, and a 3,3,4,4,5,5,5-heptafluoro-n-pentyl group.

In the same manner as R^{b1}, examples of a suitable organic group for R^{b4} include an alkyl group, an alkoxy group, a cycloalkyl group, a cycloalkoxy group, a saturated aliphatic acyl group, an alkoxycarbonyl group, a saturated aliphatic acyloxy group, an optionally substituted phenyl group, an optionally substituted phenoxy group, an optionally substituted benzoyl group, an optionally substituted phenoxycarbonyl group, an optionally substituted benzoyloxy group, an optionally substituted phenylalkyl group, an optionally substituted naphthyl group, an optionally substituted naphthoxy group, an optionally substituted naphthoyl group, an optionally substituted naphthoxycarbonyl group, an optionally substituted naphthoyloxy group, an optionally substituted naphthylalkyl group, an optionally substituted heterocyclyl group, an optionally substituted heterocyclylcarbonyl group, an amino group substituted with one or two organic groups, a morpholin-1-yl group, a piperazin-1-yl group, and the like. Specific examples of these groups are the same as the specific examples described for R^{b1}. R^{b4} is also preferably a cycloalkylalkyl group, a phenoxyalkyl group which may have a substituent on the aromatic ring, and a phenylthioalkyl group which may have a substituent on the aromatic ring. The substituent which may be possessed by a phenoxyalkyl group and phenylthioalkyl group is the same as the substituent which may be possessed by a phenyl group included in R^{b1}.

Among the organic groups, R^{b4} is preferably an alkyl group, a cycloalkyl group, an optionally substituted phenyl group or cycloalkylalkyl group, or a phenylthioalkyl group which may have a substituent on the aromatic ring. The alkyl group is preferably an alkyl group having 1 or more and 20 or less carbon atoms, more preferably an alkyl group having 1 or more and 8 or less carbon atoms, particularly preferably an alkyl group having 1 or more and 4 or less carbon atoms, and most preferably a methyl group. Among optionally substituted phenyl groups, a methylphenyl group is preferable, and a 2-methylphenyl group is more preferable. The number of carbon atoms of the cycloalkyl group included in the cycloalkylalkyl group is preferably 5 or more and 10 or less, more preferably 5 or more and 8 or less, and particularly preferably 5 or 6. The number of carbon atoms of the alkylene group included in the cycloalkylalkyl group is preferably 1 or more and 8 or less, more preferably 1 or more and 4 or less, and particularly preferably 2. Among cycloalkylalkyl groups, a cyclopentylethyl group is preferable. The number of carbon atoms of the alkylene group included in the phenylthioalkyl group which may have a substituent on the aromatic ring is preferably 1 or more and 8 or less, more preferably 1 or more and 4 or less, and particularly preferably 2. Among the phenylthioalkyl groups which may have a substituent on the aromatic ring, a 2-(4-chlorophenylthio)ethyl group is preferable.

R^{b4} is also preferably a group represented by -A³-CO—O-A⁴. A³ is a divalent organic group, preferably a divalent hydrocarbon group, and more preferably an alkylene group. A⁴ is a monovalent organic group, and preferably a monovalent hydrocarbon group.

When A³ is an alkylene group, the alkylene group may be a linear or branched alkylene group, preferably a linear alkylene group. When A³ is an alkylene group, the number of carbon atoms of the alkylene group is preferably 1 or more and 10 or less, more preferably 1 or more and 6 or less, and particularly preferably 1 or more and 4 or less.

Suitable examples of A⁴ include an alkyl group having 1 or more and 10 or less carbon atoms, an aralkyl group having 7 or more and 20 or less carbon atoms, and an aromatic hydrocarbon group having 6 or more and 20 or less carbon atoms. Suitable specific examples of A⁴ include a methyl group, an ethyl group, an n-propyl group, an isopropyl group, an n-butyl group, an isobutyl group, a sec-butyl group, a tert-butyl group, an n-pentyl group, an n-hexyl group, a phenyl group, a naphthyl group, a benzyl group, a phenethyl group, an α-naphthylmethyl group, a B-naphthylmethyl group, and the like.

Specific examples of a suitable group represented by -A³-CO—O-A⁴ include a 2-methoxycarbonylethyl group, a 2-ethoxycarbonylethyl group, a 2-n-propyloxycarbonylethyl group, a 2-n-butyloxycarbonylethyl group, a 2-n-pentyloxycarbonylethyl group, a 2-n-hexyloxycarbonylethyl group, a 2-benzyloxycarbonylethyl group, a 2-phenoxycarbonylethyl group, a 3-methoxycarbonyl-n-propyl group, a 3-ethoxycarbonyl-n-propyl group, a 3-n-propyloxycarbonyl-n-propyl group, a 3-n-butyloxycarbonyl-n-propyl group, a 3-n-pentyloxycarbonyl-n-propyl group, a 3-n-hexyloxycarbonyl-n-propyl group, a 3-benzyloxycarbonyl-n-propyl group, a 3-phenoxycarbonyl-n-propyl group, and the like.

While R^{b4} has been described above, R^{b4} is preferably a group represented by the following formula (1a) or (1b).

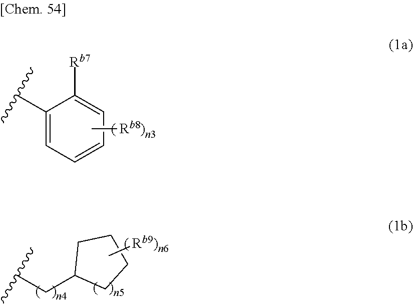

In the formulas (1a) and (1b), R^{b7} and R^{b8} each are an organic group, n3 is an integer of 0 or more and 4 or less; when R^{b7} and R^{b8} exist at adjacent positions on a benzene ring, R^{b7} and R^{b8} may be bonded to one another to form a ring; n4 is an integer of 1 or more and 8 or less; n5 is an integer of 1 or more and 5 or less; n6 is an integer of 0 or more and (n5+3); and R^{b9} is an organic group.

Examples of the organic group for R^{b7} and R^{b8} in the formula (1a) are the same as those in R^{b1}. R^{b7} is preferably an alkyl group or a phenyl group. When R^{b7} is the alkyl group, the number of carbon atoms thereof is preferably 1 or more and 10 or less, more preferably 1 or more and 5 or less, preferably 1 or more and 3 or less, and most preferably 1. Namely, R^{b7} is most preferably a methyl group. When R^{b7} and R^{b8} are bonded to form a ring, the ring may be either one of an aromatic ring or an aliphatic ring. Suitable examples of the group represented by the formula (1a) in which R^{b7} and R^{b8} form a ring include a naphthalen-1-yl group, a 1,2,3,4-tetrahydronaphthalen-5-yl group, and the like. In the above formula (1a), n3 is an integer of 0 or more and 4 or less, preferably 0 or 1, and more preferably 0.

In the above formula (1b), R^{b9} is an organic group. Examples of the organic group include the same group as the organic group described for R^{b1}. Among the organic groups, an alkyl group is preferable. The alkyl group may be any one of linear and branched alkyl groups. The number of carbon atoms of the alkyl group is preferably 1 or more and 10 or less, more preferably, 1 or more and 5 or less, and particularly preferably 1 or more and 3 or less. Preferable examples of R^{b9} include a methyl group, an ethyl group, a propyl group, an isopropyl group, a butyl group, and the like. Among these, the methyl group is more preferable.

In the above formula (1b), n5 is an integer of 1 or more and 5 or less, preferably 1 or more and 3 or less, and more preferably 1 or 2. In the formula (1b), n6 is 0 or more and (n5+3) or less, preferably an integer of 0 or more and 3 or less, more preferably an integer of 0 or more and 2 or less, and particularly preferably 0. In the formula (1b), n4 is an integer of 1 or more and 8 or less, preferably an integer of 1 or more and 5 or less, more preferably an integer of 1 or more and 3 or less, and particularly preferably 1 or 2.

In the formula (1), R^{b5} is a hydrogen atom, an alkyl group having 1 or more and 11 or less carbon atoms which may have a substituent, or an aryl group which may have a substituent. When R^{b5} is an alkyl group, preferable examples of optional substituents include a phenyl group, a naphthyl group, and the like. When R^{b1} is an aryl group, preferable examples of optional substituents include an alkyl group having 1 or more and 5 or less carbon atoms, an alkoxy group, a halogen atom, and the like.

In the formula (1), suitable examples of R^{b5} include a hydrogen atom, a methyl group, an ethyl group, an n-propyl group, an isopropyl group, an n-butyl group, a phenyl group, a benzyl group, and a methyl phenyl group. Among these, the methyl group or the phenyl group is preferable.

Suitable examples of the compound represented by the formula (1) include the following PI-43 to PI-83.

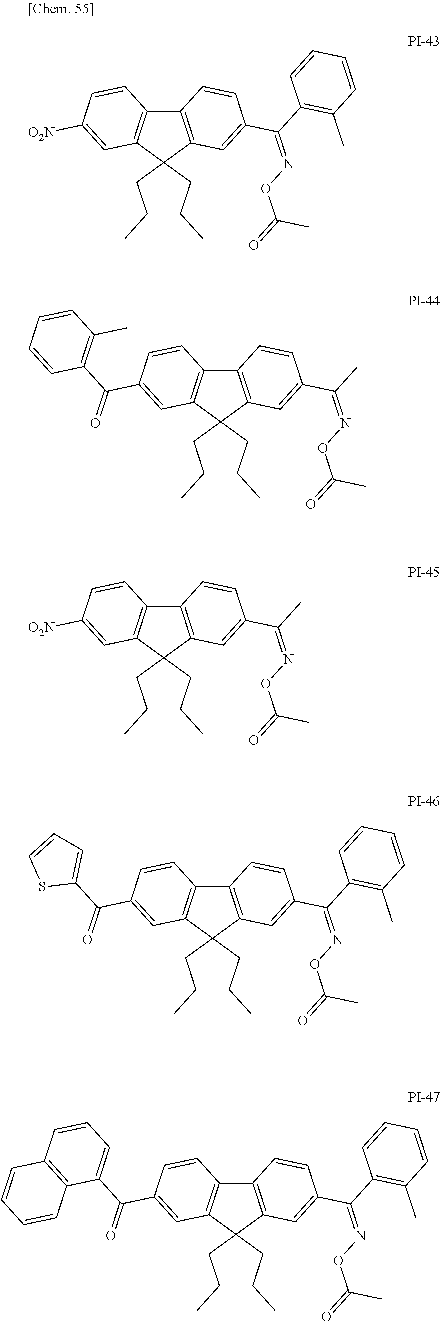 [SMILES: CCCC1(CCC)c2cc(/C(=N\OC(C)=O)c3ccccc3C)ccc2-c2ccc([N+](=O)[O-])cc21 ; CCCC1(CCC)c2cc(C(=O)c3ccccc3C)ccc2-c2ccc(/C(C)=N\OC(C)=O)cc21 ; CCCC1(CCC)c2cc(/C(C)=N\OC(C)=O)ccc2-c2ccc([N+](=O)[O-])cc21 ; CCCC1(CCC)c2cc(C(=O)c3cccs3)ccc2-c2ccc(/C(=N\OC(C)=O)c3ccccc3C)cc21 ; CCCC1(CCC)c2cc(C(=O)c3cccc4ccccc34)ccc2-c2ccc(/C(=N\OC(C)=O)c3ccccc3C)cc21]

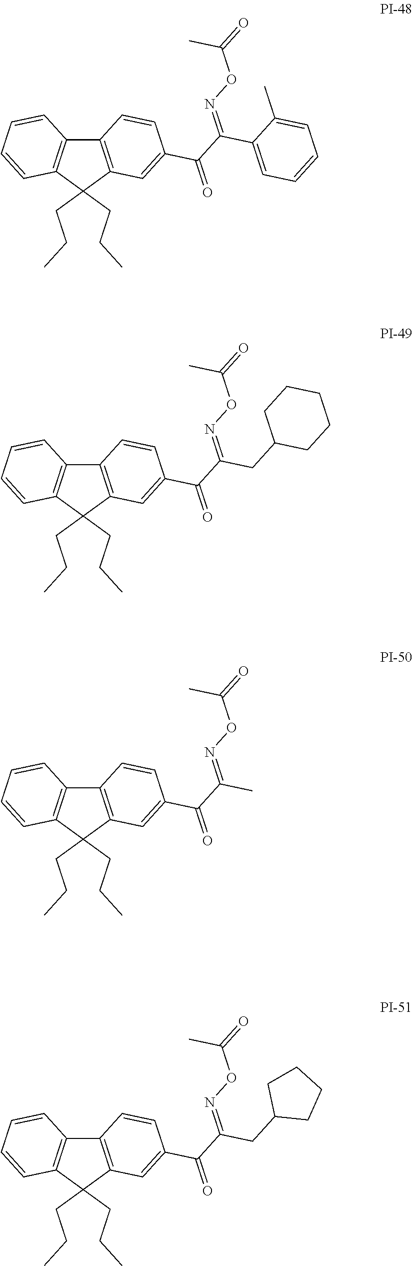 [SMILES: CCCC1(CCC)c2ccccc2-c2ccc(C(=O)/C(=N/OC(C)=O)c3ccccc3C)cc21 ; CCCC1(CCC)c2ccccc2-c2ccc(C(=O)/C(CC3CCCCC3)=N/OC(C)=O)cc21 ; CCCC1(CCC)c2ccccc2-c2ccc(C(=O)/C(C)=N/OC(C)=O)cc21 ; CCCC1(CCC)c2ccccc2-c2ccc(C(=O)/C(CC3CCCC3)=N/OC(C)=O)cc21]

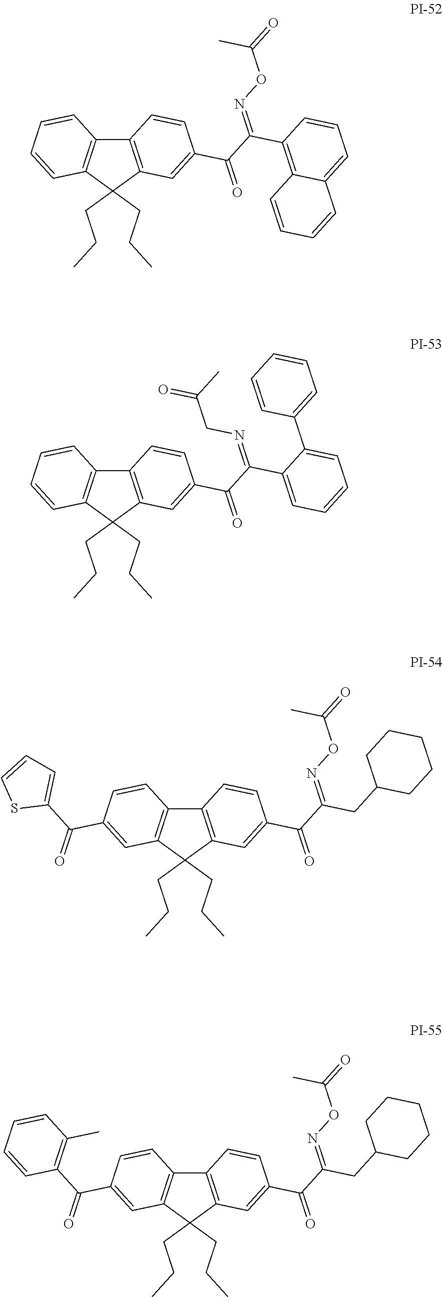 [SMILES: CCCC1(CCC)c2ccccc2-c2ccc(C(=O)/C(=N/OC(C)=O)c3cccc4ccccc34)cc21 ; CCCC1(CCC)c2ccccc2-c2ccc(C(=O)/C(=N\CC(C)=O)c3ccccc3-c3ccccc3)cc21 ; CCCC1(CCC)c2cc(C(=O)/C(CC3CCCCC3)=N/OC(C)=O)ccc2-c2ccc(C(=O)c3cccs3)cc21 ; CCCC1(CCC)c2cc(C(=O)/C(CC3CCCCC3)=N/OC(C)=O)ccc2-c2ccc(C(=O)c3ccccc3C)cc21]

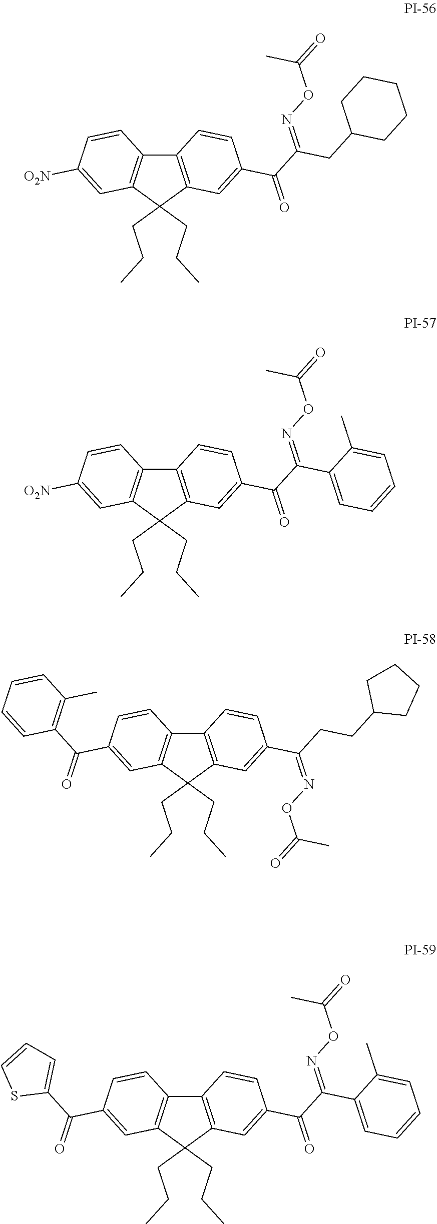 [SMILES: CCCC1(CCC)c2cc(C(=O)/C(CC3CCCCC3)=N/OC(C)=O)ccc2-c2ccc([N+](=O)[O-])cc21 ; CCCC1(CCC)c2cc(C(=O)/C(=N/OC(C)=O)c3ccccc3C)ccc2-c2ccc([N+](=O)[O-])cc21 ; CCCC1(CCC)c2cc(C(=O)c3ccccc3C)ccc2-c2ccc(/C(CCC3CCCC3)=N\OC(C)=O)cc21 ; CCCC1(CCC)c2cc(C(=O)/C(=N/OC(C)=O)c3ccccc3C)ccc2-c2ccc(C(=O)c3cccs3)cc21]

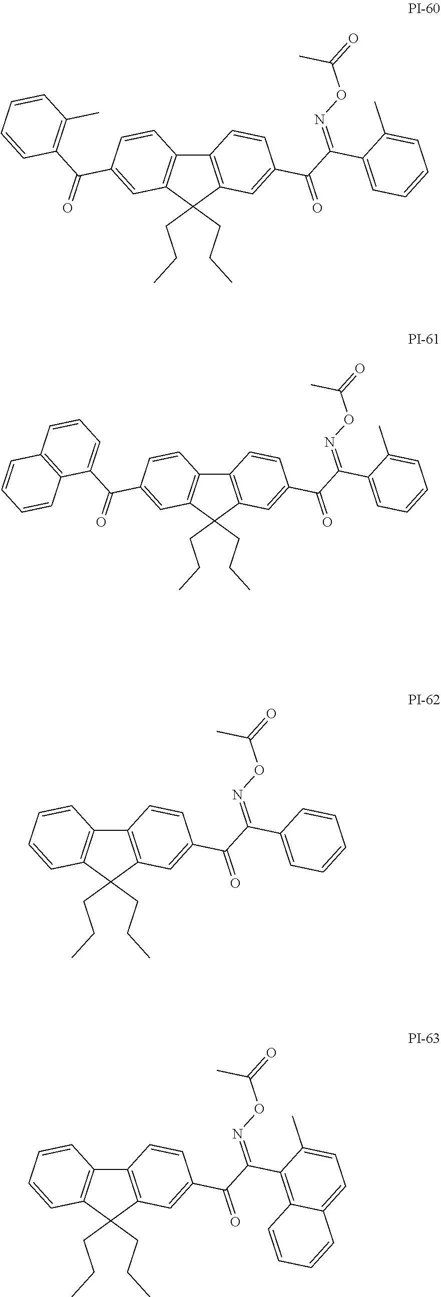 [SMILES: CCCC1(CCC)c2cc(C(=O)/C(=N/OC(C)=O)c3ccccc3C)ccc2-c2ccc(C(=O)c3ccccc3C)cc21 ; CCCC1(CCC)c2cc(C(=O)/C(=N/OC(C)=O)c3ccccc3C)ccc2-c2ccc(C(=O)c3cccc4ccccc34)cc21 ; CCCC1(CCC)c2ccccc2-c2ccc(C(=O)/C(=N/OC(C)=O)c3ccccc3)cc21 ; CCCC1(CCC)c2ccccc2-c2ccc(C(=O)/C(=N/OC(C)=O)c3c(C)ccc4ccccc34)cc21]

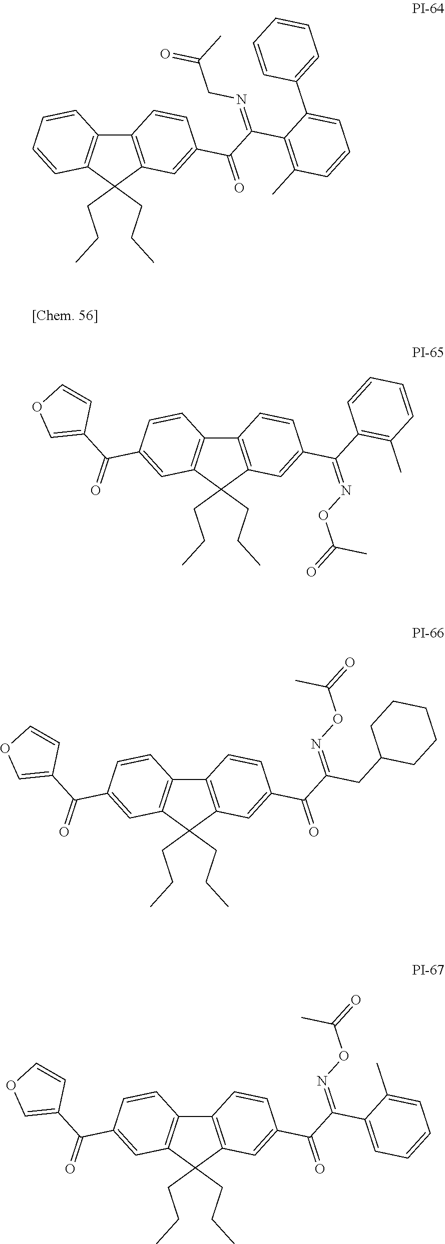 [SMILES: CCCC1(CCC)c2ccccc2-c2ccc(C(=O)/C(=N\CC(C)=O)c3c(C)cccc3-c3ccccc3)cc21 ; CCCC1(CCC)c2cc(C(=O)c3ccoc3)ccc2-c2ccc(/C(=N\OC(C)=O)c3ccccc3C)cc21 ; CCCC1(CCC)c2cc(C(=O)/C(CC3CCCCC3)=N/OC(C)=O)ccc2-c2ccc(C(=O)c3ccoc3)cc21 ; CCCC1(CCC)c2cc(C(=O)/C(=N/OC(C)=O)c3ccccc3C)ccc2-c2ccc(C(=O)c3ccoc3)cc21]

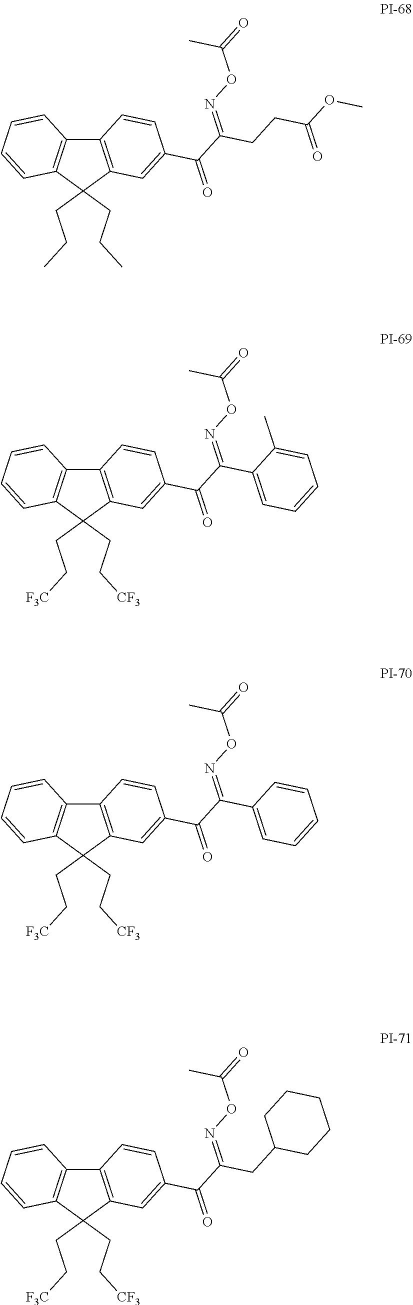 [SMILES: CCCC1(CCC)c2ccccc2-c2ccc(C(=O)/C(CCC(=O)OC)=N/OC(C)=O)cc21 ; CC(=O)O/N=C(/C(=O)c1ccc2c(c1)C(CCC(F)(F)F)(CCC(F)(F)F)c1ccccc1-2)c1ccccc1C ; CC(=O)O/N=C(/C(=O)c1ccc2c(c1)C(CCC(F)(F)F)(CCC(F)(F)F)c1ccccc1-2)c1ccccc1 ; CC(=O)O/N=C(\CC1CCCCC1)C(=O)c1ccc2c(c1)C(CCC(F)(F)F)(CCC(F)(F)F)c1ccccc1-2]

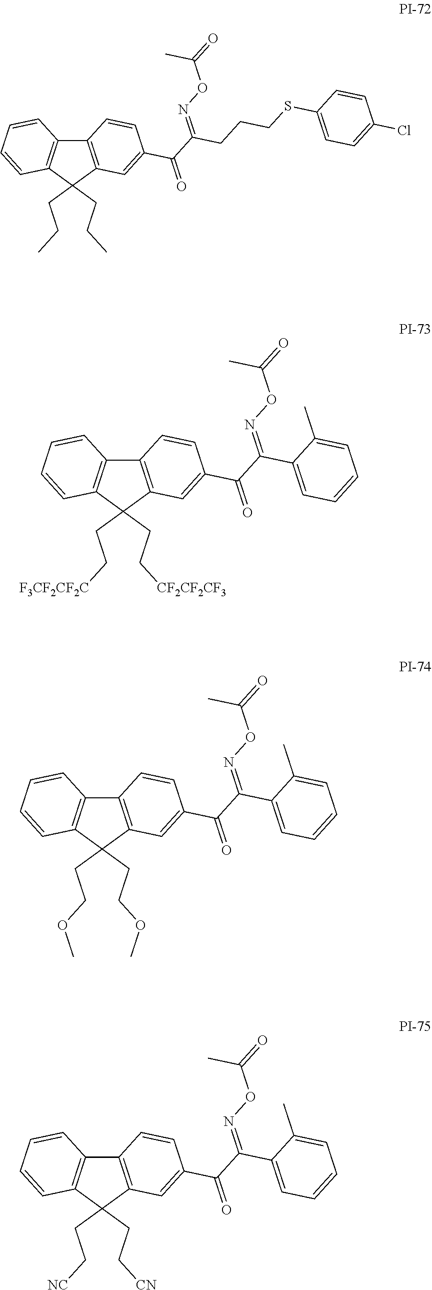

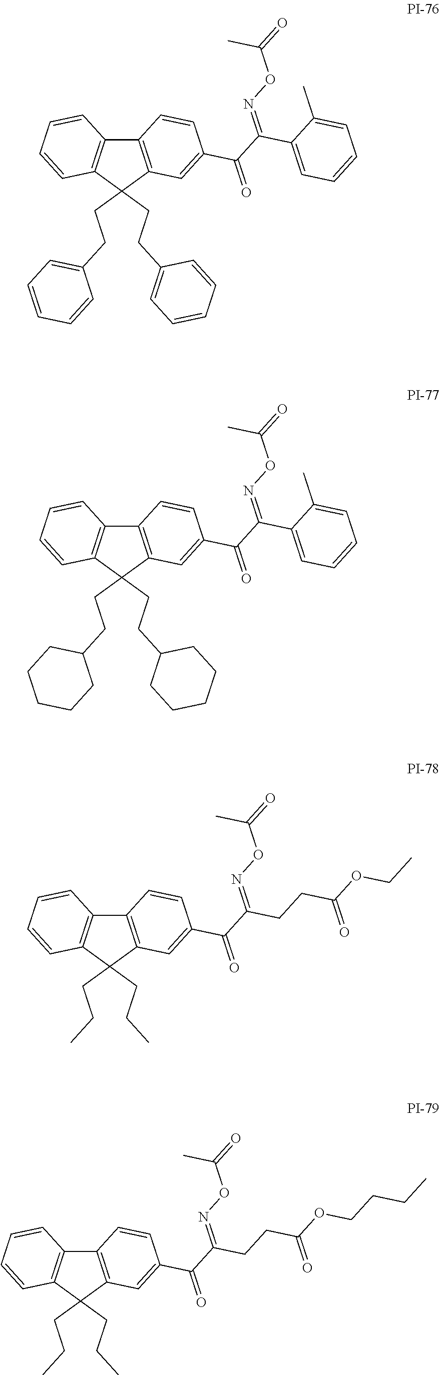 [SMILES: CC(=O)O/N=C(/C(=O)c1ccc2c(c1)C(CCc1ccccc1)(CCc1ccccc1)c1ccccc1-2)c1ccccc1C ; CC(=O)O/N=C(/C(=O)c1ccc2c(c1)C(CCC1CCCCC1)(CCC1CCCCC1)c1ccccc1-2)c1ccccc1C ; CCCC1(CCC)c2ccccc2-c2ccc(C(=O)/C(CCC(=O)OCC)=N/OC(C)=O)cc21 ; CCCCOC(=O)CC/C(=N\OC(C)=O)C(=O)c1ccc2c(c1)C(CCC)(CCC)c1ccccc1-2]

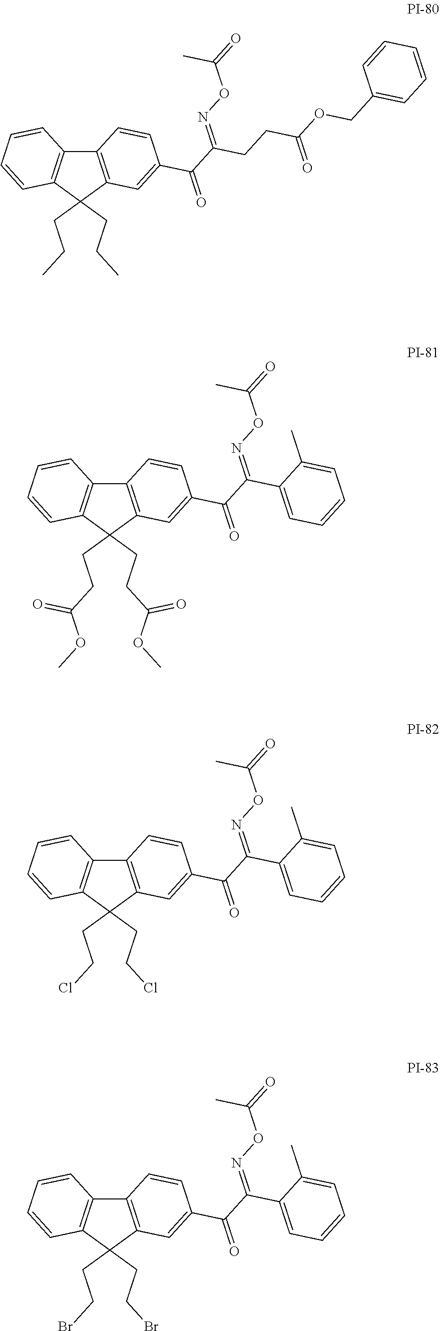 [SMILES: CCCC1(CCC)c2ccccc2-c2ccc(C(=O)/C(CCC(=O)OCc3ccccc3)=N/OC(C)=O)cc21 ; COC(=O)CCC1(CCC(=O)OC)c2ccccc2-c2ccc(C(=O)/C(=N/OC(C)=O)c3ccccc3C)cc21 ; CC(=O)O/N=C(/C(=O)c1ccc2c(c1)C(CCCl)(CCCl)c1ccccc1-2)c1ccccc1C ; CC(=O)O/N=C(/C(=O)c1ccc2c(c1)C(CCBr)(CCBr)c1ccccc1-2)c1ccccc1C]

### [Other Photopolymerization Initiator (B3)]

As other photopolymerization initiator (B3), 1-hydroxycyclohexyl phenyl ketone, 2-hydroxy-2-methyl-1-phenylpropan-1-one, 1-[4-(2-hydroxyethoxy) phenyl]-2-hydroxy-2-methyl-1-propan-1-one, 1-(4-isopropylphenyl)-2-hydroxy-2-methylpropan-1-one, 1-(4-dodecylphenyl)-2-hydroxy-2-methylpropan-1-one, 2,2-dimethoxy-1,2-diphenylethan-1-one, bis(4-dimethylaminophenyl) ketone, 2-methyl-1-[4-(methylthio)phenyl]-2-morpholinopropan-1-one, 2-benzyl-2-dimethylamino-1-(4-morpholinophenyl)-butan-1-one, 4-benzoyl-4′-methyldimethyl sulfide, 4-dimethylaminobenzoic acid, methyl 4-dimethylaminobenzoate, ethyl 4-dimethylaminobenzoate, butyl 4-dimethylaminobenzoate, 4-dimethylamino-2-ethylhexylbenzoic acid, 4-dimethylamino-2-isoamylbenzoic acid, benzyl-β-methoxyethyl acetal, benzyl dimethyl ketal, 1-phenyl-1,2-propanedion-2-(O-ethoxycarbonyl) oxime, methyl o-benzoylbenzoate, 2,4-diethylthioxanthone, 2-chlorothioxanthone, 2,4-dimethylthioxanthone, 1-chloro-4-propoxythioxanthone, thioxanthene, 2-chlorothioxanthene, 2,4-diethylthioxanthene, 2-methylthioxanthene, 2-isopropylthioxanthene, 2-ethylanthraquinone, octamethylanthraquinone, 1,2-benzanthraquinone, 2,3-diphenylanthraquinone, azobisisobutyronitrile, benzoyl peroxide, cumene hydroperoxide, 2-mercaptobenzimidazole, 2-mercaptobenzoxazole, 2-mercaptobenzothiazole, 2-(o-chlorophenyl)-4,5-di(m-methoxyphenyl)-imidazolyl dimer, benzophenone, 2-chlorobenzophenone, p,p′-bisdimethylaminobenzophenone, 4,4′-bisdiethylaminobenzophenone, 4,4′-dichlorobenzophenone, 3,3-dimethyl-4-methoxybenzophenone, benzil, benzoin, benzoin methyl ether, benzoin ethyl ether, benzoin isopropyl ether, benzoin-n-butyl ether, benzoin isobutyl ether, benzoin butyl ether, acetophenone, 2,2-diethoxyacetophenone, p-dimethylacetophenone, p-dimethylaminopropiophenone, dichloroacetophenone, trichloroacetophenone, p-tert-butylacetophenone, p-dimethylaminoacetophenone, p-tert-butyltrichloroacetophenone, p-tert-butyldichloroacetophenone, α,α-dichloro-4-phenoxyacetophenone, thioxanthone, 2-methylthioxanthone, 2-isopropylthioxanthone, dibenzosuberone, pentyl 4-dimethylaminobenzoate, 9-phenylacridine, 1,7-bis-(9-acridinyl)heptane, 1,5-bis-(9-acridinyl)pentane, 1,3-bis-(9-acridinyl)propane, p-methoxytriazine, 2,4,6-tris(trichloromethyl)-s-triazine, 2-methyl-4,6-bis(trichloromethyl)-s-triazine, 2-[2-(5-methylfuran-2-yl)ethenyl]-4,6-bis(trichloromethyl)-s-triazine, 2-[2-(furan-2-yl)ethenyl]-4,6-bis(trichloromethyl)-s-triazine, 2-[2-(4-diethylamino-2-methylphenyl)ethenyl]-4,6-bis(trichloromethyl)-s-triazine, 2-[2-(3,4-dimethoxyphenyl)ethenyl]-4,6-bis(trichloromethyl)-s-triazine, 2-(4-methoxyphenyl)-4,6-bis(trichloromethyl)-s-triazine, 2-(4-ethoxystyryl)-4,6-bis(trichloromethyl)-s-triazine, 2-(4-n-butoxyphenyl)-4,6-bis(trichloromethyl)-s-triazine, 2,4-bis-trichloromethyl-6-(3-bromo-4-methoxy)phenyl-s-triazine, 2,4-bis-trichloromethyl-6-(2-bromo-4-methoxy)phenyl-s-triazine, 2,4-bis-trichloromethyl-6-(3-bromo-4-methoxy)styrylphenyl-s-triazine, 2,4-bis-trichloromethyl-6-(2-bromo-4-methoxy)styrylphenyl-s-triazine, and the like are specifically exemplified.

other photopolymerization initiator (B3) may be used either individually or in combination of two or more.

A content of the photopolymerization initiator (B) is preferably 0.5% by mass or more and 30% by mass or less, and more preferably 1% by mass or more and 20% by mass or less relative to the mass of the photosensitive composition excluding the mass of the organic solvent (S) described later (total solid content). When the content of the photopolymerization initiator (B) is in the above range, it is possible to obtain the photosensitive composition with good curability.

A ratio of a mass W2 of the oxime ester compound (B2) is preferably 30% by mass or more, more preferably 35% by mass or more and 95% by mass or less, and further preferably 40% by mass or more and 90% by mass or less relative to sum of a mass W1 of the phosphine oxide compound (B1) and the mass W2 of the oxime ester compound (B2).

The photopolymerization initiator (B) may be used in combination with a photoinitiator aid. Examples of the photoinitiator aid include triethanolamine, methyldiethanolamine, triisopropanolamine, methyl 4-dimethylaminobenzoate, ethyl 4-dimethylaminobenzoate, isoamyl 4-dimethylaminobenzoate, 2-ethylhexyl 4-dimethylaminobenzoate, 2-dimethylaminoethyl 4-dimethylaminobenzoate, N,N-dimethylparatoluidine, 4,4′-bis(dimethylamino)benzophenone, 9,10-dimethoxyanthracene, 2-ethyl-9,10-dimethoxyanthracene, 9,10-diethoxyanthracene, 2-ethyl-9,10-diethoxyanthracene, 2-mercaptobenzothiazole, 2-mercaptobenzoxazole, 2-mercaptobenzimidazole, 2-mercapto-5-methoxybenzothiazole, 3-mercaptopropionic acid, methyl 3-mercaptopropionate, pentaerythritol tetramercaptoacetate, 3-mercaptopropionate, and the like. These photoinitiator aids may be used either individually or in combination of two or more.

### <Solvent (S)>

The photosensitive composition may include a solvent (S) for the purpose of adjustment of applicability and the like. Type of the solvent (S) is not particularly limited, and typically an organic solvent.

Examples of the organic solvent that may be included in the photosensitive composition include (poly)alkylene glycol monoalkyl ethers such as ethylene glycol monomethyl ether, ethylene glycol monoethyl ether, ethylene glycol n-propyl ether, ethylene glycol mono-n-butyl ether, diethylene glycol monomethyl ether, diethylene glycol monoethyl ether, diethylene glycol mono-n-propyl ether, diethylene glycol mono-n-butyl ether, triethylene glycol monomethyl ether, triethylene glycol monoethyl ether, propylene glycol monomethyl ether, propylene glycol monoethyl ether, propylene glycol mono-n-propyl ether, propylene glycol mono-n-butyl ether, dipropylene glycol monomethyl ether, dipropylene glycol monoethyl ether, dipropylene glycol mono-n-propyl ether, dipropylene glycol mono-n-butyl ether, tripropylene glycol monomethyl ether, and tripropylene glycol monoethyl ether; (poly)alkylene glycol monoalkyl ether acetates such as ethylene glycol monomethyl ether acetate, ethylene glycol monoethyl ether acetate, diethylene glycol monomethyl ether acetate, diethylene glycol monoethyl ether acetate, propylene glycol monomethyl ether acetate, and propylene glycol monoethyl ether acetate; other ethers such as diethylene glycol dimethyl ether, diethylene glycol methyl ethyl ether, diethylene glycol diethyl ether, and tetrahydrofuran; ketones such as methyl ethyl ketone, cyclohexanone, 2-heptanone, and 3-heptanone; alkyl lactates such as methyl 2-hydroxyprionate, and ethyl 2-hydroxypropionate; other esters such as ethyl 2-hydroxy-2-methylpropionate, methyl 3-methoxypropionate, ethyl 3-methoxypropionate, methyl 3-ethoxypropionate, ethyl 3-ethoxypropionate, ethyl ethoxyacetate, ethyl hydroxyacetate, 2-hydroxy-3-methybutanonate, 3-methoxybutyl acetate, 3-methyl-3-methoxybutyl acetate, 3-methyl-3-methoxybutyl propionate, ethyl acetate, n-propyl acetate, isopropyl acetate, n-butyl acetate, isobutyl acetate, n-pentyl formate, isopentyl acetate, n-butyl propionate, ethyl butyrate, n-propyl butyrate, isopropyl butyrate, n-butyl butyrate, methyl pyruvate, ethyl pyruvate, n-propyl pyruvate, methyl acetoacetate, ethyl acetoacetate, and ethyl 2-oxobutanoate; aromatic hydrocarbons such as toluene and xylene; and amides such as N-methylpyrrolidone, N,N-dimethylformamide, and N,N-dimethylacetamide.

A content of the solvent (S) in the photosensitive composition is not particularly limited as long as the objective of the present invention is not impaired. For example, the content of the solvent (S) in the photosensitive composition may be 95% by mass or less, 80% by mass or less, 50% by mass or less, 30% by mass or less, or 20% by mass or less relative to the mass of the photosensitive composition. In addition, when the photosensitive composition includes the solvent (S), the content of the solvent (S) may be 1% by mass or more, 5% by mass or more, 10% by mass or more, 20% by mass or more, or 30% by mass or more.

When the cured product of the photosensitive composition is a cured film, this cured film is often used to form a high refractive index film in display panels such as an organic EL panel. In this case, it is desirable that there is little volatilization of the solvent (S) during the formation of the high refractive index film and little outgassing derived from the solvent (S) remaining in the high refractive index film, in order to avoid damage to the various components that constitutes the display panel. Problems of volatilization of the solvent (S) and outgassing can be solved by reducing the content of the solvent (S) in the photosensitive composition. However, when the content of the solvent is reduced in photosensitive compositions and the like, the applicability of the composition is significantly impaired. Particularly, the inkjet method is difficult to apply.

Nevertheless, in some cases, the photosensitive compositions including the aforementioned sulfide compound (A2-1) and the (meth)acrylate compound (A2-2) in combination can achieve a low viscosity that is applicable to an inkjet method, even if the photosensitive composition includes only a small amount of or no solvent (S).

The viscosity of the photosensitive composition is preferably 40 cP or lower, more preferably 30 cP or lower, further preferably 28 cP or lower, and particularly preferably 25 cP or lower as a viscosity measured at 25° C. with an E type viscometer. The viscosity of the photosensitive composition can be adjusted by, for example, adjusting a content of the base component (A), and the solvent (S).

Due to the above problems related to volatilization of the solvent (S) and outgassing, a content of the solvent (S) in the photosensitive composition is preferably 5% by mass or less. Furthermore, the content of the solvent (S) in the photosensitive composition is preferably 3% by mass or less, more preferably 2% by mass or less, further preferably 1% by mass or less, even more preferably 0.5% by mass or less, and particularly preferably 0.3% by mass or less. Considering the problems of volatilisation of the solvent (S) and outgassing, it is most preferable that the photosensitive composition include substantially no solvent (s). Inclusion of substantially no solvent (S) in the photosensitive composition means that no solvent (S) is intentionally added to the photosensitive composition, other than a very small amount of solvent (S) unavoidably brought into the photosensitive composition with the raw materials. When the photosensitive composition includes substantially no solvent (S), for example, the content of the solvent (S) in the photosensitive composition is preferably 0.2% by mass or less, more preferably 0.15% by mass or less, further preferably 0.1% by mass or less, and particularly preferably 0.05% by mass or less.

### [Other Component]

The photosensitive composition may include various additives conventionally used in photosensitive compositions in addition to the components described above as long as the objective of the present invention is not impaired. Examples of the preferred additives for use in the photosensitive composition include a dispersant, an adhesion promoter such as a silane coupling agent, an antioxidant, an anti-cohesion agent, a defoamer, a surfactant, and the like. The surfactant is not particularly limited, and known components such as fluoro-surfactants and silicone-surfactants can be used.

When the cured product with high refractive index is formed, the photosensitive composition may include metal compound particles that are at least one selected from the group consisting of titanium oxide particle, barium titanate particles, cerium oxide particles, and zinc sulfide particles. When the photosensitive composition includes the above metal compound particles, the cured product with high refractive index can be easily formed.

In view of transparency of the cured product, an average particle diameter of the metal compound particles is preferably 500 nm or less, and more preferably 2 nm or more and 100 nm or less.

A content of the metal compound particles in the photosensitive composition is not particularly limited as long as the objective of the present invention is not impaired. The content of the metal compound particles in the photosensitive composition is preferably 5% by mass or more and 70% by mass or less, more preferably 35% by mass or more and 70% by mass or less, and further preferably 45% by mass or more and 60% by mass or less relative to the mass of the photosensitive composition excluding the mass of the solvent (S). When the content of the metal compound particles in the photosensitive composition is within the above range, it is easy to obtain the photosensitive composition with low viscosity and to form the cured product with high refractive index.

### <Method for Producing Photosensitive Composition>

The photosensitive composition is obtained by mixing the above-mentioned components in the predetermined quantities and then stirring the mixture uniformly.

### <<Method for Producing Cured Product>>

The photosensitive composition described above, typically gives the cured product by a method comprising, shaping the photosensitive composition according to the shape of the cured product to be formed, and exposing the shaped photosensitive composition.

The method of shaping the photosensitive composition is not particularly limited and is selected according to the shape of the cured product. The shape of the cured product includes, but is not limited to, a film shape, a lens shape, a line shape, a prism shape, and the like. Among these shapes, the film shape is preferred. When the shape of the cured product is the lens shape, the prism shape, or the like, the photosensitive composition may be filled into a mould according to the shape of the cured product using a squeegee and the like. As an application method, for example, printing, such as an inkjet method is exemplified. In addition, when the photosensitive composition includes the alkali-soluble resin (A1-2) as the base component (A), the cured product patterned into any shape, such as a line shape, and dot shape can be formed by photolithography method using an alkali developing solution or an organic solvent as a developing solution. Examples of the method of applying the photosensitive composition in the film shape include methods in which a contact transfer-type applicator such as a roll coater, a reverse coater or a bar coater, and a non-contact type applicator such as a spinner (a rotary applicator), or a curtain flow coater are used. The photosensitive composition can also be applied in the form of a film by printing methods such as an inkjet method.

When the photosensitive composition includes the solvent (S), the solvent (S) may be removed from the photosensitive composition by a method of heating and the like, after shaping the photosensitive composition into the desired shape.

For example, after exposure to the photosensitive composition shaped into a desired shape, such as a film shape, so that the photosensitive composition is not completely cured, it may be shaped to the semi-cured photosensitive composition by methods such as imprinting. In this case, the shaped semi-cured photosensitive composition is further exposed, and the photosensitive composition is sufficiently cured to the desired degree. The aforementioned photosensitive composition may also be applied to the 3D printing method to form a cured product of the desired shape by layering a thin film of cured product through repeated inkjet printing and curing by exposure.

As for the exposure method for curing the photosensitive composition shaped by the above method, various methods known as curing methods for photosensitive compositions can be applied accordingly. Exposure to the shaped photosensitive composition is carried out, for example, by irradiating with active energy rays such as ultraviolet light and excimer laser light.

Exposure to the shaped photosensitive composition may be regioselectively carried out, for example by method of exposing through a mask. When the exposure is regioselectively carried out, the patterned cured product is formed by developing the exposed photosensitive composition using an organic solvent to remove unexposed areas. Examples of a developing solution include an organic developing solution such as monoethanolamine, diethanolamine, and triethanolamine, and an aqueous solution of sodium carbonate, ammonia, quaternary ammonium salt, or the like. When a development process is carried out, it is preferable to remove the developing solution sufficiently after the development, e.g., by drying with heat.

By the method described above, the cured product with high transparency is formed having desired shape.

### EXAMPLES

Hereinafter, the present invention is described in more detail by way of Examples, but the present invention is not limited to these Examples.

### Examples 1 to 5 and Comparative Example 1

In Examples 1 to 5 and Comparative Example 1, (meth)acrylic-modified silicone resin (a silsesquioxane resin 1: a silsesquioxane resin derived from monomer composition consisting of 2-(3-triethoxysilylpropyl)carbamoyl)cyclohexane carboxylic acid (40% by mol), 3-(trimethoxysilyl)propyl methacrylate (40% by mol), and phenyltrimethoxysilane (20% by mol)) was used as the resin (A1).

In Examples 1 to 5 and Comparative Example 1, dipentaerythritol hexaacrylate was used as the photopolymerizable monomer (A2).

In Examples 1 to 5 and Comparative Example 1, the following compounds were used as the phosphine oxide compound (B1).
(B1-1): Bis(2,4,6-trimethylbenzoyl)-phenylphosphine oxide
(B1-2): 2,4,6-trimethyulbenzoyl-diphenyl-phosphine oxide
(B1-3): ethyl(2,4,6-trimethylbenzoyl)phenylphosphinate

In Examples 1 to 5 and Comparative Example 1, compound OE1 and compound OE2 respectively having the following structure were used as the oxime ester compound (B2). The compound OE1 and the compound OE2 have a peak in a wavelength range of 320 nm or longer and 400 nm or shorter in the absorption spectrum and show a gram absorption coefficient of 10 or more at one or more wavelengths in the wavelength range of 400 nm or longer.

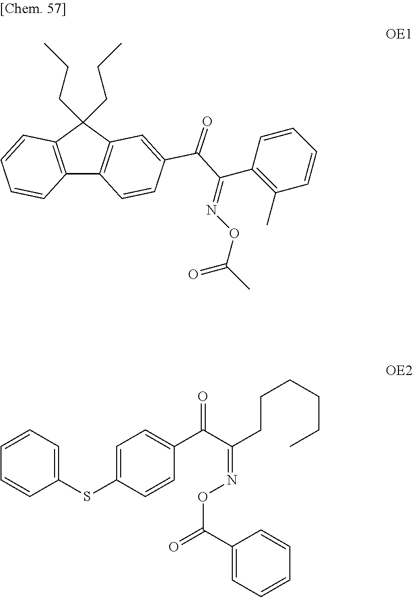 [SMILES: CCCC1(CCC)c2ccccc2-c2ccc(C(=O)/C(=N/OC(C)=O)c3ccccc3C)cc21 ; CCCCCC/C(=N/OC(=O)c1ccccc1)C(=O)c1ccc(Sc2ccccc2)cc1]

In Examples 1 to 5 and Comparative Example 1, propylene glycol monomethyl ether was used as the solvent (S).

The photosensitive compositions of Examples 1 to 5 and Comparative Example 1 were obtained by uniformly mixing each of the components described above in the proportions shown in Table 3. Sensitivities of the obtained photosensitive compositions and light transmittances of the cured films formed using the obtained photosensitive compositions were measured according to the following methods. These measurement results are shown in Table 3.

### <Method for Measuring Sensitivity>

Photosensitive compositions of Examples and Comparative Examples were spin-coated on a glass substrate, and dried at 100° C. for 2 minutes. Thereafter, light exposure using a 395 nm UV-LED exposure system was conducted, and coating films were obtained. The resulting films were immersed in an aqueous solution of TMAH (tetramethylammonium hydroxide) at a concentration of 2.38% by mass. After 2 minutes, the glass substrates were pulled out. Thereafter, thicknesses of films were measured after rinsing with pure water and drying. The case that exposure dose at which the film thickness after TMAH immersion is thicker than 90% thickness of the film before TMAH immersion is lower than 200 mJ/cm² was judged to be Very Good, and the case that above exposure dose is 200 mJ/cm² or higher and lower than 1 J/cm² is judged to be Good. In addition, the case of no curing even with exposure dose of 1 J/cm² was judged to be Poor.

### <Method for Measuring Light Transmittance>

Photosensitive compositions of Examples 1 to 5 and Comparative Example 1 were spin-coated on a glass substrate, and dried at 100° C. for 2 minutes. Thereafter, light exposure of coating films using a 395 nm UV-LED exposure system was conducted, and cured films were obtained. The light transmittances of obtained films were measured using a MCPD transmittance meter (manufactured by Otsuka Electronics Co. Ltd.). Based on the light transmittances measured, the light transmittances of the cured product formed by using the photosensitive compositions of each of the Examples 1 to 5 and Comparative Example 1 were evaluated according to the following criteria.

Very Good: Light transmittance is 95% or higher.
Good: Light transmittance is 93% or higher and lower than 95%.
Poor: Light transmittance is lower than 93%.

TABLE 3

| | | Ex. | | | | | Comp. Ex. |
|---|---|---|---|---|---|---|---|
| | | 1 | 2 | 3 | 4 | 5 | 1 |
| Base component (A) | Resin (A1) | 66 | 66 | 66 | 66 | 66 | 66 |
| | (Type/Parts by mass) | | | | | | |
| | Photopolymerizable | 30 | 30 | 30 | 30 | 30 | 30 |
| | monomer (A2) | | | | | | |
| | (Parts by mass) | | | | | | |
| Photopolymerization | Phosphine oxide | B1-1/2 | B1-1/1 | B1-1/3 | B1-2/2 | B1-3/2 | B1-1/4 |
| initiator (B) | compound (B1) | | | | | | |
| | (Type/Parts by mass) | | | | | | |
| | Oxime ester | OE1/2 | OE1/3 | OE1/1 | OE1/2 | OE1/2 | — |
| | compound (B2) | | OE2/2 | | | | |
| | (Type/Parts by mass) | | | | | | |

| | | | | | | |
|---|---|---|---|---|---|---|
| Solvent (S) | 200 | 200 | 200 | 200 | 200 | 200 |
| Sensitivity | Very Good | Very Good | Very Good | Very Good | Very Good | Good |
| Light transmittance of the cured product | Very Good | Very Good | Very Good | Very Good | Very Good | Poor |

According to Examples 1 to 5, it is found that the photosensitive composition including the base component (A) including the silicone resin and the photopolymerization initiator (B), and including the phosphine oxide compound (B1) and the oxime ester compound (B2) in combination gives the cured product with high transparency.

According to Comparative Example 1, it is found that the cured product with high transparency can not be formed, when the photosensitive composition including the base component (A) and the photopolymerization initiator (B), but not including a combination of the phosphine oxide compound (B1) and the oxime ester compound (B2) as the photopolymerization initiator (B) is used.

1. A photosensitive composition comprising a base component (A) and a photopolymerization initiator (B),
wherein the base component (A) consists of a resin (A1), or a combination of the resin (A1) and a photopolymerizable monomer (A2),
the resin (A1) comprises a silicone resin,
when the base component does not comprise the photopolymerizable monomer (A2), the resin (A1) comprises a photopolymerizable resin (A1-1) having an ethylenically unsaturated double bond,
the photopolymerization initiator (B) comprises a phosphine oxide compound (B1) and an oxime ester compound (B2) in combination.

2. The photosensitive composition according to claim 1, wherein the oxime ester compound (B2) does not comprise a compound having a peak in a wavelength range of 320 nm or longer and 400 nm or shorter in the absorption spectrum and showing a gram absorption coefficient of 10 or more at one or more wavelengths in the wavelength range of 400 nm or longer.

3. The photosensitive composition according to claim 1, wherein the oxime ester compound (B2) is a compound represented by following formula (1): 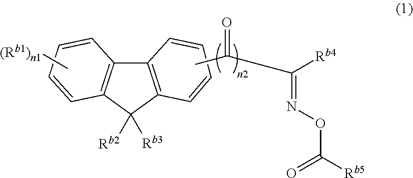
wherein, in the formula (1), R^{b1} is a hydrogen atom, a nitro group, or a monovalent organic group,
R^{b2} and R^{b3} each represent an optionally substituted chain alkyl group, an optionally substituted cyclic organic group, or a hydrogen atom,
R^{b2} and R^{b3} may be bonded to one another to form a ring,
R^{b4} is a monovalent organic group,
R^{b5} is a hydrogen atom, an optionally substituted alkyl group having 1 or more and 11 or less carbon atoms, or an optionally substituted aryl group,
n1 is an integer of 0 or more and 4 or less, and
n2 is 0 or 1.

4. The photosensitive composition according to claim 1, wherein a ratio of a mass W2 of the oxime ester compound (B2) is 30% by mass or more relative to sum of a mass W1 of the phosphine oxide compound (B1) and the mass W2 of the oxime ester compound (B2).

5. The photosensitive composition according to claim 1, wherein the base component (A) comprises the resin (A1) and the photopolymerizable monomer (A2).

6. The photosensitive composition according claim 1, wherein the base component (A) comprises the resin (A1), and the resin (A) comprises the silicone resin having an ethylenically unsaturated double bond.

7. A cured product of the photosensitive composition according to claim 1.

8. A method for producing a cured product comprising:
shaping the photosensitive composition according to claim 1 according to the shape of the cured material to be formed; and
exposing the shaped photosensitive composition.
